(19) United States
(12) Patent Application Publication
(10) Pub. No.: US 2025/0151294 A1
(43) Pub. Date: May 8, 2025

(54) STORAGE DEVICE

(71) Applicant: Semiconductor Energy Laboratory Co., Ltd., Atsugi-shi, Kanagawa-ken (JP)

(72) Inventors: Shunpei YAMAZAKI, Setagaya (JP); Tatsuya ONUKI, Atsugi (JP); Hitoshi KUNITAKE, Machida (JP)

(21) Appl. No.: 18/834,280

(22) PCT Filed: Feb. 6, 2023
(86) PCT No.: PCT/IB2023/051025

§ 371 Date: Jul. 30, 2024

(30) Foreign Application Priority Data
Feb. 18, 2022 (JP) 2022-023698

(51) Int. Cl. H10B 80/00; H01L 25/07; H10B 12/00; H10D 1/68

(52) U.S. Cl. CPC H10B 80/00; H01L 25/074; H10B 12/31; H10D 1/716; H01L 2225/06524

(57) ABSTRACT

A semiconductor device that can be miniaturized or highly integrated is provided. A storage device includes a first transistor, a second transistor, a first capacitor, and a second capacitor. The first capacitor includes a first electrode and a second electrode. The second capacitor includes the first electrode and a third electrode. One of a source and a drain of the first transistor is electrically connected to the second electrode; one of a source and a drain of the second transistor is electrically connected to the third electrode; and the first electrode includes a portion overlapping with each of the second electrode, the third electrode, the first transistor, and the second transistor and is supplied with a fixed potential or a ground potential.

### TECHNICAL FIELD

One embodiment of the present invention relates to a transistor, a semiconductor device, a storage device, and an electronic appliance. Another embodiment of the present invention relates to a method for manufacturing a semiconductor device. Another embodiment of the present invention relates to a semiconductor wafer and a module.

Note that in this specification and the like, a semiconductor device generally means a device that can function by utilizing semiconductor characteristics. A semiconductor element such as a transistor, a semiconductor circuit, an arithmetic device, and a storage device are each an embodiment of a semiconductor device. It can be sometimes said that a display device (a liquid crystal display device, a light-emitting display device, and the like), a projection device, a lighting device, an electro-optical device, a power storage device, a storage device, a semiconductor circuit, an image capturing device, an electronic appliance, and the like include a semiconductor device.

### BACKGROUND ART

In recent years, the development of semiconductor devices has progressed, and LSIs, CPUs, memories, and the like are mainly used as the semiconductor devices. A CPU is an aggregation of semiconductor elements; the CPU includes a semiconductor integrated circuit (including at least a transistor and a memory) formed into a chip by processing a semiconductor wafer, and is provided with an electrode that is a connection terminal.

A semiconductor circuit (IC chip) of an LSI, a CPU, a memory, or the like is mounted on a circuit board, for example, a printed wiring board, to be used as one of components of a variety of electronic appliances.

A technique by which a transistor is formed using a semiconductor thin film formed over a substrate having an insulating surface has been attracting attention. The transistor is used in a wide range of electronic devices such as an integrated circuit (IC) and an image display device (also simply referred to as a display device). A silicon-based semiconductor material is widely known as a semiconductor thin film applicable to the transistor and further, an oxide semiconductor has been attracting attention as another material.

It is known that a transistor using an oxide semiconductor has an extremely low leakage current in a non-conduction state. For example, Patent Document 1 discloses a low-power-consumption CPU utilizing a characteristically low leakage current of the transistor using an oxide semiconductor. Furthermore, for example, Patent Document 2 discloses a storage device that can retain stored contents for a long time by utilizing a characteristically low leakage current of the transistor using an oxide semiconductor.

In recent years, demand for an integrated circuit with higher density has risen with reductions in size and weight of electronic appliances. Furthermore, the productivity of a semiconductor device including an integrated circuit is desired to be improved. For example, Patent Document 3 and Non-Patent Document 1 disclose a technique to achieve an integrated circuit with higher density by making a plurality of memory cells overlap with each other by stacking a first transistor including an oxide semiconductor film and a second transistor including an oxide semiconductor film.

### REFERENCES

### Patent Documents

[Patent Document 1] Japanese Published Patent Application No. 2012-257187
[Patent Document 2] Japanese Published Patent Application No. 2011-151383
[Patent Document 3] PCT International Publication No. 2021/053473

### Non-Patent Document

[Non-Patent Document 1] M. Oota et. al, “3D-Stacked CAAC-In—Ga—Zn Oxide FETs with Gate Length of 72 nm”, IEDM Tech. Dig., 2019, pp. 50-53

### SUMMARY OF THE INVENTION

### Problems to be Solved by the Invention

An object of one embodiment of the present invention is to provide a semiconductor device that can be miniaturized or highly integrated. Another object is to provide a semiconductor device with high operation speed. Another object is to provide a semiconductor device having favorable electrical characteristics. Another object is to provide a semiconductor device with a small variation in electrical characteristics of transistors. Another object is to provide a semiconductor device having favorable reliability. Another object is to provide a semiconductor device with a high on-state current. Another object is to provide a semiconductor device with low power consumption. Another object is to provide a novel semiconductor device. Another object is to provide a method for manufacturing a semiconductor device with a reduced number of steps. Another object is to provide a storage device including a novel semiconductor device.

Note that the description of these objects does not preclude the existence of other objects. In one embodiment of the present invention, there is no need to achieve all of these objects. Note that objects other than these can be derived from the description of the specification, the drawings, the claims, and the like.

### Means for Solving the Problems

One embodiment of the present invention is a storage device including a first transistor, a second transistor, a first capacitor, and a second capacitor. The first capacitor includes a first electrode and a second electrode. The second capacitor includes the first electrode and a third electrode. One of a source and a drain of the first transistor is electrically connected to the second electrode; one of a source and a drain of the second transistor is electrically connected to the third electrode; and the first electrode includes a portion overlapping with each of the second electrode, the third electrode, the first transistor, and the second transistor and is supplied with a fixed potential or a ground potential.

In the above, the first electrode preferably includes a portion located above the first transistor and a portion located on a side of the first transistor.

In any of the above, it is preferable that a connection electrode be further included. In that case, it is preferable that the other of the source and the drain of the first transistor be electrically connected to the connection electrode and the other of the source and the drain of the second transistor be electrically connected to the connection electrode.

In the above, the other of the source and the drain of the first transistor preferably includes a first conductive layer. The other of the source and the drain of the second transistor preferably includes a second conductive layer. In that case, the connection electrode preferably includes a portion in contact with a top surface of the first conductive layer, a portion in contact with a side surface of the first conductive layer, a portion in contact with a top surface of the second conductive layer, and a portion in contact with a side surface of the second conductive layer.

In the above, it is preferable that a third transistor and a third capacitor be further included. In that case, the third transistor and the third capacitor are located below the first transistor. The third capacitor includes a fourth electrode and a fifth electrode, and the fourth electrode is supplied with a ground potential or a fixed potential. It is preferable that one of a source and a drain of the third transistor be electrically connected to the fifth electrode and the other of the source and the drain of the third transistor be electrically connected to the connection electrode.

In the above, the other of the source and the drain of the third transistor preferably includes a third conductive layer. In that case, the connection electrode preferably includes a portion in contact with a top surface of the third conductive layer and a portion in contact with a side surface of the third conductive layer.

In the above, the first electrode preferably includes a portion located on a side of the third transistor.

In the above, the fourth electrode is preferably electrically connected to the first electrode.

In the above, the first transistor preferably includes a semiconductor layer and a gate electrode. In that case, the fourth electrode includes a portion located below the first transistor. Furthermore, the gate electrode preferably includes a portion overlapping with the fourth electrode with the semiconductor layer therebetween.

In the above, each of the first electrode and the second electrode preferably has a flat-plate shape.

In the above, it is preferable that a top surface of the second electrode include a depressed portion and the first electrode include a protruding portion engaging with the top surface of the second electrode.

### Effect of the Invention

According to one embodiment of the present invention, a semiconductor device that can be miniaturized or highly integrated can be provided. Alternatively, a semiconductor device with high operation speed can be provided. Alternatively, a semiconductor device having favorable reliability can be provided. Alternatively, a semiconductor device with a small variation in electrical characteristics of transistors can be provided. Alternatively, a semiconductor device having favorable electrical characteristics can be provided. Alternatively, a semiconductor device with a high on-state current can be provided. Alternatively, a semiconductor device with low power consumption can be provided. Alternatively, a novel semiconductor device can be provided. Alternatively, a method for manufacturing a semiconductor device with a reduced number of steps can be provided. Alternatively, a storage device including a novel semiconductor device can be provided.

Note that the description of these effects does not preclude the existence of other effects. Note that one embodiment of the present invention does not need to have all of these effects. Note that effects other than these can be derived from the description of the specification, the drawings, the claims, and the like.

### BRIEF DESCRIPTION OF THE DRAWINGS

FIG. 1A and FIG. 1B are diagrams illustrating a structure example of a storage device.

FIG. 2A and FIG. 2B are diagrams illustrating a structure example of a storage device.

FIG. 3 is a diagram illustrating a structure example of a storage device.

FIG. 4 is a diagram illustrating a structure example of a storage device.

FIG. 5 is a diagram illustrating a structure example of a storage device.

FIG. 6A to FIG. 6D are circuit diagrams illustrating structure examples of a storage device.

FIG. 7A is a top view of a semiconductor device of one embodiment of the present invention.

FIG. 7B to FIG. 7D are cross-sectional views of the semiconductor device of one embodiment of the present invention.

FIG. 8 is a circuit diagram illustrating a structure of a storage device of one embodiment of the present invention.

FIG. 9A to FIG. 9C are cross-sectional views of a semiconductor device of one embodiment of the present invention.

FIG. 10A and FIG. 10B are cross-sectional views of a semiconductor device of one embodiment of the present invention.

FIG. 11A and FIG. 11B are cross-sectional views of a semiconductor device of one embodiment of the present invention.

FIG. 12A to FIG. 12C are cross-sectional views of a semiconductor device of one embodiment of the present invention.

FIG. 13A is a cross-sectional view of a semiconductor device of one embodiment of the present invention. FIG. 13B is a top view of the semiconductor device of one embodiment of the present invention.

FIG. 14A is a top view of a semiconductor device of one embodiment of the present invention.

FIG. 14B to FIG. 14D are cross-sectional views of the semiconductor device of one embodiment of the present invention.

FIG. 15A is a top view of a semiconductor device of one embodiment of the present invention.

FIG. 15B to FIG. 15D are cross-sectional views of the semiconductor device of one embodiment of the present invention.

FIG. 16A is a cross-sectional view of a semiconductor device of one embodiment of the present invention. FIG. 16B is a top view of the semiconductor device of one embodiment of the present invention.

FIG. 17A and FIG. 17B are cross-sectional views of semiconductor devices of embodiments of the present invention.

FIG. 18 is a cross-sectional view of a semiconductor device of one embodiment of the present invention.

FIG. 19 is a cross-sectional view of a semiconductor device of one embodiment of the present invention.

FIG. 20 is a block diagram illustrating a structure example of a storage device.

FIG. 21A and FIG. 21B are schematic views and a circuit diagram illustrating a structure example of a storage device.

FIG. 22A and FIG. 22B are schematic views each illustrating a structure example of a storage device.

FIG. 23 is a circuit diagram illustrating a structure example of a storage device.

FIG. 24 is a timing chart illustrating a structure example of a storage device.

FIG. 25A and FIG. 25B are layout diagrams each illustrating a structure of a storage device of one embodiment of the present invention.

FIG. 26 is a cross-sectional view illustrating a structure of a storage device of one embodiment of the present invention.

FIG. 27 is a cross-sectional view illustrating a structure of a storage device of one embodiment of the present invention.

FIG. 28 is a layout diagram illustrating a structure of a storage device of one embodiment of the present invention.

FIG. 29A and FIG. 29B are schematic views of a semiconductor device of one embodiment of the present invention.

FIG. 30A and FIG. 30B are diagrams illustrating examples of electronic components.

FIG. 31A to FIG. 31E are schematic views of storage devices of embodiments of the present invention.

FIG. 32A to FIG. 32H are diagrams illustrating electronic appliances of embodiments of the present invention.

FIG. 33 is a diagram illustrating an example of a device for space.

### MODE FOR CARRYING OUT THE INVENTION

Embodiments are described below with reference to the drawings. Note that the embodiments can be implemented with many different modes, and it is readily understood by those skilled in the art that modes and details thereof can be changed in various ways without departing from the spirit and scope thereof. Thus, the present invention should not be construed as being limited to the description of the embodiments below.

In the drawings, the size, the layer thickness, or the region is exaggerated for clarity in some cases. Therefore, the size, the layer thickness, or the region is not limited to the illustrated scale. Note that the drawings schematically show ideal examples, and embodiments of the present invention are not limited to shapes or values shown in the drawings. For example, in the actual manufacturing process, a layer, a resist mask, or the like might be unintentionally reduced in size by treatment such as etching, which might not be reflected in the drawings for easy understanding. Furthermore, in the drawings, the same reference numerals are used in common for the same portions or portions having similar functions in different drawings, and repeated description thereof is omitted in some cases. The same hatching pattern is applied to portions having similar functions, and the portions are not especially denoted by reference numerals in some cases.

The ordinal numbers such as “first” and “second” in this specification and the like are used for convenience and do not denote the order of steps or the stacking order of layers. Therefore, for example, the term “first” can be replaced with the term “second”, “third”, or the like as appropriate. In addition, the ordinal numbers in this specification and the like do not sometimes correspond to the ordinal numbers that are used to specify one embodiment of the present invention.

Moreover, in this specification and the like, terms for describing arrangement, such as “over” and “under,” are used for convenience to describe the positional relationship between components with reference to drawings. The positional relationship between components is changed as appropriate in accordance with a direction in which each component is described. Thus, without limitation to terms described in this specification, the description can be changed appropriately depending on the situation.

In this specification and the like, the term “film”, the term “layer”, and words ending with “or” can be interchanged with one another. For example, in some cases, the term “conductive layer” can be interchanged with the term “conductive film” or the term “conductor”, and the term “insulating layer” can be interchanged with the term “insulating film” or the term “insulator”.

### Embodiment 1

In this embodiment, a storage device of one embodiment of the present invention will be described. One embodiment of the present invention relates to the storage device including a plurality of memory cells each including a transistor and a capacitor.

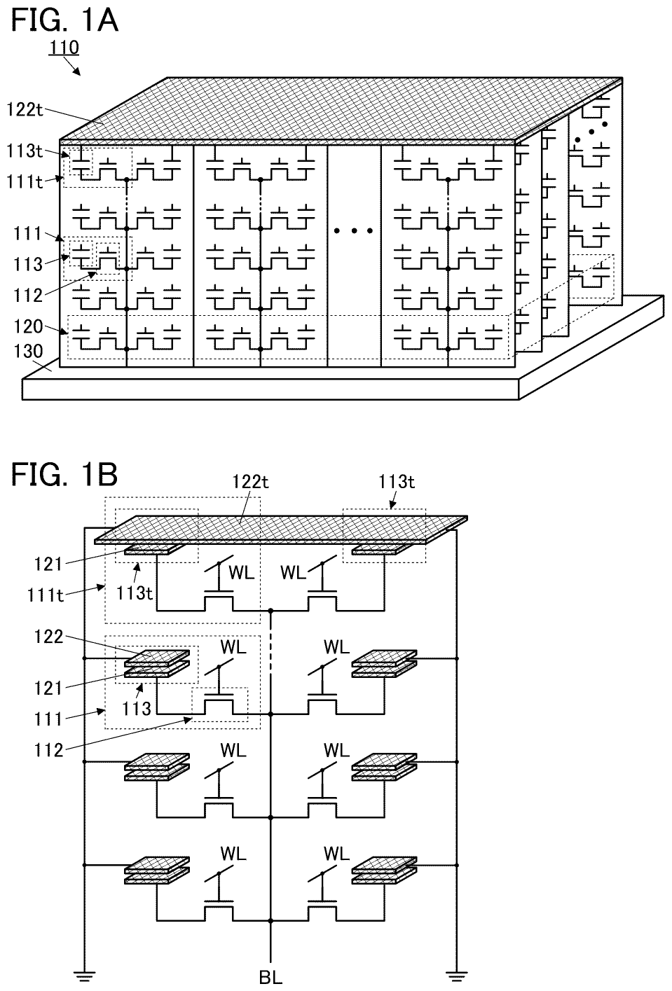

FIG. 1A is a schematic perspective view of a storage device 110 of one embodiment of the present invention.

The storage device 110 includes a plurality of memory cells 111 over a substrate 130. The memory cells 111 are arranged periodically three-dimensionally in the lateral direction, the depth direction, and the height direction. Each of the memory cells 111 includes at least a transistor 112 and a capacitor 113.

The substrate 130 may include a variety of circuits such as a control circuit, a logic circuit, and a storage circuit in addition to a driver circuit, a read circuit (including a sense amplifier), and a power supply circuit that are necessary for driving the memory cell 111, or an external connection terminal. As the substrate 130, a single crystal semiconductor substrate such as a silicon substrate or an SOI substrate is preferably used, for example.

In FIG. 1A, the plurality of memory cells 111 at the same level can be collectively referred to as a memory cell array 120. Although FIG. 1A illustrates an example of a case where five or more layers of the memory cell arrays 120 are stacked, the memory cell array 120 may be a single layer, or two or more layers and four or less layers of the memory cell arrays 120 may be stacked. A structure in which the memory cell arrays 120 are stacked, that is, a structure including all the memory cells arranged three-dimensionally is referred to as a three-dimensional memory cell array or a stacked-layer memory cell array in some cases.

Here, uppermost memory cells 111t each include a capacitor 113t. One terminal of the capacitor 113t is electrically connected to an electrode 122t. The electrode 122t is electrically connected to each of the capacitors 113t of the plurality of memory cells 111t.

The electrode 122t is provided to cover the plurality of memory cells 111 included in the storage device 110. In other words, the electrode 122t is provided to cover the top surface of the three-dimensional memory cell array. Furthermore, a fixed potential or a ground potential is preferably supplied to the electrode 122t. Accordingly, the electrode 122t functions as a protective film (also referred to as an electrostatic shielding film) that can block electrical noise input from the outside and protect the storage device 110 from the noise. With the electrode 122t, the storage device 110 can have high reliability.

Here, the electrode 122t preferably constitutes a part of the capacitor 113t. FIG. 1B is a schematic diagram obtained by extracting a part of the storage device 110.

The capacitor 113 included in the memory cell 111 includes an electrode 121 and an electrode 122. The electrode 121 is electrically connected to one of a source and a drain of the transistor 112. A fixed potential or a ground potential (here, a ground potential) is supplied to the electrode 122. A gate of the transistor 112 is electrically connected to a wiring WL functioning as a selection signal line (also referred to as a word line), and the other of the source and the drain of the transistor 112 is electrically connected to a wiring BL functioning as a data line (also referred to as a bit line).

In the same level (the memory cell array 120), a pair of memory cells 111 arranged bilaterally symmetrically are connected to one wiring BL. Thus, the number of memory cells 111 connected to one wiring BL is twice as large as the number of stacked memory cell arrays 120.

In the uppermost memory cell 111t, the capacitor 113t includes the electrode 121 and the electrode 122t. The electrode 122t serves as one electrode of at least two capacitors 113t. The electrode 122t is provided to cover the transistors 112, the wirings WL, and the wiring BL.

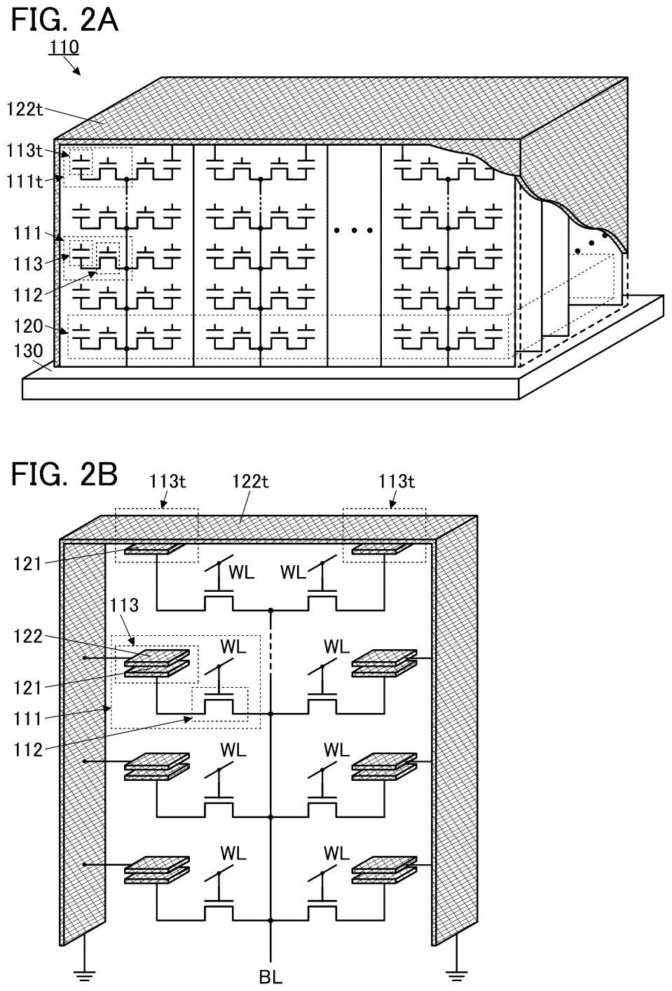

The electrode 122t is preferably provided not only above but also on a side of the three-dimensional memory cell array. FIG. 2A and FIG. 2B each illustrate an example of the electrode 122t with a different shape.

In FIG. 2A, the electrode 122t is provided to cover not only the top surface but also the side surfaces of the three-dimensional memory cell array in which a plurality of memory cell arrays 120 are stacked. Here, as the number of stacked memory cell arrays 120 increases, the aspect ratio (the ratio of the height to the length in the lateral direction or the depth direction) of the three-dimensional memory cell array increases, and thus the three-dimensional memory cell array is easily influenced by external electrical noise not only from the top surface but also from the side surfaces. Accordingly, the electrode 122t is preferably provided to cover the side surfaces of the three-dimensional memory cell array.

Although part of the electrode 122t is cut out for easy description in FIG. 2A and FIG. 2B, the electrode 122t is preferably provided to cover all surfaces other than the bottom surface of the three-dimensional memory cell array. In other words, the electrode 122t is preferably provided to cover all the side surfaces and the top surface of the three-dimensional memory cell array.

Furthermore, a side portion of the electrode 122t preferably reaches the substrate 130. In that case, part of the electrode 122t is preferably electrically connected to a wiring provided on the substrate 130. Accordingly, a fixed potential or a ground potential can be directly supplied from the substrate 130 to the electrode 122t.

As illustrated in FIG. 2B, it is preferable that the electrode 122 of the capacitor 113 in each memory cell be electrically connected to the electrode 122t and be supplied with a fixed potential or a ground potential (here, a ground potential) through the electrode 122t. This eliminates the need for a connection electrode (also referred to as a via hole) for supplying a potential from the substrate 130 to the electrode 122, whereby the manufacturing process can be simplified and the chip area can be reduced.

Next, a more specific example of the storage device of one embodiment of the present invention will be described.

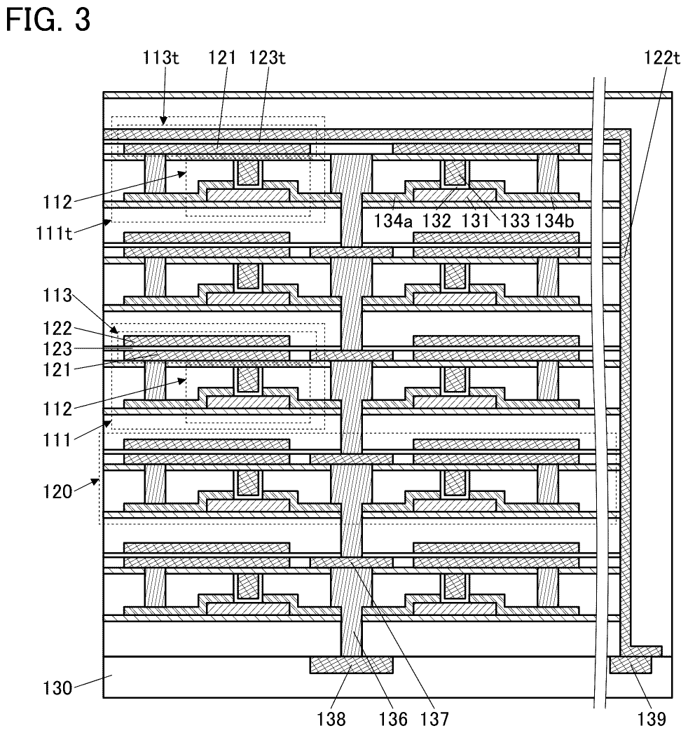

FIG. 3 illustrates a schematic cross-sectional view of the storage device. FIG. 3 illustrates a cross section of the case where five memory cell arrays 120 are stacked as an example.

The transistor 112 includes a semiconductor layer 131, a gate insulating layer 132, a gate electrode 133, and a pair of electrodes (an electrode 134a and an electrode 134b). The transistor that can be used in the storage device will be described in detail in a later embodiment.

A plurality of conductive layers 136 electrically connected to the stacked transistors 112 are provided to be stacked in the height direction. The stack of the conductive layers 136 can be referred to as a through electrode, a connection electrode, a plug, or the like. The conductive layer 136 is electrically connected to the electrode 134a of each transistor. The lowermost conductive layer 136 is electrically connected to a wiring 138 provided on the substrate 130. In FIG. 3, between two conductive layers 136 adjacent to each other in the height direction, a conductive layer 137 obtained by processing the same conductive film as the electrode 121 is provided. That is, the conductive layer 136 and the conductive layer 137 are alternately connected to each other.

The electrode 134b of the transistor 112 is electrically connected to the electrode 121 of the capacitor 113 or the capacitor 113t.

The capacitor 113 includes the electrode 121, the electrode 122, and an insulating layer 123 functioning as a dielectric and located between the electrodes. The capacitor 113t includes the electrode 121, the electrode 122t, and an insulating layer 123t. The insulating layer 123t and the electrode 122t are shared by the capacitors 113t of the memory cells 111t. The capacitor 113 and the capacitor 113t form what is called a parallel plate capacitor. The insulating layer 123t and the electrode 122t each include a portion overlapping with the electrode 121, a portion overlapping with the transistor 112, and a portion overlapping with the conductive layer 136.

Here, the electrode 122 is provided to overlap with the semiconductor layer 131 of the transistor 112 in the memory cell located thereabove, in which case the electrode 122 may also serve as a second gate electrode (a back gate electrode) of the transistor 112. Since a fixed potential or a ground potential is supplied to the electrode 122, using such an electrode as the back gate of the transistor 112 can stabilize the electrical characteristics such as the threshold voltage of the transistor 112.

On the right side in FIG. 3, a state in which the electrode 122t covers the side surface of the three-dimensional memory cell array is illustrated. The electrode 122t is electrically connected to a wiring 139 provided on the substrate 130. The wiring 139 is a wiring to which a ground potential or a fixed potential is supplied, for example.

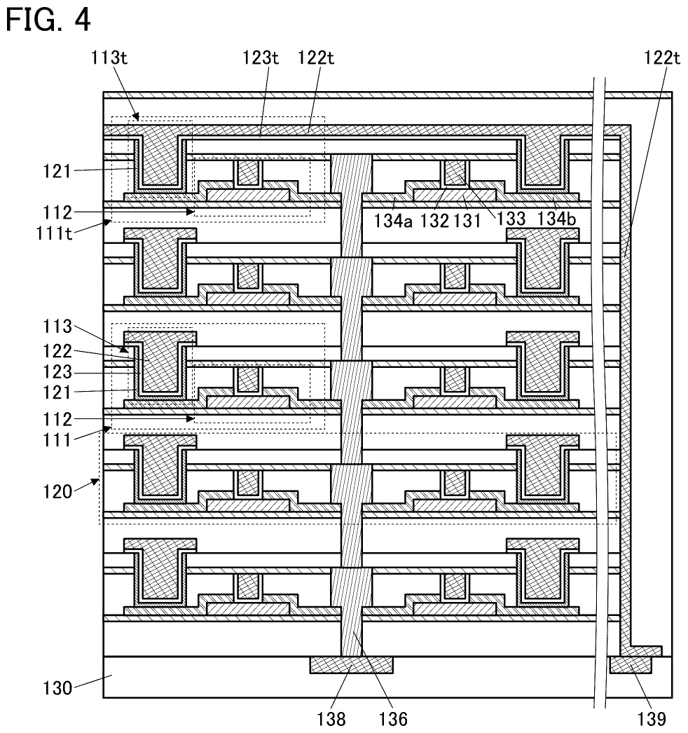

FIG. 4 illustrates an example in which the capacitor 113 and the capacitor 113t have structures different from those in FIG. 3.

An opening portion is provided in an interlayer insulating film to reach the electrode 134b of the transistor 112, and the electrode 121 and the insulating layer 123 (or the insulating layer 123t) are stacked along the sidewalls of the opening portion and the top surface of the electrode 134b. The electrode 122 (or the electrode 122t) is provided over the insulating layer 123 (or the insulating layer 123t) to fill the opening portion. In other words, it can be said that the top surface of the electrode 121 includes a depressed portion, and the electrode 122 includes a protruding portion engaging with the top surface of the electrode 121. The capacitor 113 and the capacitor 113t each having such a structure can be referred to as a trench-type capacitor or a trench capacitor. The capacitance value per area of the trench capacitor can be larger than that of a parallel plate capacitor, and thus the trench capacitor is suitable for reduction in area and high integration.

FIG. 4 illustrates an example in which the conductive layers 136 adjacent to each other in the vertical direction (the height direction) are directly connected to each other.

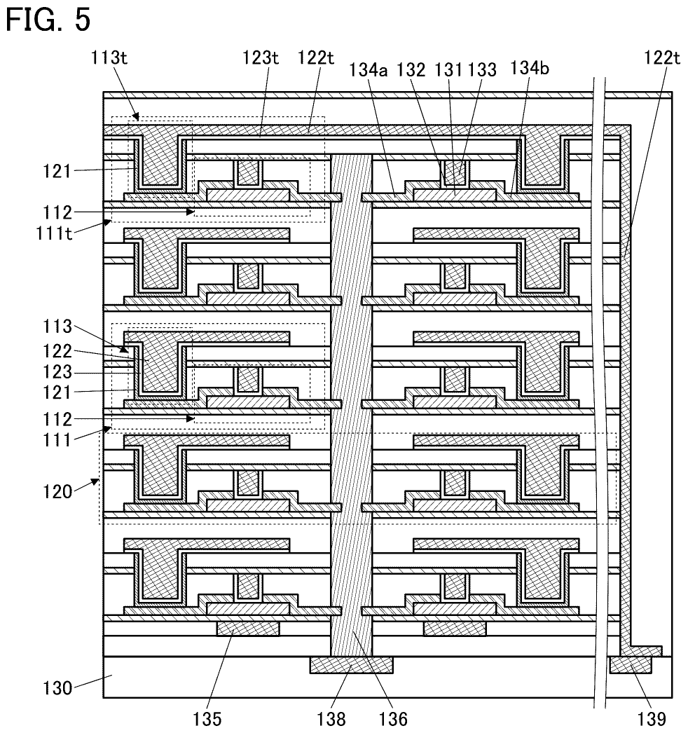

FIG. 5 illustrates a structure of a case where the electrode 122 also serves as the back gate of the transistor 112. The electrode 122 includes a portion overlapping with the semiconductor layer 131 included in the transistor 112 thereabove. Furthermore, FIG. 5 illustrates an example in which the transistor 112 in the lowermost memory cell array 120 is provided with a conductive layer 135 functioning as a back gate. As the electrode 122, the conductive layer 135 is supplied with a fixed potential or a ground potential.

FIG. 5 illustrates an example in which a through electrode is formed of one conductive layer 136. That is, an opening reaching the wiring 138 is provided to penetrate the stack of the memory cell arrays and the conductive layer 136 is embedded in the opening. Such a structure is preferable because the number of formation steps of the through electrode can be reduced.

Next, structures of memory cells that can each be used in the storage device of one embodiment of the present invention will be described.

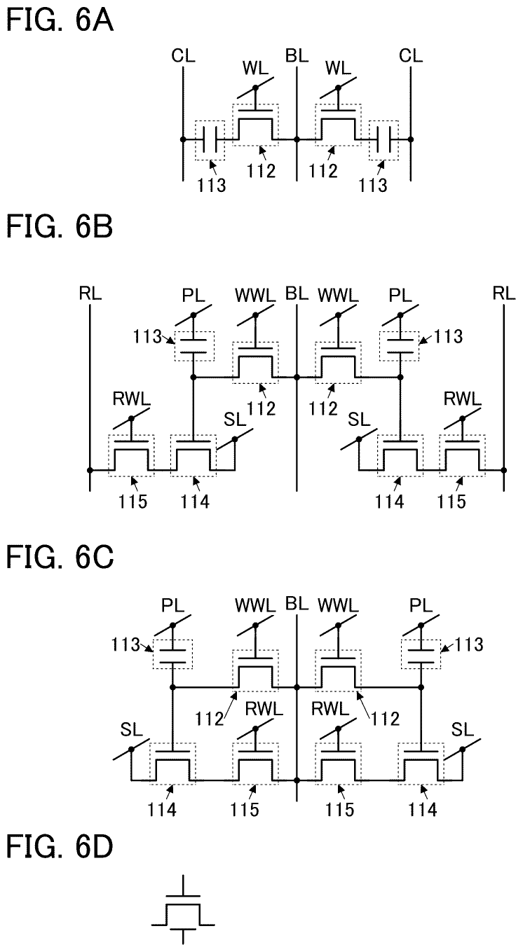

FIG. 6A, FIG. 6B, and FIG. 6C are each a circuit diagram in which two memory cells are connected bilaterally symmetrically.

FIG. 6A illustrates an example of a case where one memory cell includes one transistor 112 and one capacitor 113. Each memory cell is connected to the wiring BL, the wiring WL, and a wiring CL. The wiring BL functions as a bit line, and the wiring WL functions as a word line. The wiring CL is supplied with a fixed potential or a ground potential.

In FIG. 6A, the gate of the transistor 112 is electrically connected to the wiring WL, one of the source and the drain of the transistor 112 is electrically connected to the wiring BL, and the other thereof is electrically connected to one electrode of the capacitor 113. The other electrode of the capacitor 113 is electrically connected to the wiring CL.

FIG. 6B has a structure in which two transistors (a transistor 114 and a transistor 115) are added to each memory cell in FIG. 6A. The wiring BL, a wiring WWL, a wiring PL, a wiring SL, a wiring RWL, and a wiring RL are connected to each memory cell illustrated in FIG. 6B. The wiring WWL and the wiring RWL function as word lines. One of the wiring RL and the wiring SL is electrically connected to a read circuit, and the other thereof is supplied with a fixed potential or a signal. The wiring PL is supplied with a fixed potential or a ground potential.

The gate of the transistor 112 is electrically connected to the wiring WWL, one of the source and the drain of the transistor 112 is electrically connected to the wiring BL, and the other thereof is electrically connected to one electrode of the capacitor 113 and a gate of the transistor 114. The other electrode of the capacitor 113 is electrically connected to the wiring PL. One of a source and a drain of the transistor 114 is electrically connected to the wiring SL, and the other thereof is electrically connected to one of a source and a drain of the transistor 115. A gate of the transistor 115 is electrically connected to the wiring RWL, and the other of the source and the drain of the transistor 115 is electrically connected to the wiring RL.

Note that in the case of the structure illustrated in FIG. 6B, the transistor 115 is not necessarily provided when not needed. In that case, the other of the source and the drain of the transistor 114 can be electrically connected to the wiring RL. In the case where the transistor 115 is not provided, a potential supplied to the wiring PL is controlled so that the transistor 114 is not brought into a conduction state in the memory cell in which reading is not performed.

FIG. 6C is a modification example of FIG. 6B. In FIG. 6C, the wiring BL also serves as the wiring RL. That is, the other of the source and the drain of the transistor 115 is electrically connected to the wiring BL. Such a structure can reduce the number of wirings, thereby enabling high integration.

Here, a transistor including a back gate can be used as each of the transistors illustrated in FIG. 6A to FIG. 6C. FIG. 6D illustrates a transistor including a back gate. The back gate may be supplied with a fixed potential, a ground potential, a signal for controlling the threshold voltage of the transistor, or a signal supplied to the gate.

In the storage device of one embodiment of the present invention, the conductive film supplied with a fixed potential is provided to cover the memory cell array; thus, data change or the like due to the influence of electrical noise from the outside is inhibited, so that a highly reliable storage device can be achieved. With the structure in which the electrode of the capacitive element included in the memory cell also serves as the conductive film, a highly reliable storage device can be achieved while an increase in cost is suppressed. Furthermore, when an increase in the number of cells per area is achieved by stacking a plurality of memory cell arrays, the side surfaces can be covered with the conductive film even when the aspect ratio of the stacked-layer structure is high; thus, the storage device with both high integration and high reliability can be achieved.

At least part of this embodiment can be implemented in combination with the other embodiments described in this specification as appropriate.

### Embodiment 2

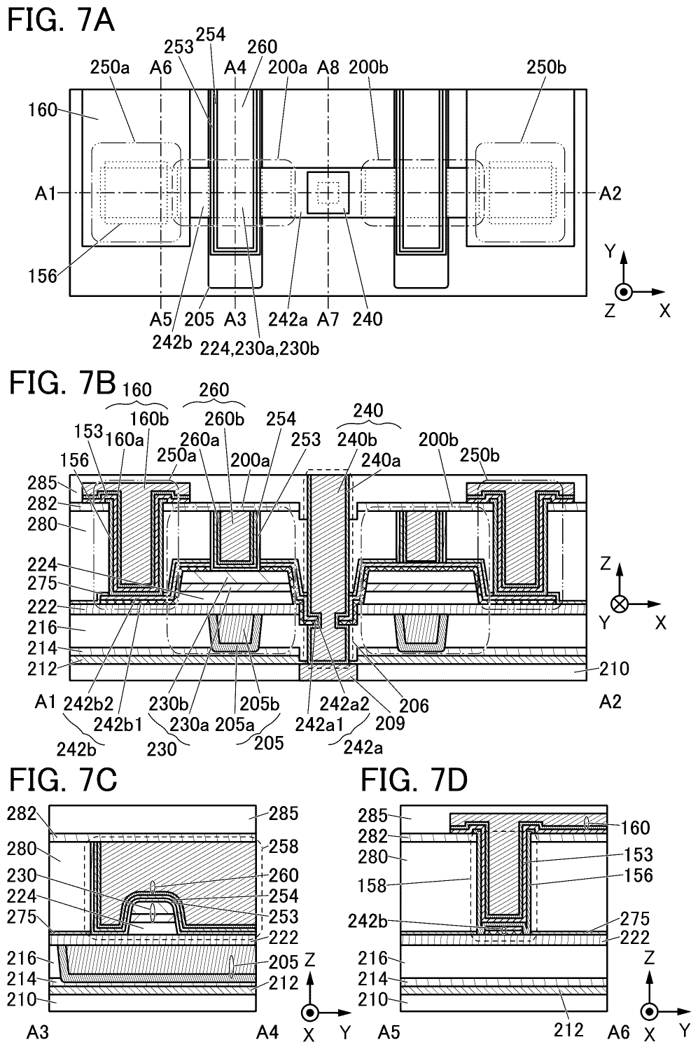

In this embodiment, an example of a semiconductor device of one embodiment of the present invention is described with reference to FIG. 7A to FIG. 13. The semiconductor device of one embodiment of the present invention includes a transistor and a capacitive element and functions as a storage device.

### <Structure Example of Semiconductor Device>

A structure of a semiconductor device including a transistor and a capacitive element is described with reference to FIG. 7. The semiconductor layer illustrated in FIG. 7A to FIG. 7D includes a transistor 200a, a transistor 200b, a capacitive element 250a, and a capacitive element 250b. FIG. 7A is a top view of the semiconductor device, and FIG. 7B to FIG. 7D are cross-sectional views of the semiconductor device. FIG. 7B is a cross-sectional view of a portion indicated by the dashed-dotted line A1-A2 in FIG. 7A. FIG. 7C is a cross-sectional view of a portion indicated by the dashed-dotted line A3-A4 in FIG. 7A. FIG. 7D is a cross-sectional view of a portion indicated by the dashed-dotted line A5-A6 in FIG. 7A. Note that for clarity of the drawing, some components are omitted in the top view of FIG. 7A.

The X direction and the Y direction illustrated in FIG. 7A and the like are parallel to the channel length direction and the channel width direction, respectively, of the transistor 200a and the transistor 200b. The X direction, the Y direction, and the Z direction are perpendicular to one another.

The semiconductor device of one embodiment of the present invention includes an insulator 214 over a substrate (not illustrated); the transistor 200a, the transistor 200b, the capacitive element 250a, and the capacitive element 250b over the insulator 214; an insulator 280 over an insulator 275 provided in the transistor 200a and the transistor 200b; an insulator 282 over the insulator 280; an insulator 285 over the capacitive element 250a, the capacitive element 250b, and the insulator 282; and a conductor 240 (a conductor 240a and a conductor 240b). The insulator 214, the insulator 280, the insulator 282, and the insulator 285 each function as an interlayer film. As illustrated in FIG. 7B, the transistor 200a, the transistor 200b, the capacitive element 250a, and the capacitive element 250b are provided to be at least partly embedded in the insulator 280.

Here, the transistor 200a and the transistor 200b each include an oxide 230 functioning as a semiconductor layer, a conductor 260 functioning as a first gate (also referred to as top gate) electrode, a conductor 205 functioning as a second gate (also referred to as back gate) electrode, a conductor 242a functioning as one of a source electrode and a drain electrode, and a conductor 242b functioning as the other of the source electrode and the drain electrode. An insulator 253 and an insulator 254 functioning as a first gate insulator are also included. An insulator 222 and an insulator 224 functioning as a second gate insulator are also included. Note that a gate insulator is also referred to as a gate insulating layer or a gate insulating film in some cases.

The transistor 200a and the transistor 200b have the same structure; thus, in the following description common to the transistor 200a and the transistor 200b, the alphabets are omitted from the reference numerals and the term “transistor 200” is used in some cases. Similarly, the capacitive element 250a and the capacitive element 250b are described using the term “capacitive element 250” in some cases.

The first gate electrode and the first gate insulating film are located in an opening 258 formed in the insulator 280 and the insulator 275. That is, the conductor 260, the insulator 254, and the insulator 253 are located in the opening 258.

The capacitive element 250 includes a conductor 156 functioning as a lower electrode, an insulator 153 functioning as a dielectric, and a conductor 160 functioning as an upper electrode. In other words, the capacitive element 250 forms a MIM (Metal-Insulator-Metal) capacitor.

The upper electrode, the dielectric, and part of the lower electrode of the capacitive element 250 are located in an opening 158 formed in the insulator 282, the insulator 280, and the insulator 275. That is, the conductor 160, the insulator 153, and the conductor 156 are located in the opening 158.

The semiconductor device also includes the conductor 240 (the conductor 240a and the conductor 240b) electrically connected to the transistor 200 and functioning as a plug (which can also be referred to as a connection electrode). The conductor 240 is located in an opening 206 formed in the insulator 280 and the like. The conductor 240 includes a region that is in contact with part of the top surface of the conductor 242a and part of a side surface of the conductor 242a.

The semiconductor device includes an insulator 210 and a conductor 209 between the substrate (not illustrated) and the insulator 214. The conductor 209 is located to be embedded in the insulator 210. The conductor 209 includes a region that is in contact with the conductor 240.

The semiconductor device may include an insulator 212 between the insulator 214 and each of the insulator 210 and the conductor 209.

The semiconductor device illustrated in FIG. 7A and the like can be used as a memory cell of a storage device. In that case, the conductor 240 is electrically connected to a sense amplifier in some cases. Here, at least part of the capacitive element 250 is provided to overlap with the conductor 242b of the transistor 200. Thus, the capacitive element 250 can be provided without a significant increase in footprint in a plan view, enabling miniaturization or high integration of the semiconductor device.

The semiconductor device has a line-symmetric structure with respect to the dashed-dotted line A7-A8 in FIG. 7A. Here, the conductor 242a serves as one of a source electrode and a drain electrode of each of the transistor 200a and the transistor 200b. With the above connection structure between the two transistors, the two capacitive elements, and the plug, a semiconductor device that can be miniaturized or highly integrated can be provided.

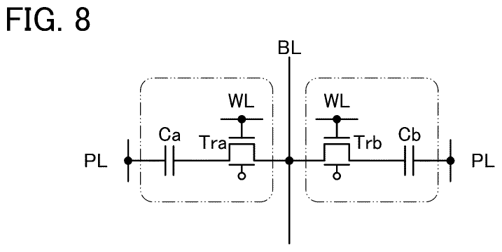

FIG. 8 is a circuit diagram illustrating the case where the semiconductor device is used in a storage device. A structure including one transistor 200 and one capacitive element 250 can be used as the memory cell of the storage device.

As illustrated in FIG. 8, the semiconductor device illustrated in FIG. 7A to FIG. 7D can be rephrased as a storage device that includes two memory cells. A transistor Tra, a transistor Trb, a capacitive element Ca, and a capacitive element Cb in FIG. 8 correspond to the transistor 200a, the transistor 200b, the capacitive element 250a, and the capacitive element 250b in FIG. 7A and the like, respectively.

In FIG. 8, one of a source and a drain of the transistor Tra is connected to the wiring BL, and the other thereof is connected to one electrode of the capacitive element Ca. The other electrode of the capacitive element Ca is connected to the wiring PL. The same applies to the transistor Trb and the capacitive element Cb.

### [Transistor 200]

The transistor 200 includes an insulator 216 over the insulator 214; the conductor 205 (a conductor 205a and a conductor 205b) located to be embedded in the insulator 216; the insulator 222 over the insulator 216 and the conductor 205; the insulator 224 over the insulator 222; an oxide 230a over the insulator 224; an oxide 230b over the oxide 230a; the conductor 242a (a conductor 242al and a conductor 242a2) and the conductor 242b (a conductor 242b1 and a conductor 242b2) over the oxide 230b; the insulator 253 over the oxide 230b; the insulator 254 over the insulator 253; the conductor 260 (a conductor 260a and a conductor 260b) located over the insulator 254 and overlapping with part of the oxide 230b; and the insulator 275 located over the insulator 222, the insulator 224, the oxide 230a, the oxide 230b, the conductor 242a, and the conductor 242b.

In this specification and the like, the oxide 230a and the oxide 230b are collectively referred to as the oxide 230 in some cases. The conductor 242a and the conductor 242b are collectively referred to as a conductor 242 in some cases.

The opening 258 reaching the oxide 230b is provided in the insulator 280 and the insulator 275. The insulator 253, the insulator 254, and the conductor 260 are located in the opening 258. Furthermore, in the channel length direction of the transistor 200, the conductor 260, the insulator 253, and the insulator 254 are provided between the conductor 242a and the conductor 242b. The insulator 254 includes a region in contact with a side surface of the conductor 260 and a region in contact with the bottom surface of the conductor 260.

The oxide 230 preferably includes the oxide 230a over the insulator 224 and the oxide 230b over the oxide 230a. With the oxide 230a under the oxide 230b, diffusion of impurities from components formed below the oxide 230a into the oxide 230b can be inhibited.

Although a structure in which two layers, the oxide 230a and the oxide 230b, are stacked as the oxide 230 in the transistor 200 is described, the present invention is not limited thereto. For example, only the oxide 230b may be provided as the oxide 230, a stacked-layer structure of three or more layers may be provided as the oxide 230, or the oxide 230a and the oxide 230b may each have a stacked-layer structure.

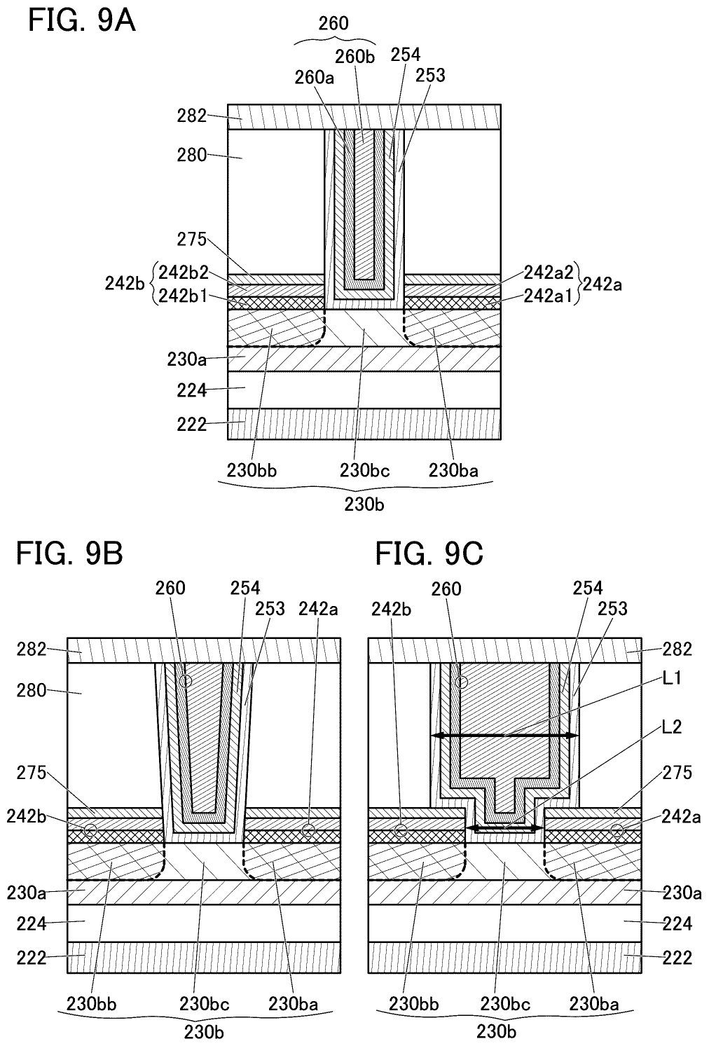

At least part of a region of the oxide 230 overlapping with the conductor 260 functions as a channel formation region. FIG. 9A is an enlarged view of the vicinity of the channel formation region in FIG. 7B. As illustrated in FIG. 9A and FIG. 7C, the opening 258 can also be regarded as having a shape in which part of a structure body including the insulator 224 and the oxide 230 protrudes in an opening having the insulator 222 as its bottom surface and the insulator 280 and the insulator 275 as its side surface.

As illustrated in FIG. 9A and FIG. 7C, the insulator 253 is provided in contact with the bottom surface and the inner wall (also referred to as sidewall) of the opening 258. Accordingly, the insulator 253 is in contact with at least part of each of the top surface of the insulator 222, a side surface of the insulator 224, a side surface of the oxide 230a, the top surface and a side surface of the metal oxide 230b, side surfaces of the conductor 242a and the conductor 242b, a side surface of the insulator 275, a side surface of the insulator 280, and the bottom surface of the insulator 254.

As illustrated in FIG. 9A, the width of the opening 258 in the channel length direction is substantially equal to the distance between the conductor 242a and the conductor 242b. Thus, the channel formation region is formed in a region of the oxide 230b that overlaps with the width of the opening 258 in the channel length direction. Here, the distance between the conductor 242a and the conductor 242b is preferably less than or equal to 60 nm, less than or equal to 50 nm, less than or equal to 40 nm, less than or equal to 30 nm, less than or equal to 20 nm, or less than or equal to 10 nm, and greater than or equal to 1 nm or greater than or equal to 5 nm, for example. When the channel formation region of the transistor 200 is extremely minute as described above, the transistor 200 can have a higher on-state current and improved frequency characteristics. In addition, a plurality of the transistors 200 can be provided with high density in a small area. Note that without limitation to the above, the distance between the conductor 242a and the conductor 242b can be greater than or equal to 60 nm.

Miniaturization of the transistor 200 can improve the high frequency characteristics. Specifically, the cutoff frequency can be improved. When the gate length is within any of the above ranges, the cutoff frequency of the transistor can be greater than or equal to 50 GHz or greater than or equal to 100 GHz at room temperature, for example.

Although FIG. 9A illustrates a structure in which the sidewall of the opening 258 is substantially perpendicular to the top surface of the insulator 222, the present invention is not limited thereto. As illustrated in FIG. 9B, the sidewall of the opening 258 may have a tapered shape. When the sidewall of the opening 258 has a tapered shape, the coverage with the insulator 253 and the like can be improved in a later step, so that defects such as a void can be reduced.

Note that in this specification and the like, a tapered shape refers to a shape such that at least part of a side surface of a component is inclined to a substrate surface. Preferably, there is a region where the angle formed between the inclined side surface and the substrate surface (hereinafter, the angle is sometimes referred to as a taper angle) is less than 90°, for example. Note that the side surface of the component and the substrate surface are not necessarily completely flat and may be substantially flat with a slight curvature or substantially flat with slight unevenness.

As illustrated in FIG. 9C, a distance L2 between the conductor 242a and the conductor 242b may be smaller than the width of the opening 258 in the cross-sectional view of the transistor 200 in the channel length direction. Here, the width of the opening 258 corresponds to a distance L1 between an interface between the insulator 280 and the insulator 253 on the conductor 242a side and an interface between the insulator 280 and the insulator 253 on the conductor 242b side, which is illustrated in FIG. 9C. With such a structure, the distance L2 between the conductor 242a and the conductor 242b can be extremely small (e.g., less than or equal to 60 nm, less than or equal to 50 nm, less than or equal to 40 nm, less than or equal to 30 nm, less than or equal to 20 nm, or less than or equal to 10 nm, and greater than or equal to 1 nm or greater than or equal to 5 nm). Since the conductor 260 includes a region having the distance L1 larger than the distance L2, a reduction in conductivity of the conductor 260 located in the region having the distance L1 can be inhibited and the conductor 260 can function as a wiring.

As illustrated in FIG. 9C, in the opening 258 seen in the cross-sectional view of the transistor 200 in the channel length direction, the width of the opening included in the insulator 280 is equal to the distance L1, and the width of the opening included in the insulator 275 is equal to the distance L2.

As illustrated in FIG. 9C and FIG. 7C, the opening 258 can also be regarded as having a shape in which part of a structure body including the insulator 224, the oxide 230, the conductor 242, and the insulator 275 protrudes in an opening having the insulator 222 as its bottom surface and the insulator 280 as its side surface. Furthermore, a region of the oxide 230 sandwiched between the conductor 242a and the conductor 242b can be regarded as being exposed in the structure body including the insulator 224, the oxide 230, the conductor 242, and the insulator 275.

As illustrated in FIG. 9C and FIG. 7C, the insulator 253 is provided in contact with the bottom surface and the inner wall (also referred to as sidewall) of the opening 258. Accordingly, the insulator 253 is in contact with at least part of each of the top surface of the insulator 222, the side surface of the insulator 224, the side surface of the oxide 230a, the top surface and the side surface of the metal oxide 230b, the side surfaces of the conductor 242a and the conductor 242b, the side surface of the insulator 275, the side surface of the insulator 280, and the bottom surface of the insulator 254. The insulator 254 and the conductor 260 are stacked over the insulator 253. Thus, the insulator 253, the insulator 254, and the conductor 260 are provided to cover the parts of the conductor 242 and the insulator 275 that protrude in the opening 258.

The channel formation region is formed in a region of the oxide 230b corresponding to the distance L2. Thus, the channel formation region of the transistor 200 is extremely minute. Accordingly, the transistor 200 can have a higher on-state current and improved frequency characteristics.

As illustrated in FIG. 9A, the oxide 230b includes a region 230bc functioning as the channel formation region of the transistor 200 and a region 230ba and a region 230bb that are provided to sandwich the region 230bc and function as a source region and a drain region. At least part of the region 230bc overlaps with the conductor 260. The region 230ba is provided to overlap with the conductor 242a, and the region 230bb is provided to overlap with the conductor 242b.

The region 230bc has a smaller amount of oxygen vacancies or a lower impurity concentration than the region 230ba and the region 230bb, and thus is a high-resistance region with a low carrier concentration. Thus, the region 230bc can be regarded as being i-type (intrinsic) or substantially i-type.

The region 230ba and the region 230bb are each an n-type region having a higher carrier concentration and lower resistance than the region 230bc. For example, the region 230ba and the region 230bb have a large amount of oxygen vacancies or a high concentration of an impurity such as hydrogen, nitrogen, or a metal element, and thus are each a low-resistance region with an increased carrier concentration.

Here, as illustrated in FIG. 9A, the side surfaces of the conductor 242a and the conductor 242b that face each other are preferably substantially perpendicular to the top surface of the oxide 230b. This can inhibit formation of an offset region (what is called an Loff region) between the region 230ba and the region 230bc and between the region 230bb and the region 230bc.

Accordingly, the frequency characteristics of the transistor 200 can be improved, and the operation speed of the semiconductor device of one embodiment of the present invention can be improved. For example, in the case where the semiconductor device of one embodiment of the present invention is used as a memory cell of a storage device, the writing speed and the reading speed can be improved.

The carrier concentration of the region 230bc functioning as the channel formation region is preferably lower than or equal to 1×10¹⁸ cm⁻³, further preferably lower than 1×10¹⁷ cm⁻³, still further preferably lower than 1×10¹⁶ cm⁻³, yet still further preferably lower than 1×10¹³ cm⁻³, and yet still further preferably lower than 1×10¹² cm⁻³. Note that the lower limit of the carrier concentration of the region 230bc functioning as the channel formation region is not particularly limited and can be, for example, 1×10⁻⁹ cm⁻³.

Between the region 230bc and the region 230ba or the region 230bb, a region having a carrier concentration that is lower than or substantially equal to the carrier concentrations of the region 230ba and the region 230bb and higher than or substantially equal to the carrier concentration of the region 230bc may be formed. That is, the region functions as a junction region between the region 230bc and the region 230ba or the region 230bb. The junction region has a hydrogen concentration lower than or substantially equal to that of the region 230ba and the region 230bb and higher than or substantially equal to that of the region 230bc in some cases. The amount of oxygen vacancies in the junction region is smaller than or substantially equal to those in the region 230ba and the region 230bb and larger than or substantially equal to that in the region 230bc in some cases.

Although FIG. 9A illustrates an example where the region 230ba, the region 230bb, and the region 230bc are formed in the oxide 230b, the present invention is not limited thereto. For example, the above regions may be formed not only in the oxide 230b but also in the oxide 230a.

In the oxide 230, the boundaries between the regions are difficult to detect clearly in some cases. The concentrations of a metal element and impurity elements such as hydrogen and nitrogen, which are detected in each region, may be not only gradually changed between the regions but also continuously changed in each region. That is, the region closer to the channel formation region has lower concentrations of a metal element and an impurity element such as hydrogen or nitrogen.

In the transistor 200, a metal oxide functioning as a semiconductor (hereinafter also referred to as an oxide semiconductor) is preferably used for the oxide 230 (the oxide 230a and the oxide 230b) including the channel formation region.

The metal oxide functioning as a semiconductor preferably has a band gap wider than or equal to 2 eV, further preferably wider than or equal to 2.5 eV. With use of a metal oxide having a wide band gap, the off-state current of the transistor can be reduced.

As the oxide 230, a metal oxide such as indium oxide, gallium oxide, or zinc oxide is preferably used, for example. Alternatively, as the oxide 230, a metal oxide containing two or three selected from indium, an element M, and zinc is preferably used, for example. The element M is one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium. Specifically, the element M is preferably one or more selected from aluminum, gallium, yttrium, and tin. Note that a metal oxide containing indium, the element M, and zinc is referred to as an In-M-Zn oxide in some cases.

The oxide 230 preferably has a stacked-layer structure of a plurality of oxide layers with different chemical compositions. For example, the atomic ratio of the element M to In in the metal oxide used as the oxide 230a is preferably higher than the atomic ratio of the element M to In in the metal oxide used as the oxide 230b. With this structure, impurities and oxygen can be inhibited from diffusing into the oxide 230b from the components formed below the oxide 230a.

Furthermore, the atomic ratio of In to the element M in the metal oxide used as the oxide 230b is preferably higher than the atomic ratio of In to the element M in the metal oxide used as the oxide 230a. With this structure, the transistor 200 can have a high on-state current and high frequency characteristics.

When the oxide 230a and the oxide 230b include a common element as the main component besides oxygen, the density of defect states at the interface between the oxide 230a and the oxide 230b can be reduced. Thus, the influence of interface scattering on carrier conduction is small, and the transistor 200 can have a high on-state current and high frequency characteristics.

Specifically, as the oxide 230a, a metal oxide with a composition of In:M:Zn=1:3:4 [atomic ratio] or in the neighborhood thereof, a composition of In:M:Zn=1:3:2 [atomic ratio] or in the neighborhood thereof, or a composition of In:M:Zn=1:1:0.5 [atomic ratio] or in the neighborhood thereof is used. As the oxide 230b, a metal oxide with a composition of In:M:Zn=1:1:1 [atomic ratio] or in the neighborhood thereof, a composition of In:M:Zn=1:1:1.2 [atomic ratio] or in the neighborhood thereof, a composition of In:M:Zn=1:1:2 [atomic ratio] or in the neighborhood thereof, or a composition of In:M:Zn=4:2:3 [atomic ratio] or in the neighborhood thereof is used. Note that a composition in the neighborhood includes the range of +30% of an intended atomic ratio. Gallium is preferably used as the element M. In the case where only the oxide 230b is provided as the oxide 230, a metal oxide that can be used as the oxide 230a may be used as the oxide 230b.

Note that a metal oxide in which the atomic ratio of In to the element M is higher than that in the oxide 230b may be used as the oxide 230a, and a metal oxide in which the atomic ratio of the element M to In is higher than that in the oxide 230a may be used as the oxide 230b. With such a structure, the reliability can be improved.

When a film of the metal oxide is formed by a sputtering method, the above atomic ratio is not limited to the atomic ratio of the formed film of the metal oxide and may be the atomic ratio of a sputtering target used for forming the film of the metal oxide.

The oxide 230b preferably has crystallinity. It is particularly preferable to use a CAAC-OS (c-axis aligned crystalline oxide semiconductor) as the oxide 230b.

The CAAC-OS is a metal oxide having a dense structure with high crystallinity and small amounts of impurities and defects (for example, oxygen vacancies). In particular, after the formation of a metal oxide, heat treatment is performed at a temperature at which the metal oxide does not become a polycrystal (e.g., higher than or equal to 400° C. and lower than or equal to 600° C.), whereby a CAAC-OS having a dense structure with higher crystallinity can be obtained. When the density of the CAAC-OS is increased in such a manner, diffusion of impurities or oxygen in the CAAC-OS can be further reduced.

A clear crystal grain boundary is difficult to observe in the CAAC-OS; thus, it can be said that a reduction in electron mobility due to the crystal grain boundary is less likely to occur. Thus, a metal oxide including the CAAC-OS is physically stable. Therefore, the metal oxide including the CAAC-OS is resistant to heat and has high reliability.

When an oxide having crystallinity, such as CAAC-OS, is used as the oxide 230b, oxygen extraction from the oxide 230b by the source electrode or the drain electrode can be inhibited. This can reduce oxygen extraction from the oxide 230b even when heat treatment is performed; thus, the transistor 200 is stable with respect to high temperatures in the manufacturing process (what is called thermal budget).

A transistor using an oxide semiconductor is likely to have its electrical characteristics changed by impurities and oxygen vacancies in a region of the oxide semiconductor where a channel is formed, which might degrade the reliability. In some cases, hydrogen in the vicinity of an oxygen vacancy forms a defect that is an oxygen vacancy into which hydrogen enters (hereinafter, sometimes referred to as VoH), which generates an electron serving as a carrier. Therefore, when the region of the oxide semiconductor where a channel is formed includes oxygen vacancies, the transistor tends to have normally-on characteristics (even when no voltage is applied to the gate electrode, the channel exists and a current flows through the transistor). Therefore, impurities, oxygen vacancies, and VoH are preferably reduced as much as possible in the region of the oxide semiconductor where a channel is formed. In other words, it is preferable that the region of the oxide semiconductor where a channel is formed have a reduced carrier concentration and be of i-type (intrinsic) or substantially i-type.

As a countermeasure to the above, an insulator containing oxygen that is released by heating (hereinafter, sometimes referred to as excess oxygen) is provided in the vicinity of the oxide semiconductor and heat treatment is performed, so that oxygen can be supplied from the insulator to the oxide semiconductor to reduce oxygen vacancies and VoH. However, supply of an excess amount of oxygen to the source region or the drain region might cause a decrease in the on-state current or field-effect mobility of the transistor 200. Furthermore, a variation of the amount of oxygen supplied to the source region or the drain region in the substrate plane leads to a variation in characteristics of the semiconductor device including the transistor. When oxygen supplied from the insulator to the oxide semiconductor diffuses into conductors such as the gate electrode, the source electrode, and the drain electrode, the conductors might be oxidized and the conductivity might be impaired, for example, so that the electrical characteristics and reliability of the transistor might be adversely affected.

Therefore, the region 230bc functioning as the channel formation region in the oxide semiconductor is preferably an i-type or substantially i-type region with a reduced carrier concentration, whereas the region 230ba and the region 230bb functioning as the source region and the drain region are preferably n-type regions with high carrier concentrations. That is, the amounts of oxygen vacancies and VoH in the region 230bc of the oxide semiconductor are preferably reduced. Furthermore, it is preferable that the region 230ba and the region 230bb not be supplied with an excessive amount of oxygen and the amount of VoH in the region 230ba and the region 230bb not be excessively reduced. Furthermore, a reduction in conductivity of the conductor 260, the conductor 242a, the conductor 242b, and the like is preferably inhibited. For example, oxidation of the conductor 260, the conductor 242a, the conductor 242b, and the like is preferably inhibited. Note that hydrogen in an oxide semiconductor can form VoH; thus, the hydrogen concentration needs to be reduced in order to reduce the amount of VoH.

In order to reduce the hydrogen concentration of the region 230bc, the insulator 253 preferably has a function of capturing or fixing hydrogen. As illustrated in FIG. 9A and the like, the insulator 253 includes a region in contact with the region 230bc of the oxide 230b. With this structure, the hydrogen concentration in the region 230bc of the oxide 230b can be reduced. Thus, the amount of VoH in the region 230bc can be reduced, whereby the region 230bc can be an i-type or substantially i-type region.

An example of the insulator having a function of capturing or fixing hydrogen is a metal oxide having an amorphous structure. For example, a metal oxide, such as magnesium oxide or an oxide containing one or both of aluminum and hafnium, is preferably used. In such a metal oxide having an amorphous structure, an oxygen atom has a dangling bond and sometimes has a property of capturing or fixing hydrogen with the dangling bond. In other words, the metal oxide having an amorphous structure has high capability of capturing or fixing hydrogen.

Specifically, as the insulator 253, an oxide containing one or both of aluminum and hafnium is preferably used, more preferably, an oxide containing one or both of aluminum and hafnium and having an amorphous structure is used, and further preferably, hafnium oxide having an amorphous structure is used. In this embodiment, hafnium oxide is used as the insulator 253. In this case, the insulator 253 includes at least oxygen and hafnium. The hafnium oxide has an amorphous structure. In this case, the insulator 253 has an amorphous structure.

Note that an insulator that can be used as the insulator 253 is not limited to the above barrier insulator against hydrogen. An insulator having a thermally stable structure, such as silicon oxide or silicon oxynitride, can also be used. For example, a stacked-layer film including an aluminum oxide film and a silicon oxide film or a silicon oxynitride film over the aluminum oxide film may be used as the insulator 253. Alternatively, for example, a stacked-layer film including an aluminum oxide film, a silicon oxide film or a silicon oxynitride film over the aluminum oxide film, and a hafnium oxide film over the silicon oxide film or the silicon oxynitride film may be used as the insulator 253.

In order to inhibit oxidation of the conductor 242a, the conductor 242b, and the conductor 260, a barrier insulator against oxygen is preferably provided in the vicinity of each of the conductor 242a, the conductor 242b, and the conductor 260. In the semiconductor device described in this embodiment, the insulator corresponds to the insulator 253, the insulator 254, and the insulator 275, for example.

Note that in this specification and the like, a barrier insulator refers to an insulator having a barrier property. A barrier property in this specification and the like means a function of inhibiting diffusion of a targeted substance (also referred to as having low permeability). Alternatively, the barrier property means a function of capturing or fixing (also referred to as gettering) a targeted substance.

Examples of a barrier insulator against oxygen include an oxide containing one or both of aluminum and hafnium, magnesium oxide, gallium oxide, indium gallium zinc oxide, silicon nitride, and silicon nitride oxide. Examples of the oxide containing one or both of aluminum and hafnium include aluminum oxide, hafnium oxide, an oxide containing aluminum and hafnium (hafnium aluminate), and an oxide containing hafnium and silicon (hafnium silicate). For example, a single layer or a stacked layer of the barrier insulator against oxygen may be used as each of the insulator 253, the insulator 254, and the insulator 275.

As the insulator 253, a film through which oxygen is less likely to pass than at least the insulator 280 is preferably used. Since the insulator 253 includes a region in contact with the side surface of the conductor 242a and the side surface of the conductor 242b, formation of oxide films on these side surfaces can be inhibited. Accordingly, a decrease in the on-state current or field-effect mobility of the transistor 200 can be inhibited.

Since the insulator 253 is provided in contact with the top surface and the side surface of the oxide 230b, the side surface of the oxide 230a, the side surface of the insulator 224, and the top surface of the insulator 222, release of oxygen from the region 230bc of the oxide 230b by heat treatment or the like can be inhibited and oxygen vacancies in the region 230bc can be reduced. Even when an excess amount of oxygen is contained in the insulator 280, it is possible to inhibit supply of excess oxygen to the oxide 230a and the oxide 230b and a decrease in the on-state current or field-effect mobility of the transistor 200.

As the insulator 254, a film through which oxygen is less likely to pass than at least the insulator 280 is preferably used. The insulator 254 is provided between the conductor 260 and the region 230bc of the oxide 230 and between the insulator 280 and the conductor 260, so that oxygen contained in the region 230bc of the oxide 230 can be inhibited from diffusing into the conductor 260 and forming oxygen vacancies in the region 230bc of the oxide 230. The insulator 254 is provided between the insulator 280 and the conductor 260, so that oxygen contained in the oxide 230 and the insulator 280 can be inhibited from diffusing into the conductor 260 and oxidizing the conductor 260. For example, silicon nitride is preferably used as the insulator 254.

As the insulator 275, a film through which oxygen is less likely to pass than at least the insulator 280 is preferably used. The insulator 275 is provided between the insulator 280 and each of the conductor 242a and the conductor 242b, so that oxygen contained in the insulator 280 can be inhibited from diffusing into the conductor 242a and the conductor 242b. Thus, the conductor 242a and the conductor 242b can be inhibited from being oxidized and having increased resistivity, and a reduction in on-state current of the transistor 200 can be inhibited. For example, silicon nitride is preferably used as the insulator 275.

In order to inhibit a reduction in the hydrogen concentration in the region 230ba and the region 230bb, a barrier insulator against hydrogen is preferably provided in the vicinity of each of the region 230ba and the region 230bb. For example, a barrier insulator against hydrogen is used as the insulator 275. Examples of the barrier insulator against hydrogen include an oxide such as aluminum oxide, hafnium oxide, or tantalum oxide and a nitride such as silicon nitride. For example, a single layer or a stacked layer of the barrier insulator against hydrogen may be used as the insulator 275.

The insulator 275 is located in contact with a side surface of the region 230ba and a side surface of the region 230bb. The insulator 275 is located between the insulator 253 and the side surface of the region 230ba and between the insulator 253 and the side surface of the region 230bb. This can inhibit diffusion of hydrogen from the region 230ba and the region 230bb to the outside, so that a decrease in the hydrogen concentration in the region 230ba and the region 230bb can be inhibited. Thus, the region 230ba and the region 230bb can each be an n-type region.

With the above structure, the region 230bc functioning as the channel formation region can be an i-type or substantially i-type region, the region 230ba and the region 230bb functioning as the source region and the drain region can be n-type regions, and thus, a semiconductor device with favorable electrical characteristics can be provided. The semiconductor device can have favorable electrical characteristics even when miniaturized or highly integrated.

The insulator 253 functions as part of the gate insulator. As illustrated in FIG. 7B, the insulator 253 is provided in contact with the side surface of the insulator 275 and the side surface of the insulator 280.

The insulator 253 is provided in the opening formed in the insulator 280 and the like, together with the insulator 254 and the conductor 260. The thickness of the insulator 253 is preferably small for miniaturization of the transistor 200. The thickness of the insulator 253 is greater than or equal to 0.1 nm and less than or equal to 5.0 nm, preferably greater than or equal to 0.5 nm and less than or equal to 5.0 nm, further preferably greater than or equal to 1.0 nm and less than 5.0 nm, still further preferably greater than or equal to 1.0 nm and less than or equal to 3.0 nm. In this case, at least part of the insulator 253 includes a region having a thickness like the above-described thickness.

To form the insulator 253 having a small thickness as described above, an atomic layer deposition (ALD) method is preferably used for film formation. Examples of an ALD method include a thermal ALD method, in which a precursor and a reactant react with each other only by a thermal energy, and a PEALD (Plasma Enhanced ALD) method, in which a reactant excited by plasma is used. The use of plasma in a PEALD method is sometimes preferable because film formation at a lower temperature is possible.

An ALD method, which enables an atomic layer to be deposited one by one, has characteristics that enable formation of an extremely thin film, film formation on a component with a high aspect ratio, formation of a film with a small number of defects such as pinholes, film formation with excellent coverage, low-temperature film formation, and the like. Therefore, the insulator 253 can be formed on the side surface of the opening formed in the insulator 280 and the like, the side end portion of the conductor 242, and the like, with a small thickness like the above-described thickness and favorable coverage.

Note that some of precursors usable in an ALD method contain carbon or the like. Thus, in some cases, a film provided by an ALD method includes carbon as an impurity in a larger amount than a film provided by another film formation method. Note that impurities can be quantified by secondary ion mass spectrometry (SIMS), X-ray photoelectron spectroscopy (XPS), or auger electron spectroscopy (AES).

Note that the insulator 253 does not necessarily have the above thickness. For example, the thickness of the insulator 253 is appropriately set to be within the range of approximately 0.1 nm to 30 nm, considering the case where the insulator 253 has a stacked-layer structure of an aluminum oxide film, a silicon oxide film over the aluminum oxide film, and a hafnium oxide film over the silicon oxide film, for example.

The insulator 254 functions as part of the gate insulator. The insulator 254 preferably has a barrier property against hydrogen. In that case, diffusion of impurities included in the conductor 260, such as hydrogen, into the oxide 230b can be prevented.

The insulator 254 needs to be provided in the opening formed in the insulator 280 and the like, together with the insulator 253 and the conductor 260. The thickness of the insulator 254 is preferably small for miniaturization of the transistor 200. The thickness of the insulator 254 is greater than or equal to 0.1 nm and less than or equal to 5.0 nm, preferably greater than or equal to 0.5 nm and less than or equal to 3.0 nm, further preferably greater than or equal to 1.0 nm and less than or equal to 3.0 nm. In this case, at least part of the insulator 254 includes a region having a thickness like the above-described thickness.

As the insulator 254, a film of silicon nitride formed by a PEALD method is used, for example.

When an insulator having a function of inhibiting the passage of oxygen and impurities such as hydrogen, e.g., hafnium oxide, is used as the insulator 253, the insulator 253 can also have the function of the insulator 254. In such a case, the structure without the insulator 254 enables simplification of the manufacturing process and the improvement in productivity of the semiconductor device.

The insulator 275 is provided to cover the insulator 222, the insulator 224, the oxide 230a, the oxide 230b, and the conductor 242. The insulator 275 can have a structure including a region in contact with the top surface of the insulator 222, a region in contact with the side surface of the insulator 224, a region in contact with the side surface of the oxide 230a, a region in contact with the side surface of the oxide 230b, a region in contact with the top surface and the side surface of the conductor 242a, and a region in contact with the top surface and the side surface of the conductor 242b.

A conductive material that is less likely to be oxidized or a conductive material that is less likely to allow diffusion of oxygen is preferably used for the conductor 242a, the conductor 242b, and the conductor 260. Examples of the conductive material include a conductive material containing nitrogen and a conductive material containing oxygen. This can inhibit a reduction in the conductivity of the conductor 242a, the conductor 242b, and the conductor 260.

One or both of the conductor 242 and the conductor 260 may have a stacked-layer structure. For example, as illustrated in FIG. 7B, the conductor 242a and the conductor 242b may each have a stacked-layer structure of two layers. In that case, a conductive material that is less likely to be oxidized or that is less likely to allow diffusion of oxygen is preferably used for the layers (the conductor 242al and the conductor 242b1) that are in contact with the oxide 230b. For example, in the case where the conductor 260 has a stacked-layer structure of the conductor 260a and the conductor 260b as illustrated in FIG. 7B, a conductive material that is less likely to be oxidized or that is less likely to allow diffusion of oxygen is preferably used for the conductor 260a.

Microwave treatment is preferably performed in an atmosphere containing oxygen in a state where the conductor 242a and the conductor 242b are provided over the oxide 230b. Accordingly, oxygen vacancies and VoH in the region 230bc can be reduced. Here, the microwave treatment refers to, for example, treatment using an apparatus including a power source that generates high-density plasma with the use of a microwave.

By the effect of the plasma, the microwave, and the like, VoH in the region 230bc can be divided into an oxygen vacancy and hydrogen; the hydrogen can be removed from the region 230bc and the oxygen vacancy can be compensated for. As a result, the hydrogen concentration, oxygen vacancies, and VoHI in the region 230bc can be reduced to lower the carrier concentration.

In that case, the effect of the microwave treatment is blocked by the conductor 242a and the conductor 242b and does not reach the region 230ba and the region 230bb; thus, a reduction in VoH and supply of an excess amount of oxygen do not occur in the region 230ba and the region 230bb, preventing a decrease in carrier concentration.

The microwave treatment is preferably performed after an insulating film to be the insulator 253 is formed. By performing the microwave treatment in an oxygen-containing atmosphere through the insulator 253 in such a manner, oxygen can be efficiently implanted into the region 230bc. In addition, the insulator 253 is located to be in contact with the side surface of the conductor 242 and a surface of the region 230bc, thereby inhibiting the side surface of the conductor 242 from being oxidized.

The oxygen implanted into the region 230bc is in any of a variety of forms such as an oxygen atom, an oxygen molecule, an oxygen ion, and an oxygen radical (also referred to as O radical, which is an atom, a molecule, or an ion having an unpaired electron). An oxygen radical is particularly suitable. Furthermore, the film quality of the insulator 253 can be improved, leading to higher reliability of the transistor 200.

As illustrated in FIG. 7C, the oxide 230b may have a curved surface between the side surface and the top surface in a cross-sectional view of the transistor 200 in the channel width direction.

The radius of curvature of the curved surface is preferably greater than 0 nm and less than the thickness of the oxide 230b in a region overlapping with the conductor 242, or less than half of the length of a region that does not have the curved surface. For example, the radius of curvature of the curved surface is greater than 0 nm and less than or equal to 20 nm, preferably greater than or equal to 1 nm and less than or equal to 15 nm, further preferably greater than or equal to 2 nm and less than or equal to 10 nm. Such a shape can improve the coverage of the oxide 230b with the insulator 253, the insulator 254, and the conductor 260.

In the manufacturing process of the transistor 200, heat treatment is preferably performed with a surface of the oxide 230 exposed. The heat treatment is performed at higher than or equal to 100° C. and lower than or equal to 600° C., preferably higher than or equal to 350° C. and lower than or equal to 550° C., for example. Note that the heat treatment is performed in a nitrogen gas or inert gas atmosphere, or an atmosphere containing an oxidizing gas at higher than or equal to 10 ppm, higher than or equal to 1%, or higher than or equal to 10%. For example, the heat treatment is preferably performed in an oxygen atmosphere. Accordingly, oxygen can be supplied to the oxide 230 to reduce oxygen vacancies. The heat treatment may be performed under reduced pressure. Alternatively, the heat treatment may be performed in an atmosphere containing an oxidizing gas at higher than or equal to 10 ppm, higher than or equal to 1%, or higher than or equal to 10% in order to compensate for oxygen released, after heat treatment is performed in a nitrogen gas or inert gas atmosphere. Alternatively, the heat treatment may be performed in a nitrogen gas or inert gas atmosphere successively after heat treatment is performed in an atmosphere containing an oxidizing gas at higher than or equal to 10 ppm, higher than or equal to 1%, or higher than or equal to 10%.

Indium included in the oxide 230 is unevenly distributed, in some cases, at the interface between the oxide 230 and the insulator 253 and in its vicinity. Accordingly, the vicinity of the surface of the oxide 230 has an atomic ratio close to that of indium oxide or that of In—Zn oxide. Such an increase in the atomic ratio of indium in the vicinity of the surface of the oxide 230, especially the oxide 230b, can increase the field-effect mobility of the transistor 200.

A structure in which hydrogen is inhibited from entering the transistor 200 is preferably employed. For example, the insulator 212 and the insulator 282 each having a function of inhibiting diffusion of impurities such as water and hydrogen are preferably provided to cover the transistor 200.

The insulator 212 can inhibit diffusion of hydrogen into the transistor 200 from below the insulator 212. As the insulator 212, an insulator that can be used as the insulator 275 described above may be used.

At least one of the insulator 212, the insulator 214, and the insulator 282 is preferably formed using an insulating material which has a function of inhibiting diffusion of impurities (through which the impurities are less likely to pass) such as a hydrogen atom, a hydrogen molecule, a water molecule, a nitrogen atom, a nitrogen molecule, a nitrogen oxide molecule (N₂O, NO, NO₂, or the like), or a copper atom. Alternatively, it is preferable to use an insulating material having a function of inhibiting diffusion of oxygen (e.g., at least one of an oxygen atom, an oxygen molecule, and the like) (an insulating material through which the oxygen is less likely to pass).

For the insulator 212, the insulator 214, and the insulator 282, aluminum oxide, magnesium oxide, hafnium oxide, gallium oxide, indium gallium zinc oxide, silicon nitride, silicon nitride oxide, or the like can be used, for example. For example, silicon nitride, which has a higher hydrogen barrier property, is preferably used for the insulator 212. For example, aluminum oxide, magnesium oxide, or the like, which has an excellent function of capturing or fixing hydrogen, is preferably used for the insulator 214 and the insulator 282. In this manner, the transistor 200 is preferably surrounded by the insulator 212, the insulator 214, and the insulator 282 which have a function of inhibiting diffusion of oxygen and impurities such as water and hydrogen.

Here, an oxide having an amorphous structure is preferably used as the insulator 212, the insulator 214, and the insulator 282. For example, a metal oxide such as AlOₓ (x is a given number greater than 0) or MgO_{y} (y is a given number greater than 0) is preferably used. In such a metal oxide having an amorphous structure, an oxygen atom has a dangling bond and sometimes has a property of capturing or fixing hydrogen with the dangling bond; thus, hydrogen around the transistor 200, in particular, hydrogen included in the channel formation region of the transistor 200 can be captured or fixed.

Although the insulator 212, the insulator 214, and the insulator 282 preferably have an amorphous structure, a region having a polycrystalline structure may be partly formed. Alternatively, a multilayer structure in which a layer having an amorphous structure and a layer having a polycrystalline structure are stacked may be employed. For example, a stacked-layer structure in which a layer having a polycrystalline structure is formed over a layer having an amorphous structure may be employed.

The insulator 212, the insulator 214, and the insulator 282 are formed by a sputtering method, for example. Since a sputtering method does not need to use a molecule containing hydrogen as a film formation gas, the hydrogen concentrations of the insulator 212, the insulator 214, and the insulator 282 can be reduced. Note that the film formation method is not limited to a sputtering method, and a chemical vapor deposition (CVD) method, a molecular beam epitaxy (MBE) method, a pulsed laser deposition (PLD) method, an ALD method, or the like may be used as appropriate.

The resistivity of the insulator 212 is preferably low in some cases. For example, by setting the resistivity of the insulator 212 to approximately 1×10¹³ Ωcm, the insulator 212 can sometimes reduce charge up of the conductor 205, the conductor 242, the conductor 260, or the conductor 240 in treatment using plasma or the like in the manufacturing process of the semiconductor device. The resistivity of the insulator 212 is preferably higher than or equal to 1×10¹⁰ Ωcm and lower than or equal to 1×10¹⁵ Ωcm.

The insulator 216, the insulator 280, and the insulator 285 each preferably have a lower permittivity than the insulator 214. When a material with a low permittivity is used for the interlayer film, parasitic capacitance generated between wirings can be reduced. For the insulator 216, the insulator 280, and the insulator 285, silicon oxide, silicon oxynitride, silicon oxide to which fluorine is added, silicon oxide to which carbon is added, silicon oxide to which carbon and nitrogen are added, porous silicon oxide, or the like is used as appropriate, for example.

The conductor 205 is located to overlap with the oxide 230 and the conductor 260. Here, the conductor 205 is preferably provided to be embedded in an opening formed in the insulator 216. Part of the conductor 205 is embedded in the insulator 214 in some cases.

The conductor 205 includes the conductor 205a and the conductor 205b. The conductor 205a is provided in contact with the bottom surface and the sidewall of the opening. The conductor 205b is provided to be embedded in a depressed portion defined by the conductor 205a. Here, the top surface of the conductor 205b is substantially level with the top surface of the conductor 205a and the top surface of the insulator 216.

Here, for the conductor 205a, it is preferable to use a conductive material that is less likely to allow diffusion of impurities such as a hydrogen atom, a hydrogen molecule, a water molecule, a nitrogen atom, a nitrogen molecule, a nitrogen oxide molecule (N₂O, NO, NO₂, or the like), and a copper atom. Alternatively, it is preferable to use a conductive material that is less likely to allow diffusion of oxygen (e.g., at least one of an oxygen atom, an oxygen molecule, and the like).

When a conductive material that is less likely to allow diffusion of hydrogen is used for the conductor 205a, impurities such as hydrogen included in the conductor 205b can be prevented from diffusing into the oxide 230 through the insulator 216, the insulator 224, and the like. When a conductive material that is less likely to allow diffusion of oxygen is used for the conductor 205a, the conductivity of the conductor 205b can be inhibited from being lowered because of oxidation. As the conductive material that is less likely to allow diffusion of oxygen, for example, titanium, titanium nitride, tantalum, tantalum nitride, ruthenium, or ruthenium oxide is preferably used. Thus, a single layer or a stacked layer of the above conductive material may be used for the conductor 205a. For example, titanium nitride may be used for the conductor 205a.

A conductive material containing tungsten, copper, or aluminum as its main component is preferably used for the conductor 205b. For example, tungsten is used for the conductor 205b. In the case where the conductor 205 is used as the second gate electrode, by changing the potential applied to the conductor 205 not in conjunction with but independently of the potential applied to the conductor 260, the threshold voltage (Vth) of the transistor 200 can be controlled. In particular, by applying a negative potential to the conductor 205, Vth of the transistor 200 can be higher, and its off-state current can be reduced.

Here, the thickness of the insulator 216 is substantially equal to that of the conductor 205. The thickness of the insulator 216 is preferably as small as possible in the allowable range of the design (resistance value) of the conductor 205. Smaller thickness of the insulator 216 is preferable because the absolute amount of impurities such as hydrogen included in the film is reduced.

As illustrated in FIG. 7A, it is preferable that the conductor 205 extend to a region outside end portions of the oxide 230a and the oxide 230b in the channel width direction and the conductor 205 and the conductor 260 overlap with each other with the insulator therebetween. Accordingly, the channel formation region of the oxide 230 can be electrically surrounded by the electric field of the conductor 260 functioning as the first gate electrode and the electric field of the conductor 205 functioning as the second gate electrode.

In this specification and the like, a transistor structure in which a channel formation region is electrically surrounded by at least the electric field of a first gate electrode is referred to as a surrounded channel (S-channel) structure. The S-channel structure disclosed in this specification and the like has a structure different from a Fin-type structure and a planar structure. Meanwhile, the S-channel structure disclosed in this specification and the like can also be regarded as a kind of the Fin-type structure. In this specification and the like, the Fin-type structure refers to a structure where at least two surfaces (specifically, two surfaces, three surfaces, four surfaces, or the like) of a channel are covered with a gate electrode. With the Fin-type structure and the S-channel structure, resistance to a short-channel effect can be enhanced; that is, a transistor in which a short-channel effect is less likely to occur can be provided.

Since the S-channel structure is a structure with the electrically surrounded channel formation region, the S-channel structure is, in a sense, equivalent to a GAA (Gate All Around) structure or an LGAA (Lateral Gate All Around) structure. In such a structure, the channel formation region that is formed at the interface between the oxide 230 and the gate insulator or in the vicinity of the interface can be formed in the entire bulk of the oxide 230. Accordingly, improvement of the on-state current of the transistor or an increase in the field-effect mobility of the transistor can be expected.

Note that the semiconductor device of one embodiment of the present invention is not limited thereto. For example, a transistor structure that can be used in one embodiment of the present invention may be one or more selected from the planar structure, the Fin-type structure, and the GAA structure.

Furthermore, as illustrated in FIG. 7C, the conductor 205 is extended to function as a wiring as well. However, without limitation to this structure, a structure in which a conductor functioning as a wiring is provided below the conductor 205 may be employed. In addition, the conductor 205 is not necessarily provided in each transistor. For example, the conductor 205 may be shared by a plurality of transistors.

Although the transistor 200 having a structure in which the conductor 205 is a stack of the conductor 205a and the conductor 205b is described, the present invention is not limited thereto. For example, the conductor 205 may be provided to have a single-layer structure or a stacked-layer structure of three or more layers.

The insulator 222 is preferably less likely to allow diffusion of hydrogen (e.g., at least one of a hydrogen atom, a hydrogen molecule, and the like). In addition, the insulator 222 is preferably less likely to allow diffusion of oxygen (e.g., at least one of an oxygen atom, an oxygen molecule, and the like). For example, the insulator 222 is preferably less likely to allow diffusion of one or both of hydrogen and oxygen as compared to the insulator 224.

The insulator 222 preferably contains an oxide of one or both of aluminum and hafnium, which is an insulating material. For example, aluminum oxide, hafnium oxide, hafnium aluminate, or the like is preferably used. Alternatively, an oxide containing hafnium and zirconium (hafnium zirconium oxide) is preferably used. In the case where such a material is used, the insulator 222 functions as a layer that inhibits release of oxygen from the oxide 230 to the substrate side and diffusion of impurities such as hydrogen from the periphery of the transistor 200 into the oxide 230.

Alternatively, aluminum oxide, bismuth oxide, germanium oxide, niobium oxide, silicon oxide, titanium oxide, tungsten oxide, yttrium oxide, or zirconium oxide may be added to the above insulator, for example. Alternatively, these insulators may be subjected to nitriding treatment. A stack of the insulator and any of silicon oxide, silicon oxynitride, and silicon nitride may be used for the insulator 222.

For example, the insulator 222 may be formed using what is called a high-k material such as aluminum oxide, hafnium oxide, tantalum oxide, zirconium oxide, or hafnium zirconium oxide. Accordingly, a gate potential at the time of the operation of the transistor can be reduced while the physical thickness is maintained. Furthermore, a substance with a high permittivity such as lead zirconate titanate (PZT), strontium titanate (SrTiO₃), or (Ba,Sr)TiO₃ (BST) can be used for the insulator 222 in some cases.

Silicon oxide or silicon oxynitride, for example, is used as appropriate for the insulator 224 that is in contact with the oxide 230.

Note that the insulator 222 and the insulator 224 may each have a stacked-layer structure of two or more layers. In that case, without limitation to a stacked-layer structure formed of the same material, a stacked-layer structure formed of different materials may be employed. The insulator 224 may be formed into an island shape so as to overlap with the oxide 230a as illustrated in FIG. 7B and the like. In that case, the insulator 275 is in contact with the side surface of the insulator 224 and the top surface of the insulator 222. Note that in this specification and the like, the term “island shape” refers to a state where two or more layers formed using the same material in the same step are physically separated from each other.

For the conductor 242 (the conductor 242a and the conductor 242b), for example, tantalum nitride, titanium nitride, molybdenum nitride, tungsten nitride, a nitride containing tantalum and aluminum, a nitride containing titanium and aluminum, or the like is preferably used. In one embodiment of the present invention, tantalum nitride is particularly preferable. As another example, ruthenium oxide, ruthenium nitride, an oxide containing strontium and ruthenium, an oxide containing lanthanum and nickel, or the like may be used. These materials are preferable because they are each a conductive material that is less likely to be oxidized or a material that maintains the conductivity even after absorbing oxygen.

Note that it is particularly preferable to use a nitride containing tantalum for the conductor 242a and the conductor 242b, in which case hydrogen included in the oxide 230b or the like is likely to diffuse into the conductor 242a or the conductor 242b. The diffused hydrogen is bonded to nitrogen included in the conductor 242a or the conductor 242b in some cases. That is, hydrogen included in the oxide 230b or the like is absorbed by the conductor 242a or the conductor 242b in some cases.

No curved surface is preferably formed between the side surface of the conductor 242 and the top surface of the conductor 242. When no curved surface is formed in the conductor 242, the conductor 242 can have a large cross-sectional area in the channel width direction as illustrated in FIG. 7D and the like. Accordingly, the conductivity of the conductor 242 is increased, so that the on-state current of the transistor 200 can be increased.

As illustrated in FIG. 7A, the conductor 242a includes an opening in a region between the transistor 200a and the transistor 200b. The conductor 240 is located to overlap with the opening. Note that in the top view of the transistor 200, the size of the opening is preferably smaller than the size of the conductor 240. With this structure, a region where the conductor 242a and the conductor 240 are in contact with each other can be provided. Thus, the conductor 242a and the conductor 240 are electrically connected to each other.

Although the memory cell illustrated in FIG. 7A has a structure in which the conductor 242a of the transistor 200a and the conductor 242a of the transistor 200b are integrated, the present invention is not limited thereto. For example, the conductor 242a of the transistor 200a and the conductor 242a of the transistor 200b may be separated from each other. With such a structure, the width of the conductor 242 in the Y direction can be set to the minimum line width, so that the semiconductor device can be highly integrated. In the above case, part of the top surface and part of the side surface of the conductor 242a of the transistor 200a are in contact with the conductor 240, and part of the top surface and part of the side surface of the conductor 242a of the transistor 200b are in contact with the conductor 240. With such a structure, the conductor 240 functioning as a plug is electrically connected to the transistor 200a and the transistor 200b.

When heat treatment is performed in the state where the conductor 242a (the conductor 242b) and the oxide 230b are in contact with each other, the carrier concentration of the oxide 230b in the region overlapping with the conductor 242a (the conductor 242b) is increased and thus the sheet resistance thereof decreases in some cases. Thus, the resistance of the oxide 230b in the region overlapping with the conductor 242a (the conductor 242b) can be lowered in a self-aligned manner.

In the semiconductor device illustrated in FIG. 7A to FIG. 7D, the conductor 242 has a stacked-layer structure of two layers. Specifically, the conductor 242a includes the conductor 242al and the conductor 242a2 over the conductor 242a1. Similarly, the conductor 242b includes the conductor 242b1 and the conductor 242b2 over the conductor 242b1. In that case, the conductor 242al and the conductor 242b1 are located on the side in contact with the oxide 230b.

Although described later in detail, the conductor 242al and the conductor 242a2 can be formed using the same material and the same process as the conductor 242b1 and the conductor 242b2, respectively.

Hereinafter, the conductor 242al and the conductor 242b1 are collectively referred to as a lower layer of the conductor 242 in some cases. The conductor 242a2 and the conductor 242b2 are collectively referred to as an upper layer of the conductor 242 in some cases.

The lower layer of the conductor 242 is preferably formed using a conductive material that is less likely to be oxidized. This can inhibit a reduction in the conductivity of the conductor 242. Furthermore, the lower layer of the conductor 242 may have a property of being likely to absorb (extract) hydrogen. Accordingly, hydrogen included in the oxide 230 is diffused into the lower layer of the conductor 242, so that the hydrogen concentration of the oxide 230 can be reduced. Thus, the transistor 200 can have stable electrical characteristics.

The upper layer of the conductor 242 preferably has higher conductivity than the lower layer of the conductor 242. For example, the thickness of the upper layer of the conductor 242 is set to be larger than the thickness of the lower layer of the conductor 242. At least part of the upper layer of the conductor 242 includes a region having higher conductivity than the lower layer of the conductor 242. Alternatively, the upper layer of the conductor 242 is preferably formed using a conductive material having lower resistivity than the lower layer of the conductor 242. Accordingly, a semiconductor device with reduced wiring delay can be manufactured.

Note that the upper layer of the conductor 242 may have a property of being likely to absorb hydrogen. Accordingly, hydrogen absorbed by the lower layer of the conductor 242 is also diffused into the upper layer of the conductor 242, so that the hydrogen concentration in the oxide 230 can be further reduced. Thus, the transistor 200 can have stable electrical characteristics.

In the case where the conductor 242 has a stacked-layer structure of two layers, one or more selected from the constituent elements, chemical composition, and film formation conditions may be different between the lower layer and the upper layer of the conductor 242.

For example, tantalum nitride or titanium nitride can be used for the lower layer of the conductor 242, and tungsten can be used for the upper layer of the conductor 242. This structure can inhibit oxidation of the lower layer of the conductor 242 and a reduction in the conductivity of the conductor 242. With this structure, the upper layer of the conductor 242 can be surrounded by the insulator 275 having a barrier property against oxygen and the lower layer of the conductor 242 having a property of being less likely to be oxidized. Thus, a semiconductor device in which oxidation of the upper layer of the conductor 242 and wiring delay are inhibited can be manufactured. When tungsten is used for the upper layer of the conductor 242, the conductor 242 can function as a wiring.

Alternatively, for example, tantalum nitride may be used for the lower layer of the conductor 242, and titanium nitride may be used for the upper layer of the conductor 242. Since titanium nitride has higher conductivity than tantalum nitride, the contact resistance with the conductor 240 provided in contact with the top surface of the conductor 242 can be reduced.

Although an example in which the lower layer of the conductor 242 and the upper layer of the conductor 242 are formed using different conductive materials is described, the present invention is not limited thereto. For the lower layer and the upper layer of the conductor 242, conductive materials containing the same constituent elements and having different chemical compositions may be used. In that case, when the lower layer and the upper layer of the conductor 242 are formed successively without being exposed to an atmospheric environment, impurities or moisture from the atmospheric environment can be prevented from being attached onto the surface of the lower layer of the conductor 242, so that the vicinity of the interface between these layers can be kept clean.

In addition, tantalum nitride with a high atomic ratio of nitrogen to tantalum is preferably used for the lower layer of the conductor 242, and tantalum nitride with a low atomic ratio of nitrogen to tantalum is preferably used for the upper layer of the conductor 242. For example, tantalum nitride with an atomic ratio of nitrogen to tantalum being greater than or equal to 1.0 and less than or equal to 2.0, preferably greater than or equal to 1.1 and less than or equal to 1.8, further preferably greater than or equal to 1.2 and less than or equal to 1.5 is used for the lower layer of the conductor 242. In addition, for example, tantalum nitride with an atomic ratio of nitrogen to tantalum being greater than or equal to 0.3 and less than or equal to 1.5, preferably greater than or equal to 0.5 and less than or equal to 1.3, further preferably greater than or equal to 0.6 and less than or equal to 1.0 is used for the upper layer of the conductor 242.

The high atomic ratio of nitrogen to tantalum can improve the oxidation resistance of tantalum nitride and can inhibit the diffusion of oxygen into tantalum nitride. Such tantalum nitride is preferably used for the lower layer of the conductor 242. It is thus possible to prevent an oxide layer from being formed between the lower layer of the conductor 242 and the oxide 230 or reduce the thickness of the oxide layer.

The low atomic ratio of nitrogen to tantalum can reduce the resistivity of tantalum nitride. Hence, tantalum nitride with a low atomic ratio of nitrogen to tantalum is preferably used for the upper layer of the conductor 242. Accordingly, a semiconductor device with reduced wiring delay can be manufactured.

Note that in the case where the conductor 242 is formed using materials having the same constituent element for the upper layer and the lower layer, it is sometimes difficult to clearly detect the boundary.

Although the transistor 200 having a structure in which the conductor 242 has a stacked-layer structure of two layers is described, the present invention is not limited thereto. For example, the conductor 242 may be provided to have a single-layer structure or a stacked-layer structure of three or more layers. In the case where a component has a stacked-layer structure, layers may be distinguished by ordinal numbers corresponding to the formation order.

The top surface of the conductor 260 is located to be substantially level with the uppermost portion of the insulator 254, the uppermost portion of the insulator 253, and the top surface of the insulator 280.

The conductor 260 functioning as the first gate electrode includes the conductor 260a and the conductor 260b over the conductor 260a. The conductor 260a is located to cover the bottom surface and a side surface of the conductor 260b. Although the conductor 260 has a two-layer structure of the conductor 260a and the conductor 260b in FIG. 7B and FIG. 7C, the conductor 260 may have a single-layer structure or a stacked-layer structure of three or more layers.

For the conductor 260a, it is preferable to use a conductive material having a function of inhibiting diffusion of impurities such as a hydrogen atom, a hydrogen molecule, a water molecule, a nitrogen atom, a nitrogen molecule, a nitrogen oxide molecule, and a copper atom. Alternatively, it is preferable to use a conductive material having a function of inhibiting diffusion of oxygen (e.g., at least one of an oxygen atom, an oxygen molecule, and the like).

In addition, when the conductor 260a has a function of inhibiting diffusion of oxygen, the conductivity of the conductor 260b can be inhibited from being lowered because of oxidation due to oxygen included in the insulator 280 and the like. As the conductive material having a function of inhibiting diffusion of oxygen, for example, titanium, titanium nitride, tantalum, tantalum nitride, ruthenium, or ruthenium oxide is preferably used.

The conductor 260 is formed to fill the opening 258 that is provided to extend in the channel width direction, and the conductor 260 is also provided to extend in the channel width direction. Thus, in the case where the plurality of transistors 200 are provided, the conductor 260 can also function as a wiring. In this case, the insulator 253 and the insulator 254 are also provided to extend together with the conductor 260.

The conductor 260 also functions as a wiring and thus is preferably formed using a conductor having high conductivity. For example, a conductive material containing tungsten, copper, or aluminum as its main component can be used for the conductor 260b. The conductor 260b may have a stacked-layer structure; for example, a stacked-layer structure of the conductive material and titanium or titanium nitride may be employed.

The conductor 260 is formed in a self-aligned manner to fill the opening 258 formed in the insulator 280 and the like. The formation of the conductor 260 in this manner allows the conductor 260 to be located properly in a region between the conductor 242a and the conductor 242b without alignment.

As illustrated in FIG. 7C, in the channel width direction of the transistor 200, with reference to the bottom surface of the insulator 222, the level of the bottom surface of the conductor 260 in a region where the conductor 260 and the oxide 230b do not overlap with each other is preferably lower than the level of the bottom surface of the oxide 230b. When the conductor 260 functioning as the gate electrode covers the side surface and the top surface of the channel formation region of the oxide 230b with the insulator 253 and the like therebetween, the electric field of the conductor 260 is likely to act on the entire channel formation region of the oxide 230b. Thus, the on-state current of the transistor 200 can be increased, and the frequency characteristics of the transistor 200 can be improved. With reference to the bottom surface of the insulator 222, the difference between the level of the bottom surface of the conductor 260 in a region where the conductor 260 do not overlap with the oxide 230a or the oxide 230b and the level of the bottom surface of the oxide 230b is greater than or equal to 0 nm and less than or equal to 100 nm, preferably greater than or equal to 3 nm and less than or equal to 50 nm, further preferably greater than or equal to 5 nm and less than or equal to 20 nm.

The insulator 280 is provided over the insulator 275, and the opening 258 is formed in a region where the insulator 253, the insulator 254, and the conductor 260 are to be provided. The top surface of the insulator 280 may be planarized.

The insulator 280 functioning as the interlayer film preferably has a low permittivity. When a material with a low permittivity is used for the interlayer film, parasitic capacitance generated between wirings can be reduced. The insulator 280 is preferably provided using a material similar to that for the insulator 216, for example. In particular, silicon oxide and silicon oxynitride, which are thermally stable, are preferable. A material such as silicon oxide, silicon oxynitride, or porous silicon oxide is preferably used, in which case a region including oxygen to be released by heating can be easily formed.

The concentration of impurities such as water and hydrogen in the insulator 280 is preferably reduced. An oxide containing silicon such as silicon oxide, silicon oxynitride, or the like is used as appropriate for the insulator 280, for example.

The insulator 282 is located to be in contact with at least part of each of the top surfaces of the conductor 260, the insulator 253, the insulator 254, and the insulator 280. The insulator 282 functions as a barrier insulating film that inhibits impurities such as water and hydrogen from diffusing into the insulator 280 from above.

In the case where aluminum oxide is used for the insulator 282, the insulator 282 is preferably formed by a sputtering method. In particular, it is further preferable that a film of aluminum oxide be formed by a pulsed DC sputtering method using an aluminum target in an atmosphere containing an oxygen gas. This can achieve more uniform film thickness distribution and improve the sputtering rate and film quality. Here, RF (Radio Frequency) power may be applied to the substrate. The amount of oxygen implanted into a layer below the insulator 282 can be controlled depending on the amount of the RF power applied to the substrate. For example, the amount of oxygen implanted into the layer below the insulator 282 decreases as the RF power decreases, and the amount of oxygen is easily saturated even when the insulator 282 has a small thickness. Moreover, the amount of oxygen implanted into the layer below the insulator 282 increases as the RF power increases.

Although FIG. 7A to FIG. 7D and the like illustrate a single-layer structure of the insulator 282, the present invention is not limited to this structure, and a stacked-layer structure of two or more layers may be employed. For example, the insulator 282 may have a stacked-layer structure of two layers.

The above is the description of the transistor 200.

### [Capacitive Element 250]

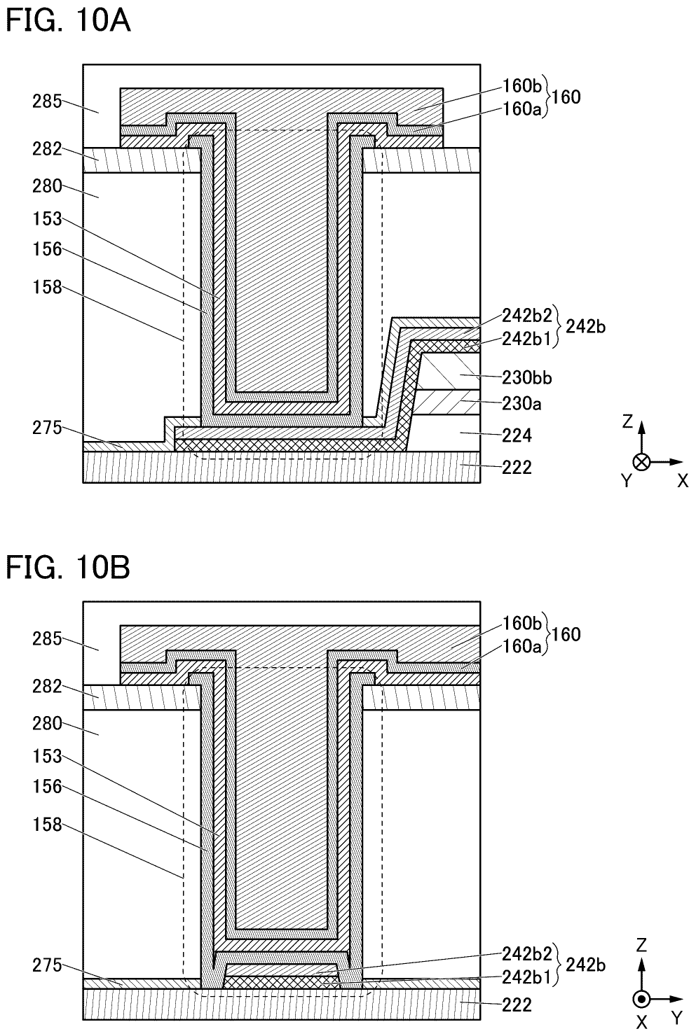

FIG. 10A is an enlarged view illustrating the capacitive element 250 in FIG. 7B and the vicinity thereof, and FIG. 10B is an enlarged view illustrating the capacitive element 250 in FIG. 7D and the vicinity thereof.

The capacitive element 250 includes the conductor 156, the insulator 153, and the conductor 160 (a conductor 160a and a conductor 160b). The conductor 156 functions as one of a pair of electrodes of the capacitive element 250 (also referred to as a lower electrode), the conductor 160 functions as the other of the pair of electrodes of the capacitive element 250 (also referred to as an upper electrode), and the insulator 153 functions as a dielectric of the capacitive element 250.

The conductor 156, the insulator 153, the conductor 160a, and the conductor 160b are at least partly located in the opening 158 provided in the insulator 275, the insulator 280, and the insulator 282. The conductor 156 is provided over the conductor 242b, the insulator 153 is provided over the conductor 156, the conductor 160a is provided over the insulator 153, and the conductor 160b is provided over the conductor 160a.

The conductor 156 is located along the opening 158 formed in the insulator 275, the insulator 280, and the insulator 282. The level of part of the top surface of the conductor 156 is preferably higher than the level of the top surface of the insulator 282. The top surface of the conductor 242b is in contact with the bottom surface of the conductor 156. The conductor 156 is preferably formed by a film formation method that enables favorable coverage, such as an ALD method or a CVD method, and a conductor that can be used as the conductor 205, the conductor 260, or the conductor 242 may be used. When the same conductive material as the conductor 242b is used for the conductor 156, for example, the contact resistance between the conductor 156 and the conductor 242b can be reduced. A film of titanium nitride or tantalum nitride formed by an ALD method can be used for the conductor 156, for example.

The insulator 153 is located to cover the conductor 156 and part of the insulator 282. For the insulator 153, a high-permittivity (high-k) material (a material with a high relative permittivity) is preferably used. The insulator 153 is preferably formed by a film formation method that enables favorable coverage, such as an ALD method or a CVD method. For example, an oxide, an oxynitride, a nitride oxide, or a nitride containing one or more kinds of metal elements selected from aluminum, hafnium, zirconium, gallium, and the like can be used for the insulator 153. In addition, any of the above materials may contain silicon.

As the insulator of the high-permittivity (high-k) material, aluminum oxide, hafnium oxide, zirconium oxide, an oxide containing aluminum and hafnium, an oxynitride containing aluminum and hafnium, an oxide containing silicon and hafnium, an oxynitride containing silicon and hafnium, an oxide containing silicon and zirconium, an oxynitride containing silicon and zirconium, an oxide containing hafnium and zirconium, an oxynitride containing hafnium and zirconium, or the like can be used, for example.

It is preferable to use stacked insulating films each formed of any of the above-described materials. A stacked-layer structure using a high-permittivity (high-k) material and a material having higher dielectric strength than the high-permittivity (high-k) material is preferably used. An insulating film in which zirconium oxide, aluminum oxide, and zirconium oxide are stacked in this order, an insulating film in which zirconium oxide, aluminum oxide, zirconium oxide, and aluminum oxide are stacked in this order, or an insulating film in which hafnium zirconium oxide, aluminum oxide, hafnium zirconium oxide, and aluminum oxide are stacked in this order can be used, for example. The stacking of an insulator having high dielectric strength can inhibit electrostatic breakdown of the capacitive element 250.

The conductor 160 is located to fill the opening 158 formed in the insulator 275, the insulator 280, and the insulator 282. The conductor 160 is preferably formed by an ALD method, a CVD method, or the like, and a conductor that can be used as the conductor 205 or the conductor 260 may be used. For example, a film of titanium nitride formed by an ALD method can be used as the conductor 160a, and a film of tungsten formed by a CVD method can be used as the conductor 160b. Note that in the case where the adhesion of tungsten to the insulator 153 is sufficiently high, a single-layer film of tungsten formed by a CVD method may be used as the conductor 160.

The opening 158 is provided to reach the conductor 242b. In other words, the opening 158 includes a region overlapping with the conductor 242b. The conductor 242b is the other of the source electrode and the drain electrode of the transistor 200 and is in contact with the bottom surface of the conductor 156 provided in the opening 158 to electrically connect the transistor 200 and the capacitive element 250 to each other.

In the plan view, the distance between the opening 158 and the oxide 230 is preferably short. Such a structure can reduce the footprint of the memory cell including the capacitive element 250 and the transistor 200. In the plan view, the shape of the opening 158 may be a quadrangular shape, a polygonal shape other than a quadrangular shape, a polygonal shape with rounded corners, or a circular shape including an elliptical shape.

As illustrated in FIG. 10A and FIG. 10B, the conductor 156 is provided in contact with the bottom surface and the inner wall of the opening 158. Thus, the conductor 156 is in contact with the side surfaces of the insulator 275, the insulator 280, and the insulator 282, a side surface of the conductor 242b1, a side surface and the top surface of the conductor 242b2, and the top surface of the insulator 222. The insulator 153 is provided in contact with the top surface of the conductor 156, the conductor 160a is provided in contact with the top surface of the insulator 153, and the conductor 160b is provided in contact with the top surface of the conductor 160a.

When the capacitive element 250 has the above structure, it is possible to form the capacitive element 250 in which the conductor 156 and the conductor 160 are located to face each other with the insulator 153 therebetween on the bottom surface and a side surface of the opening 158, as illustrated in FIG. 10A and FIG. 10B. Thus, the larger the depth of the opening 158 (which can also be referred to as the thickness of the insulator 280) is, the higher the capacitance of the capacitive element 250 can be. Increasing the capacitance per unit area of the capacitive element 250 in this manner can make the reading operation of the storage device stable.

As illustrated in FIG. 10A, part of the conductor 156, part of the insulator 153, and part of the conductor 160 are provided to be exposed from the opening 158. In other words, part of the conductor 156, part of the insulator 153, and part of the conductor 160 are formed above the top surface of the conductor 260 or the top surface of the insulator 282.

Part of the conductor 156 and part of the insulator 153 are in contact with the top surface of the insulator 282. That is, a side end portion of the conductor 156 is covered with the insulator 153. Furthermore, the conductor 160 preferably includes a region overlapping with the insulator 282 with the insulator 153 therebetween. Here, as illustrated in FIG. 10A, a side end portion of the conductor 160 and a side end portion of the insulator 153 are substantially aligned with each other. With such a structure, the conductor 160 and the conductor 156 can be separated by the insulator 153; thus, a short circuit between the conductor 160 and the conductor 156 can be inhibited.

A portion of the conductor 160 above the insulator 282 may be extended and formed in the form of a wiring. For example, as illustrated in FIG. 7D, the conductor 160 can be provided to extend in the channel width direction of the transistor 200. Thus, in the case where the plurality of transistors 200 and a plurality of the capacitive elements 250 are provided, the conductor 160 can also function as a wiring. In this case, the insulator 153 can also be provided to extend together with the conductor 160.

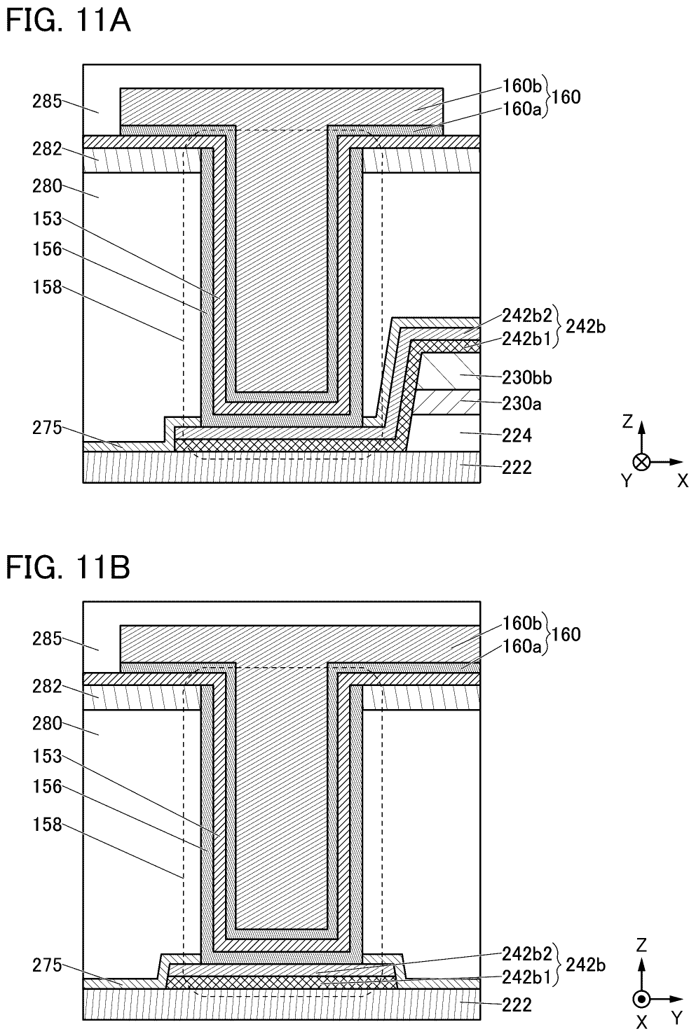

The capacitive element 250 may have a structure illustrated in FIG. 11A and FIG. 11B. Here, FIG. 11A is an enlarged view corresponding to the capacitive element 250 in FIG. 7B, and FIG. 11B is an enlarged view corresponding to the capacitive element 250 in FIG. 7D.

As illustrated in FIG. 11A and FIG. 11B, the uppermost portion of the conductor 156 of the capacitive element 250 may be substantially level with the top surface of the insulator 282.

As illustrated in FIG. 11A and FIG. 11B, part of the insulator 153 may be exposed from the conductor 160 in the capacitive element 250.

As illustrated in FIG. 11B, part of the conductor 242b may be exposed from the conductor 156 of the capacitive element 250 in a cross-sectional view in the channel width direction.

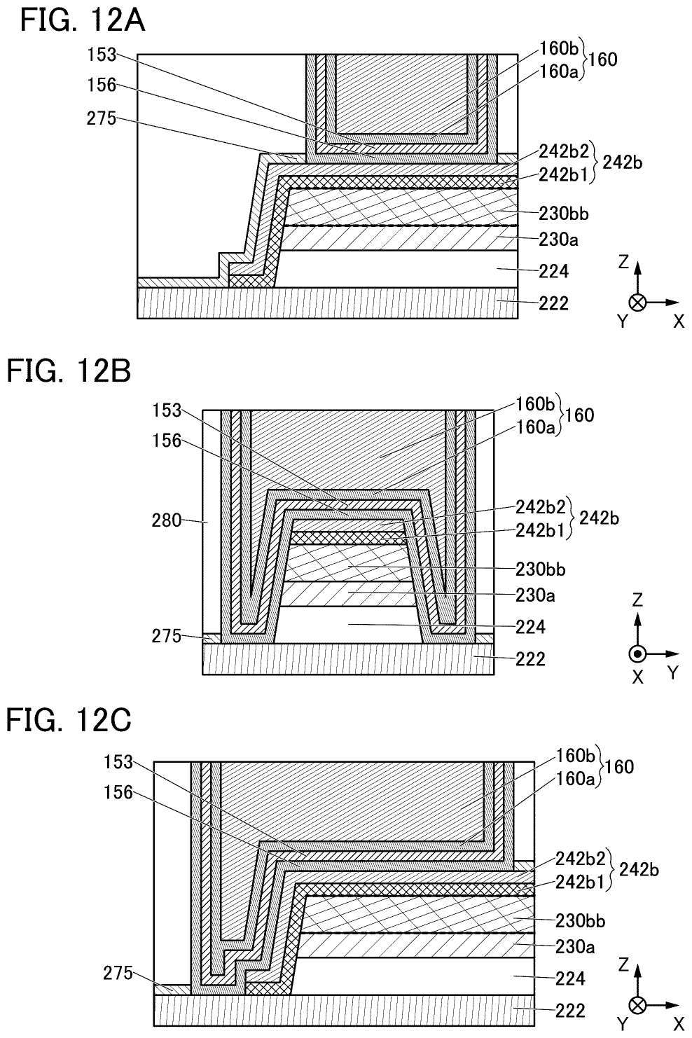

The capacitive element 250 may have a structure illustrated in FIG. 12A and FIG. 12B. Here, FIG. 12A is an enlarged view corresponding to the capacitive element 250 in FIG. 7B, and FIG. 12B is an enlarged view corresponding to the capacitive element 250 in FIG. 7D.

As illustrated in FIG. 12A, the insulator 224, the oxide 230a, and the oxide 230b may be formed under the conductor 242b in the opening 158 in the capacitive element 250. In that case, as illustrated in FIG. 12B, the conductor 156 is preferably provided in contact with the side surface of the insulator 224, the side surface of the oxide 230a, the side surface of the oxide 230b, and the side surface of the conductor 242. This allows the capacitive element 250 to be formed along the side surface of the insulator 224, the side surface of the oxide 230a, the side surface of the oxide 230b, and the side surface of the conductor 242; thus, the capacitance of the capacitive element 250 can be increased.

Alternatively, the capacitive element 250 may have a shape illustrated in FIG. 12C, for example. Specifically, part of the opening 158 overlaps with the conductor 242b as in the structure illustrated in FIG. 11A, and another part thereof overlaps with the conductor 242b, the oxide 230b, the oxide 230a, and the insulator 224 as in the structure illustrated in FIG. 12A.

Although FIG. 10A to FIG. 12C each illustrate a structure in which the sidewall of the opening 158 is substantially perpendicular to the top surface of the insulator 222, the present invention is not limited thereto. The sidewall of the opening 158 may have a tapered shape. When the sidewall of the opening 158 has a tapered shape, the coverage with the insulator 153 and the like can be improved in a later step, so that defects such as a void can be reduced.

The above is the description of the capacitive element 250.

### [Structure Example of Through Electrode]

The conductor 240 is provided in contact with the inner wall of the opening 206 formed in the insulator 285, the insulator 280, the insulator 275, the conductor 242a, the insulator 216, and the insulator 212. The conductor 240 includes a region in contact with the top surface of the conductor 209. Note that part of the conductor 242a can be regarded as protruding in the opening 206.

The conductor 240 functions as a plug or a wiring for electrically connecting the transistor 200 to a circuit element such as a switch, a transistor, a capacitive element, an inductor, a resistor, or a diode, a wiring, an electrode, or a terminal. The conductor 240 can be referred to as a through electrode.

The conductor 240 preferably has a stacked-layer structure (a two-layer structure) of the conductor 240a and the conductor 240b. For example, as illustrated in FIG. 7B, the conductor 240 can have a structure in which the conductor 240a is provided in contact with the inner wall of the above opening and the conductor 240b is provided inside the conductor 240a. That is, the conductor 240a is located in the vicinity of the insulator 285, the insulator 280, the insulator 275, the conductor 242a, the insulator 216, and the insulator 212.

Here, the conductor 240a is preferably formed by a film formation method that enables favorable coverage, such as an ALD method. When the conductor 240a is formed in this manner, the rough shape of the conductor 240a is substantially the same as the shape formed by the inner wall of the opening 206. The conductor 240a is illustrated to have a uniform thickness in FIG. 7B and the like; however, in a portion shaded by the conductor 242a, for example, the conductor 240a may have a small thickness or is not necessarily formed.

A conductive material having a function of inhibiting passage of impurities such as water and hydrogen is preferably used for the conductor 240a. For example, tantalum, tantalum nitride, titanium, titanium nitride, ruthenium, ruthenium oxide, or the like may be used as a single layer or stacked layers. Moreover, impurities such as water and hydrogen included in a layer above the insulator 282 can be inhibited from entering the oxide 230 through the conductor 240.

The conductor 240 also functions as a wiring and thus is preferably formed using a conductor having high conductivity. For example, a conductive material containing tungsten, copper, or aluminum as its main component can be used for the conductor 240b.

For example, it is preferable to use titanium nitride for the conductor 240a and tungsten for the conductor 240b. In that case, the conductor 240a is a conductor that contains titanium and nitrogen, and the conductor 240b is a conductor that contains tungsten.

Although the transistor 200 having a structure in which the conductor 240 has a two-layer structure of the conductor 240a and the conductor 240b is described, the present invention is not limited thereto. For example, the conductor 240 may have a single-layer structure or a multilayer structure of three or more layers. In the case of a multilayer structure, layers may be distinguished by ordinal numbers corresponding to the formation order. Although not illustrated in FIG. 7B, the level of the top surface of the conductor 240 is higher than the level of the top surface of the insulator 285 in some cases.

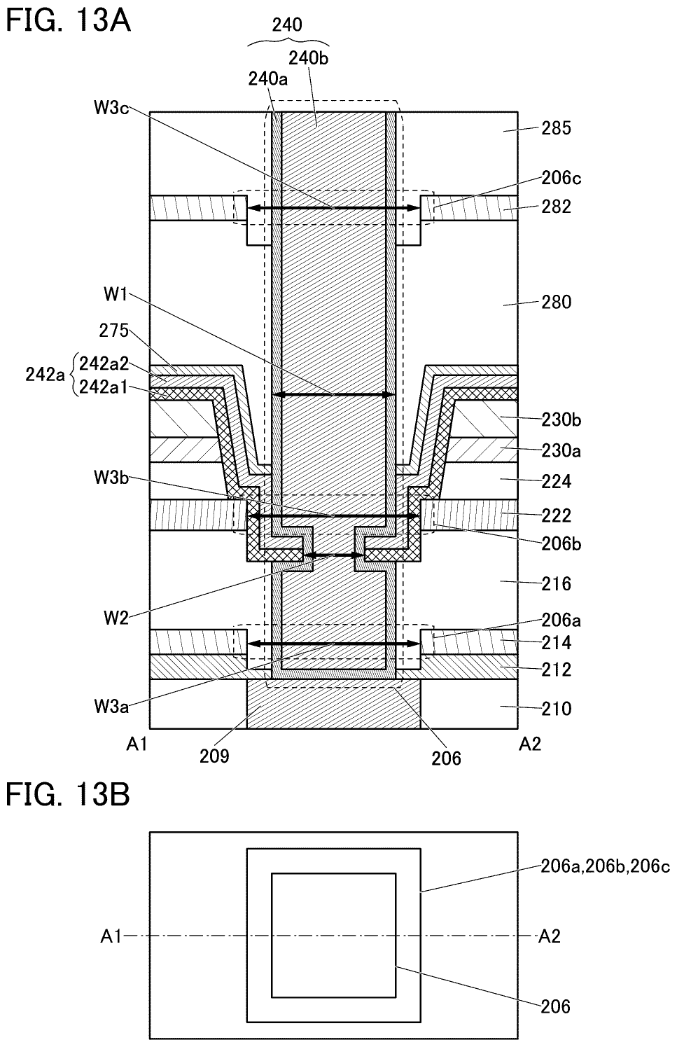

FIG. 13A is an enlarged view of a region in contact with the conductor 240 and the vicinity thereof. As illustrated in FIG. 13A, the conductor 240 is located in the opening 206 formed in the insulator 285, the insulator 280, the insulator 275, the conductor 242a, the insulator 216, and the insulator 212. The insulator 214 provided between the insulator 212 and the insulator 216 includes an opening 206a. The insulator 222 provided between the insulator 216 and the insulator 275 includes an opening 206b. The insulator 282 provided between the insulator 280 and the insulator 285 includes an opening 206c. In the cross-sectional view illustrated in FIG. 13A, the width of the opening 206 is referred to as a width W1, the width of the opening 206a is referred to as a width W3a, the width of the opening 206b is referred to as a width W3b, and the width of the opening 206c is referred to as a width W3c.

Here, FIG. 13B is a plan view corresponding to FIG. 13A. As illustrated in FIG. 13B, the opening 206 preferably overlaps with at least part of the opening 206a, at least part of the opening 206b, and at least part of the opening 206c in a plan view. Furthermore, as illustrated in FIG. 13B, the opening 206 is preferably located inside the opening 206a, inside the opening 206b, and inside the opening 206c in a plan view. In that case, as illustrated in FIG. 13A, the width W1 is smaller than each of the width W3a, the width W3b, and the width W3c. Thus, the side surfaces of the insulator 212, the insulator 216, the insulator 275, the insulator 280, and the insulator 285 protrude beyond the side surfaces of the insulator 214, the insulator 222, and the insulator 282 toward the conductor 240 side.

When the opening 206 has the above structure, the opening 206 can be formed without etching the insulator 214, the insulator 222, and the insulator 282. As described above, the insulator 214, the insulator 222, and the insulator 282 are insulating layers each formed using what is called a hardly-etched material, such as aluminum oxide or hafnium oxide, for example. When such an insulating layer formed using a hardly-etched material is sandwiched between regions where the openings 206 are formed, the etching rate of the insulating layer formed using a hardly-etched material differs greatly from that of the other insulating layers; thus, an abnormal shape might be formed in the opening 206.

In this embodiment, the opening 206a, the opening 206b, and the opening 206c are formed in the insulator 214, the insulator 222, and the insulator 282, respectively, to overlap with the regions where the openings 206 are formed. This eliminates the need to etch the insulating layer formed using a hardly-etched material in forming the opening 206; thus, the opening 206 can be manufactured with high yield and the productivity of the storage device can be improved. A sidewall of the opening 206 can be preferably provided substantially perpendicular to a substrate surface, the top surface of the conductor 209, or the like. This can reduce the area occupied by the opening 206 and the area occupied by one memory cell, so that the storage capacity per area of the storage device can be increased.

As illustrated in FIG. 13A, a depressed portion is formed on the top surface of the insulator 280 to overlap with the opening 206c of the insulator 282 in some cases. Furthermore, the insulator 285 is formed to fill the opening 206c and the depressed portion in some cases. In that case, the insulator 285 is formed between the insulator 282 and the conductor 240.

In the A1-A2 direction, the conductor 240 includes a region with the width W1 and a region with a width W2 as illustrated in FIG. 13A. The width W1 corresponds to the width of the conductor 240 in contact with the sidewall of the opening 206. The width W2 corresponds to the width of the opening included in the conductor 242a. In the case where the conductor 242a on the transistor 200a side and the conductor 242a on the transistor 200b side are provided to be separated from each other as described above, the width W2 corresponds to the distance from the conductor 242a on the transistor 200a side to the conductor 242a on the transistor 200b side.

As illustrated in FIG. 13A, the width W1 is preferably larger than the width W2. In this structure, the conductor 240 is in contact with, at least, part of the top surface and part of the side surface of the conductor 242a. Accordingly, the area of the region where the conductor 240 and the conductor 242a are in contact with each other can be increased. Here, as illustrated in FIG. 13A, the side surface of the conductor 242a protrudes from the side surfaces of the insulator 280 and the insulator 275 in the opening 206. Note that in this specification and the like, the contact between the conductor 240 and the conductor 242a is referred to as a top side contact in some cases.

As illustrated in FIG. 13A, the conductor 240 may be in contact with part of the bottom surface of the conductor 242a. With this structure, the area of the region where the conductor 240 and the conductor 242a are in contact with each other can be further increased. Here, as illustrated in FIG. 13A, the side surface of the conductor 242a protrudes from the side surface of the insulator 216 in the opening 206.

When the contact area between the conductor 240 and the conductor 242a is increased as described above, the contact resistance can be reduced. As a result, the storage device of the present invention can have increased operation speed and reduced power consumption.

In the case where a depressed portion overlapping with the opening 206b is formed on the top surface of the insulator 216 as described above, the conductor 242al and the conductor 242a2 are formed to fill the depressed portion. In this case, the conductor 242al is in contact with the top surface and the side surface of the oxide 230b, the side surface of the oxide 230a, the side surface of the insulator 224, the side surface of the insulator 222, and the top surface and a side surface of the depressed portion of the insulator 216.

The conductor 209 functions as part of a circuit element such as a switch, a transistor, a capacitive element, an inductor, a resistor, or a diode, a wiring, an electrode, or a terminal.

The insulator 210 functions as an interlayer film. As the insulator 210, an insulator that can be used as the insulator 214, the insulator 216, or the like described above may be used.

The above is the description of the through electrode.

### <Component Material of Semiconductor Device>

Component materials that can be used for the semiconductor device are described below.

### <<Substrate>>

As the substrate where the transistor 200 is formed, an insulator substrate, a semiconductor substrate, or a conductor substrate is used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material and a compound semiconductor substrate including silicon carbide, silicon germanium, gallium arsenide, indium phosphide, zinc oxide, or gallium oxide. Another example is a semiconductor substrate having an insulator region in the semiconductor substrate described above, e.g., an SOI (Silicon On Insulator) substrate. Examples of the conductor substrate include a graphite substrate, a metal substrate, an alloy substrate, and a conductive resin substrate. Other examples include a substrate including a nitride of a metal and a substrate including an oxide of a metal. Other examples include an insulator substrate provided with a conductor or a semiconductor, a semiconductor substrate provided with a conductor or an insulator, and a conductor substrate provided with a semiconductor or an insulator. Alternatively, these substrates provided with elements may be used. Examples of the element provided for the substrate include a capacitive element, a resistor, a switching element, a light-emitting element, and a storage element.

### <<Insulator>>

Examples of the insulator include an insulating oxide, an insulating nitride, an insulating oxynitride, an insulating nitride oxide, an insulating metal oxide, an insulating metal oxynitride, and an insulating metal nitride oxide.

As miniaturization and high integration of transistors progress, for example, a problem such as a leakage current may arise because of a thinner gate insulator. When a high-k material is used for the insulator functioning as a gate insulator, the voltage at the time of the operation of the transistor can be reduced while the physical thickness is maintained. In contrast, when a material with a low relative permittivity is used for the insulator functioning as an interlayer film, parasitic capacitance generated between wirings can be reduced. Thus, a material is preferably selected depending on the function of the insulator.

Examples of the insulator with a high relative permittivity include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the insulator with a low relative permittivity include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

When a transistor including a metal oxide is surrounded by an insulator having a function of inhibiting passage of oxygen and impurities such as hydrogen, the transistor can have stable electrical characteristics. As the insulator having a function of inhibiting passage of oxygen and impurities such as hydrogen, for example, a metal oxide such as aluminum oxide, magnesium oxide, gallium oxide, germanium oxide, yttrium oxide, zirconium oxide, lanthanum oxide, neodymium oxide, hafnium oxide, or tantalum oxide; or a metal nitride such as aluminum nitride, silicon nitride oxide, or silicon nitride can be used.

The insulator functioning as the gate insulator is preferably an insulator including a region containing oxygen to be released by heating. For example, when a structure is employed in which silicon oxide or silicon oxynitride including a region containing oxygen to be released by heating is in contact with the oxide 230, oxygen vacancies included in the oxide 230 can be compensated for.

### <<Conductor>>

As the conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are conductive materials that are less likely to be oxidized or materials that maintain their conductivity even after absorbing oxygen. Alternatively, a semiconductor having high electrical conductivity, typified by polycrystalline silicon containing an impurity element such as phosphorus, or silicide such as nickel silicide may be used.

It is particularly preferable to use, for the conductor functioning as the gate electrode, a conductive material containing oxygen and a metal element contained in the metal oxide where the channel is formed. A conductive material containing the above metal element and nitrogen may be used. For example, a conductive material containing nitrogen, such as titanium nitride or tantalum nitride, may be used. Indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon is added may be used. Indium gallium zinc oxide containing nitrogen may be used. With the use of such a material, hydrogen contained in the metal oxide where the channel is formed can be captured in some cases. Alternatively, hydrogen entering from an external insulator or the like can be captured in some cases.

### <<Metal Oxide>>

The oxide 230 is preferably formed using a metal oxide (an oxide semiconductor) functioning as a semiconductor. A metal oxide that can be used for the oxide 230 according to the present invention is described below.

The metal oxide preferably contains at least indium or zinc. In particular, indium and zinc are preferably contained. Furthermore, aluminum, gallium, yttrium, tin, or the like is preferably contained in addition to them. Furthermore, one or more selected from boron, titanium, iron, nickel, germanium, zirconium, molybdenum, lanthanum, cerium, neodymium, hafnium, tantalum, tungsten, magnesium, cobalt, and the like may be contained.

Here, the case where the metal oxide is an In-M-Zn oxide containing indium, the element M, and zinc is considered. The element M is aluminum, gallium, yttrium, or tin. Other elements that can be used as the element M include boron, titanium, iron, nickel, germanium, zirconium, molybdenum, lanthanum, cerium, neodymium, hafnium, tantalum, tungsten, magnesium, and cobalt. Note that two or more of the above elements may be used in combination as the element M in some cases. In particular, the element M is preferably one or more selected from gallium, aluminum, yttrium, and tin.

It is particularly preferable to use an oxide containing indium (In), gallium (Ga), and zinc (Zn) (also referred to as IGZO) for the semiconductor layer of the transistor. Alternatively, an oxide containing indium (In), aluminum (Al), and zinc (Zn) (also referred to as IAZO) may be used for the semiconductor layer of the transistor. Alternatively, an oxide containing indium (In), aluminum (Al), gallium (Ga), and zinc (Zn) (IAGZO or IGAZO) may be used for the semiconductor layer.

Note that in this specification and the like, a metal oxide containing nitrogen is also generally termed as a metal oxide in some cases. A metal oxide containing nitrogen may be referred to as a metal oxynitride.

Hereinafter, an oxide containing indium (In), gallium (Ga), and zinc (Zn) is described as an example of the metal oxide. Note that an oxide containing indium (In), gallium (Ga), and zinc (Zn) may be referred to as In—Ga—Zn oxide.

### <Classification of Crystal Structure>

Amorphous (including completely amorphous), CAAC (c-axis-aligned crystalline), nc (nanocrystalline), single crystal, and polycrystalline (poly crystal) structures can be given as examples of a crystal structure of an oxide semiconductor.

### <<Structure of Oxide Semiconductor>>

Note that oxide semiconductors might be classified in a manner different from the above-described one when classified in terms of the structure. Oxide semiconductors are classified into a single crystal oxide semiconductor and a non-single-crystal oxide semiconductor, for example. Examples of the non-single-crystal oxide semiconductor include the above-described CAAC-OS and nc-OS. Other examples of the non-single-crystal oxide semiconductor include a polycrystalline oxide semiconductor, an amorphous-like oxide semiconductor (a-like OS), and an amorphous oxide semiconductor.

Here, the above-described CAAC-OS, nc-OS, and a-like OS are described in detail.

### [CAAC-OS]

The CAAC-OS is an oxide semiconductor that has a plurality of crystal regions each of which has c-axis alignment in a particular direction. Note that the particular direction refers to the thickness direction of a CAAC-OS film, the normal direction of the surface where the CAAC-OS film is formed, or the normal direction of the surface of the CAAC-OS film. The crystal region refers to a region having a periodic atomic arrangement. Note that when an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that distortion refers to a portion where the orientation of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

[nc-OS]

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a minute crystal. Note that the size of the minute crystal is, for example, greater than or equal to 1 nm and less than or equal to 10 nm, particularly greater than or equal to 1 nm and less than or equal to 3 nm; thus, the minute crystal is also referred to as a nanocrystal. Furthermore, there is no regularity of crystal orientation between different nanocrystals in the nc-OS.

[a-Like OS]

The a-like OS is an oxide semiconductor having a structure between those of the nc-OS and the amorphous oxide semiconductor. The a-like OS includes a void or a low-density region. That is, the a-like OS has lower crystallinity than the nc-OS and the CAAC-OS. Moreover, the a-like OS has a higher hydrogen concentration in the film than the nc-OS and the CAAC-OS.

### <Transistor Including Oxide Semiconductor>

Next, the case where the above oxide semiconductor is used for a transistor is described.

When the above oxide semiconductor is used for a transistor, a transistor with high field-effect mobility can be achieved. In addition, a transistor with high reliability can be achieved.

An oxide semiconductor having a low carrier concentration is preferably used for a transistor. For example, the carrier concentration of an oxide semiconductor is lower than or equal to 1×10¹⁷ cm⁻³, preferably lower than or equal to 1×10¹⁵ cm⁻³, further preferably lower than or equal to 1×10¹³ cm⁻³, still further preferably lower than or equal to 1×10¹¹ cm⁻³, yet still further preferably lower than 1×10¹⁰ cm⁻³, and higher than or equal to 1×10⁻⁹ cm⁻³. In order to reduce the carrier concentration in an oxide semiconductor film, the impurity concentration in the oxide semiconductor film is reduced so that the density of defect states can be reduced.

### <<Other Semiconductor Materials>>

A semiconductor material that can be used for the oxide 230 is not limited to the above metal oxides. A semiconductor material that has a band gap (a semiconductor material that is not a zero-gap semiconductor) may be used for the oxide 230. For example, a single element semiconductor such as silicon, a compound semiconductor such as gallium arsenide, or a layered substance functioning as a semiconductor (also referred to as an atomic layer substance, a two-dimensional material, or the like) is preferably used as a semiconductor material. In particular, a layered substance functioning as a semiconductor is favorably used as a semiconductor material.

Here, in this specification and the like, the layered substance generally refers to a group of materials having a layered crystal structure. In the layered crystal structure, layers formed by covalent bonding or ionic bonding are stacked with bonding such as the Van der Waals force, which is weaker than covalent bonding or ionic bonding. The layered substance has high electrical conductivity in a unit layer, that is, high two-dimensional electrical conductivity. When a material that functions as a semiconductor and has high two-dimensional electrical conductivity is used for the channel formation region, the transistor can have a high on-state current.

Examples of the layered substance include graphene, silicene, and chalcogenide. Chalcogenide is a compound containing chalcogen. Chalcogen is a general term for elements belonging to Group 16 and includes oxygen, sulfur, selenium, tellurium, polonium, and livermorium. Examples of chalcogenide include transition metal chalcogenide and chalcogenide of Group 13 elements.

For the oxide 230, transition metal chalcogenide functioning as a semiconductor is preferably used, for example. Specific examples of the transition metal chalcogenide that can be used for the oxide 230 include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂). When the transition metal chalcogenide is used for the oxide 230, a semiconductor device with a high on-state current can be provided.

### <Modification Example of Semiconductor Device>

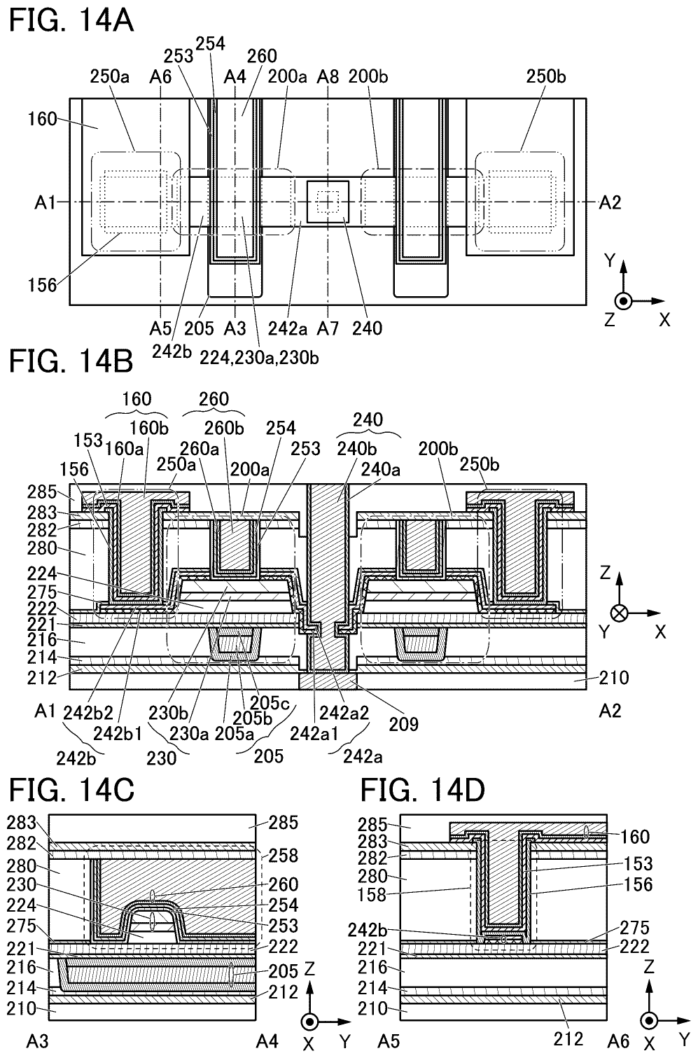

Examples of the semiconductor device of one embodiment of the present invention are described below with reference to FIG. 14A to FIG. 16B.

The semiconductor device illustrated in FIG. 14A to FIG. 14D is a modification example of the semiconductor device illustrated in FIG. 7A to FIG. 7D. The semiconductor device illustrated in FIG. 14A to FIG. 14D differs from the semiconductor device illustrated in FIG. 7A to FIG. 7D in including an insulator 283 and an insulator 221.

The insulator 283 is provided between the insulator 282 and the insulator 285. In this case, part of the conductor 156 and part of the insulator 153 are in contact with the top surface of the insulator 283. As the insulator 283, the above-described insulator that is less likely to allow diffusion of hydrogen is preferably used.

The insulator 282, which has a function of capturing impurities such as hydrogen, is provided in contact with the insulator 280 in a region sandwiched between the insulator 212 and the insulator 283. Accordingly, impurities such as hydrogen included in the insulator 280 and the like can be captured and the amount of hydrogen in the region can be constant. Aluminum oxide having an amorphous structure is particularly preferably used for the insulator 282.

Here, the opening 206c is preferably formed in the insulator 283, as well as in the insulator 282.

Although FIG. 14A to FIG. 14D illustrate the transistor 200 having a structure in which the insulator 283 is provided to have a single-layer structure, the present invention is not limited thereto. For example, the insulator 283 may be provided to have a stacked-layer structure of two or more layers.

The insulator 221 is provided between the insulator 222 and each of the insulator 216 and the conductor 205. Hydrogen is preferably less likely to diffuse into the insulator 221. This can inhibit diffusion of hydrogen into the transistor 200 from below the insulator 221. Note that a structure in which the insulator 221 also functions as the insulator 212 and the insulator 212 is not provided may be employed. As the insulator 221, an insulator that can be used as the insulator 275 described above may be used.

Here, an opening is sometimes formed in the insulator 221 to overlap with the opening 206b formed in the insulator 222. In the case where the insulator 221 has a large thickness, a depressed portion is sometimes formed to overlap with the opening 206b formed in the insulator 222.

As illustrated in FIG. 14B and FIG. 14C, the conductor 205 may have a three-layer structure of the conductor 205a, the conductor 205b, and a conductor 205c.

As in the conductor 205a, hydrogen is preferably less likely to diffuse into the conductor 205c. In that case, since the conductor 205b can be surrounded by the conductor 205a and the conductor 205c, impurities such as hydrogen included in the conductor 205b can be prevented from diffusing into the oxide 230 through the insulator 216, the insulator 224, and the like. Furthermore, oxidation of the conductor 205b can be inhibited.

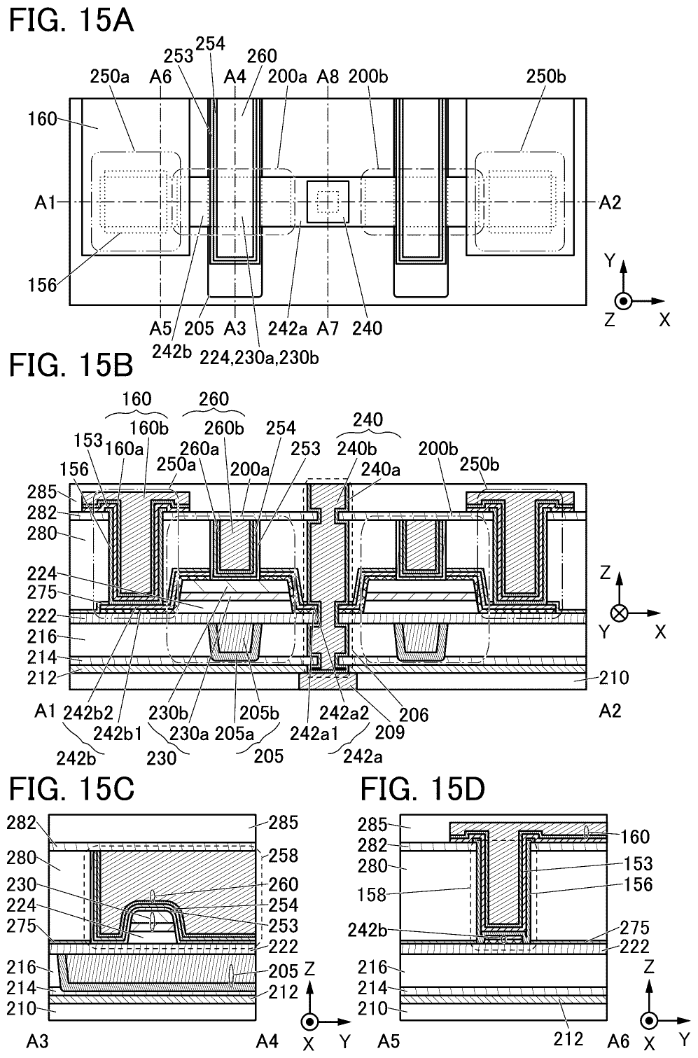

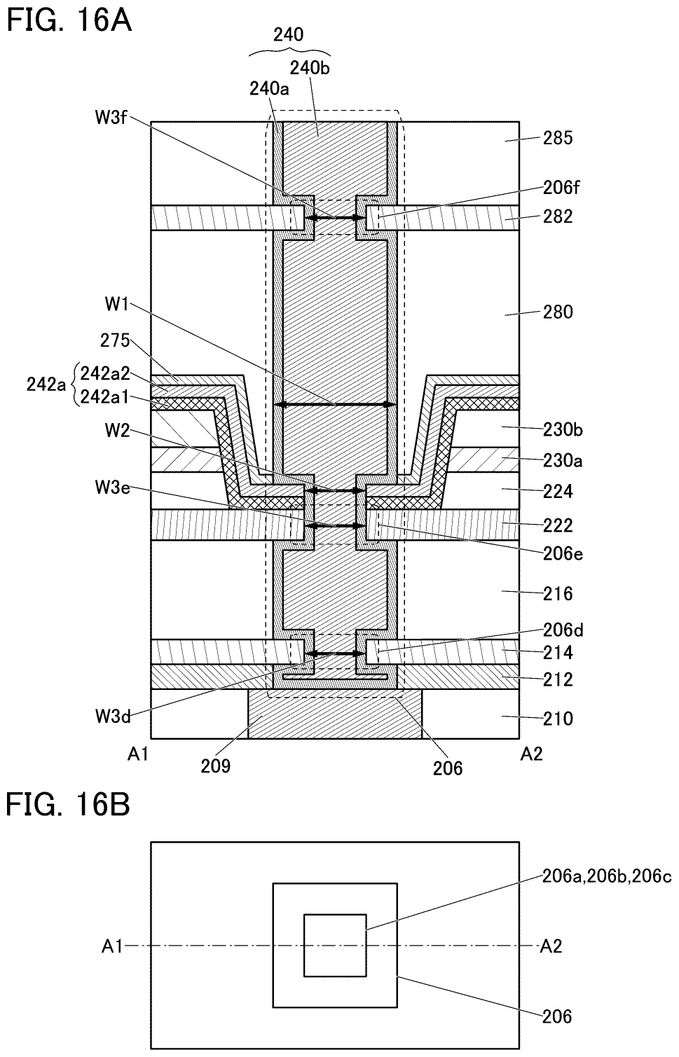

The semiconductor device illustrated in FIG. 15A to FIG. 15D is a modification example of the semiconductor device illustrated in FIG. 7A to FIG. 7D. FIG. 16A is an enlarged cross-sectional view of the vicinity of the conductor 240 illustrated in FIG. 15B, and FIG. 16B is a plan view corresponding to FIG. 16A. The semiconductor device illustrated in FIG. 15 and FIG. 16 is different from the semiconductor device illustrated in FIG. 7A to FIG. 7D in that an opening 206d is included in the insulator 214, an opening 206e is included in the insulator 222, and an opening 206f is included in the insulator 282. In the cross-sectional view illustrated in FIG. 16A, the width of the opening 206d is referred to as a width W3d, the width of the opening 206e is referred to as a width W3e, and the width of the opening 206f is referred to as a width W3f.

As illustrated in FIG. 16B, the opening 206d, the opening 206e, and the opening 206f are preferably located inside the opening 206 in a plan view. In that case, as illustrated in FIG. 16A, each of the width W3d, the width W3e, and the width W3f is smaller than the width W1. Thus, the side surfaces of the insulator 214, the insulator 222, and the insulator 282 protrude beyond the side surfaces of the insulator 212, the insulator 216, the insulator 275, the insulator 280, and the insulator 285 toward the conductor 240 side.

According to one embodiment of the present invention, a novel transistor can be provided. Alternatively, a semiconductor device that can be miniaturized or highly integrated can be provided. Alternatively, a semiconductor device with favorable frequency characteristics can be provided. Alternatively, a semiconductor device with high operation speed can be provided. Alternatively, a semiconductor device with a small variation in transistor characteristics can be provided. Alternatively, a semiconductor device having favorable electrical characteristics can be provided. Alternatively, a semiconductor device with favorable reliability can be provided. Alternatively, a semiconductor device with a high on-state current can be provided. Alternatively, a semiconductor device with a high field-effect mobility can be provided. Alternatively, a semiconductor device with low power consumption can be provided.

The semiconductor device including the transistor 200 and the capacitive element 250 and described in this embodiment can be used as a memory cell of a storage device. The transistor 200 is a transistor in which a channel is formed in a semiconductor layer including an oxide semiconductor (hereinafter referred to as an OS transistor in some cases). Since the transistor 200 has a low off-state current, a storage device that uses the transistor 200 can retain stored contents for a long time. In other words, the storage device does not require refresh operation or has extremely low frequency of the refresh operation, which leads to a sufficient reduction in power consumption of the storage device. The transistor 200 has high frequency characteristics and thus enables the storage device to perform reading and writing at high speed.

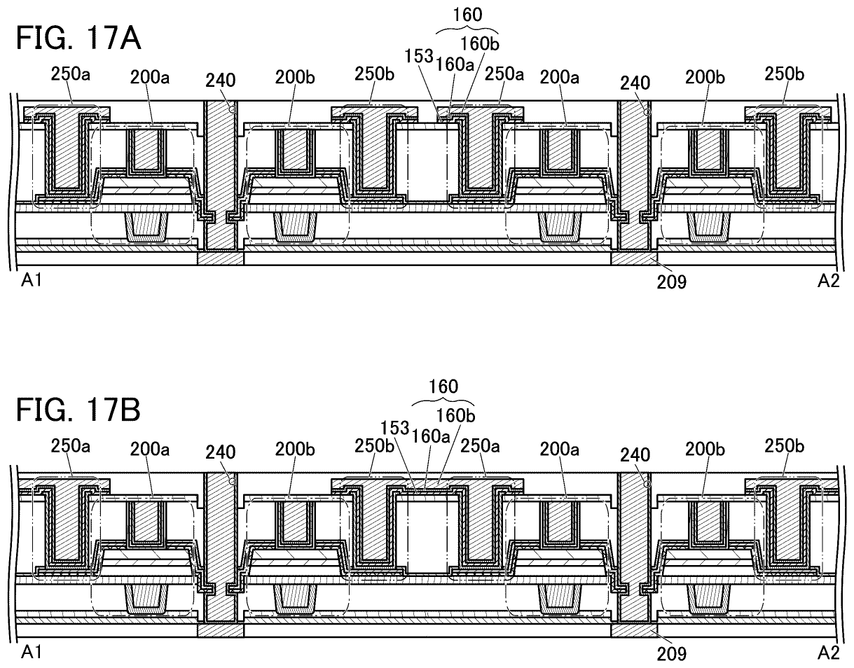

When the semiconductor devices each of which includes the transistor 200 and the capacitive element 250 and each of which can be used as a memory cell are arranged in a matrix, a memory cell array can be formed. As an example of the memory cell array, FIG. 17A illustrates an example in which a plurality of the memory cells are arranged in the A1-A2 direction.

Although FIG. 17A illustrates a structure in which the conductor 160 of the capacitive element 250a and the conductor 160 of the capacitive element 250b that are adjacent to each other are separated, the present invention is not limited thereto. For example, as illustrated in FIG. 17B, a structure may be employed in which the conductor 160 of the capacitive element 250a and the conductor 160 of the capacitive element 250b that are adjacent to each other are integrated. In that case, the insulator 153 of the capacitive element 250a and the insulator 153 of the capacitive element 250b that are adjacent to each other may be integrated.

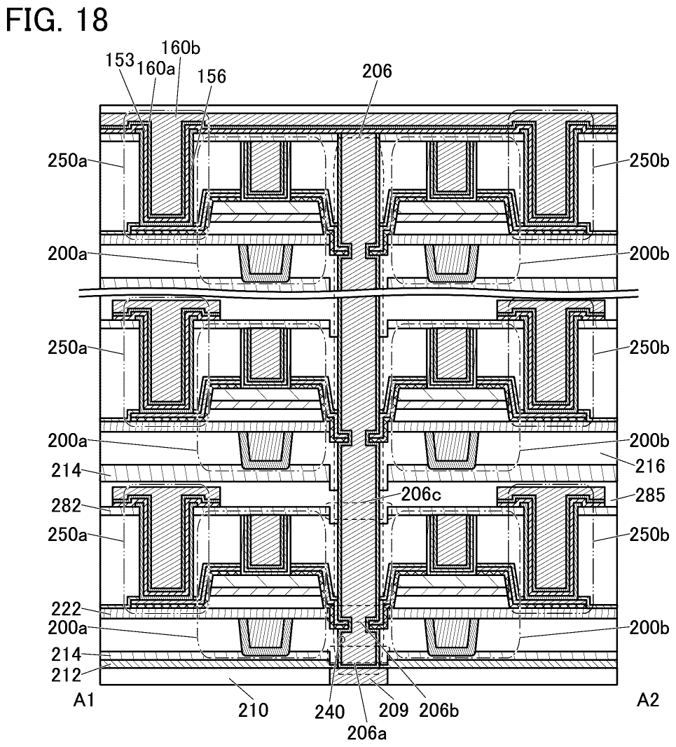

Furthermore, the memory cells may be stacked instead of being arranged over a plane. FIG. 18 is a cross-sectional view of a structure in which a plurality of layers each including the above memory cells are stacked. In this case, it can be said that the storage device includes a plurality of layers including memory cells each including the transistor 200 and the capacitive element 250 and has a structure in which the plurality of layers are stacked. Alternatively, it can be said that the storage device includes a plurality of layers each including at least two memory cells and the plurality of layers are stacked. Here, the memory cell including the transistor 200a and the capacitive element 250a is referred to as a first memory cell, and the memory cell including the transistor 200b and the capacitive element 250b is referred to as a second memory cell in some cases.

Note that although the insulator 212 is provided in the layer including the memory cells that is in contact with the insulator 210 and the conductor 209 in FIG. 18, the insulator 212 is not provided in layers thereabove. Note that without being limited to the above, the insulator 212 may be provided in all the layers including the memory cells.

Although FIG. 18 illustrates the structure in which the plurality of layers each including the memory cells are stacked, one embodiment of the present invention is not limited thereto. For example, a plurality of layers each including the memory cell array illustrated in FIG. 17A or FIG. 17B may be stacked. In that case, it can be said that the storage device includes the plurality of layers each including the memory cell array provided with the memory cells each including the transistor 200 and the capacitive element 250 and the plurality of layers are stacked.

As illustrated in FIG. 18, each of the plurality of layers included in the storage device includes the opening 206. Specifically, each of the plurality of layers included in the storage device includes the opening 206 between the first memory cell and the second memory cell. More specifically, each of the plurality of layers included in the storage device includes the opening 206 between the transistor 200a and the transistor 200b. The openings 206 included in the plurality of layers include a region where the openings 206 overlap with each other. Since the openings 206 included in the plurality of layers include the region where the openings 206 overlap with each other, the openings 206 included in the plurality of layers can be formed at a time. Accordingly, the manufacturing process of the storage device can be simplified, and the productivity can be improved.

In the uppermost memory cell array, the insulator 153, the conductor 160a, and the conductor 160b are provided to be shared by the capacitive element 250a and the capacitive element 250b. The insulator 153, the conductor 160a, and the conductor 160b each include a region overlapping with the transistor 200a, the transistor 200b, the capacitive element 250a, and the capacitive element 250b, which are located therebelow.

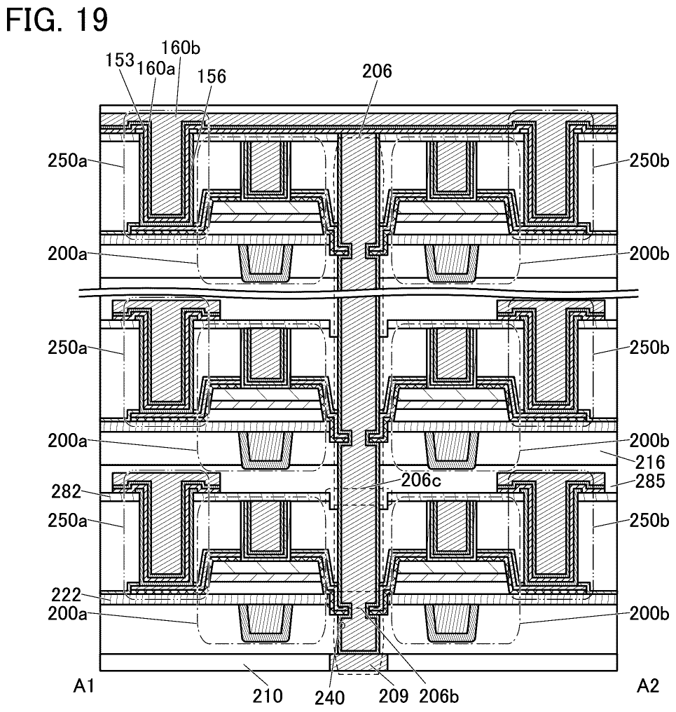

Although the storage device illustrated in FIG. 18 has a structure in which the insulator 214 is provided between the insulator 285 in a layer including a lower memory cell and the insulator 216 in a layer including an upper memory cell, the present invention is not limited thereto. For example, as illustrated in FIG. 19, a structure may be employed in which the insulator 214 is not provided between the insulator 285 in the layer including the lower memory cell and the insulator 216 in the layer including the upper memory cell and the insulator 285 in the layer including the lower memory cell is in contact with the insulator 216 in the layer including the upper memory cell. With such a structure, the formation of the insulator 214 and the formation of the opening 206a are not necessarily performed in the manufacturing process of the layers including the memory cells. Accordingly, the manufacturing process of the storage device can be simplified, and the productivity can be improved.

Although the storage device illustrated in FIG. 19 has a structure in which the insulator 285 in the layer including the lower memory cell and the insulator 216 in the layer including the upper memory cell are separate insulators, the present invention is not limited thereto. For example, the insulator 285 in the layer including the lower memory cell may be integrated with the insulator 216 in the layer including the upper memory cell.

Although the storage device illustrated in FIG. 19 has a structure in which neither the insulator 214 nor the insulator 212 is provided also in the layer including the memory cells that is in contact with the insulator 210 and the conductor 209, the present invention is not limited thereto. For example, in the storage device illustrated in FIG. 19, only the layer including the memory cells that is in contact with the insulator 210 and the conductor 209 may be provided with the insulator 214 and the insulator 212 as in FIG. 18. Such a structure can reduce diffusion of impurities or the like into the layer including the memory cells from below a layer including the insulator 210 and the conductor 209.

When a plurality of memory cells are stacked as illustrated in FIG. 18 and FIG. 19, cells can be integrally placed without increasing the footprint of the memory cell arrays. In other words, a 3D memory cell array can be formed.

At least part of the structure, method, and the like described in this embodiment can be implemented in an appropriate combination with any of those in the other embodiments described in this specification.

### Embodiment 3

In this embodiment, specific structure examples of storage devices using the semiconductor device described in the above embodiment as memory cells are described. In this embodiment, structure examples of storage devices in which a layer including a functional circuit having functions of amplifying and outputting a data potential retained in a memory cell is provided between stacked layers including memory cells are described.

### [Structure Example of Storage Device]

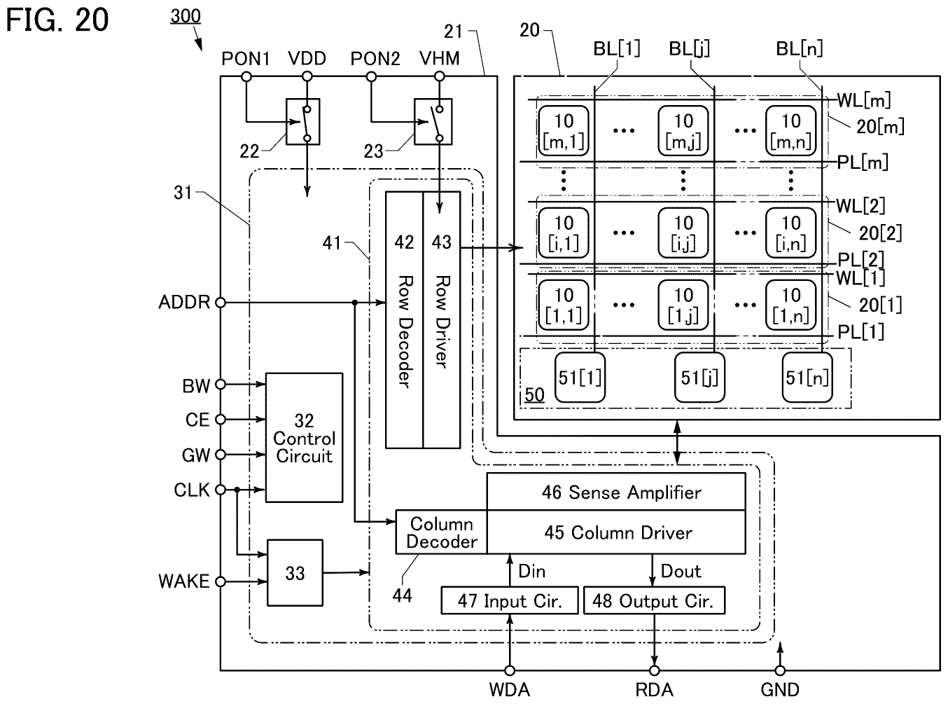

FIG. 20 is a block diagram illustrating a structure example of a storage device 300 of one embodiment of the present invention. The storage device 300 illustrated in FIG. 20 includes a driver circuit 21 and a memory array 20. The memory array 20 includes a functional layer 50 including a plurality of memory cells 10 and a plurality of functional circuits 51.

FIG. 20 illustrates an example in which the memory array 20 includes the plurality of memory cells 10 arranged in a matrix of m rows and n columns (each of m and n is an integer greater than or equal to 2). The functional circuit 51 is provided for each of the wirings BL functioning as bit lines, for example. The plurality of functional circuits 51 corresponding to n of the wirings BL are provided in the example illustrated in FIG. 20.

In FIG. 20, the memory cell 10 in the first row and the first column is referred to as a memory cell 10[1,1], and the memory cell 10 in the m-th row and the n-th column is referred to as a memory cell 10[m,n]. In this embodiment and the like, a given row is denoted as an i-th row in some cases. A given column is denoted as a j-th column in some cases. Thus, i is an integer greater than or equal to 1 and less than or equal to m, and j is an integer greater than or equal to 1 and less than or equal to n. In this embodiment and the like, the memory cell 10 in the i-th row and the j-th column is referred to as a memory cell 10[i,j]. Note that in this embodiment and the like, “i+a” (a is a positive or negative integer) is not below 1 and does not exceed m. Similarly, “j+a” is not below 1 and does not exceed n.

The memory array 20 includes m of the wirings WL extending in the row direction, m of the wirings PL extending in the row direction, and the n wirings BL extending in the column direction. In this embodiment and the like, the first (first row) wiring WL is referred to as a wiring WL[1] and the m-th (m-th row) wiring WL is referred to as a wiring WL[m]. Similarly, the first (first row) wiring PL is referred to as a wiring PL[1] and the m-th (m-th row) wiring PL is referred to as a wiring PL[m]. Similarly, the first (first column) wiring BL is referred to as a wiring BL[1] and the n-th (n-th column) wiring BL is referred to as a wiring BL[n].

The plurality of memory cells 10 provided in the i-th row are electrically connected to the wiring WL in the i-th row (wiring WL[i]) and the wiring PL in the i-th row (wiring PL[i]). The plurality of memory cells 10 provided in the j-th column are electrically connected to the wiring BL in the j-th column (wiring BL[j]).

A DOSRAM (registered trademark) (Dynamic Oxide Semiconductor Random Access Memory) can be used for the memory array 20. A DOSRAM is a RAM including a 1T (transistor) 1C (capacitor) type memory cell and refers to a memory in which an access transistor is an OS transistor. An OS transistor has an extremely low current that flows between a source and a drain in an off state, that is, a leakage current. A DOSRAM can retain charge corresponding to data retained in a capacitive element (a capacitor) for a long time by turning off an access transistor (a non-conduction state). For this reason, the refresh operation frequency of a DOSRAM can be lower than that of a DRAM formed with a transistor containing silicon in its channel formation region (hereinafter also referred to as “Si transistor”). As a result, power consumption can be reduced.

The memory cells 10 can be provided in stacked layers by stacking OS transistors as described in Embodiment 1 and the like. For example, in the memory array 20 illustrated in FIG. 20, a plurality of memory arrays 20[1] to 20[m] can be provided in stacked layers. When the memory arrays 20[1] to 20[m] included in the memory array 20 are provided in a direction perpendicular to a surface of the substrate provided with the driver circuit 21, the memory density of the memory cells 10 can be increased. The memory array 20 can be formed by repeating the same manufacturing process in the perpendicular direction. The manufacturing cost of the memory array 20 in the storage device 300 can be reduced.

The wiring BL functions as a bit line for writing and reading data. The wiring WL functions as a word line for controlling on and off states (conduction and non-conduction states) of an access transistor serving as a switch. The wiring PL has a function of supplying a back gate potential to a back gate of the OS transistor, which is an access transistor, in addition to a function of a constant potential line connected to a capacitive element. Note that the wiring CL (not illustrated) can be separately provided as a wiring for transmitting the back gate potential.

The memory cell 10 included in each of the memory arrays 20[1] to 20[m] is connected to the functional circuit 51 through the wiring BL. The wiring BL can be provided in the direction perpendicular to the surface of the substrate provided with the driver circuit 21. Since the wiring BL provided to extend from the memory cells 10 included in the memory arrays 20[1] to 20[m] is provided in the direction perpendicular to the surface of the substrate, the length of the wiring between the memory array 20 and the functional circuit 51 can be shortened. Accordingly, a signal transmission distance between the two circuits connected to the bit line can be shortened, and the resistance and parasitic capacitance of the bit line can be significantly reduced, so that power consumption and signal delays can be reduced. Moreover, even when the capacitance of the capacitive elements included in the memory cells 10 is reduced, operation is possible.

The functional circuit 51 has functions of amplifying a data potential retained in the memory cell 10 and outputting the amplified data potential to a sense amplifier 46 included in the driver circuit 21 through a wiring GBL (not illustrated) described later. With this structure, a slight difference in the potential of the wiring BL can be amplified at the time of data reading. Like the wiring BL, the wiring GBL can be provided in the direction perpendicular to the surface of the substrate provided with the driver circuit 21. Since the wiring BL and the wiring GBL provided to extend from the memory cells 10 included in the memory arrays 20[1] to 20[m] are provided in the direction perpendicular to the surface of the substrate, the length of the wiring between the functional circuit 51 and the sense amplifier 46 can be shortened. Accordingly, a signal transmission distance between the two circuits connected to the wiring GBL can be shortened, and the resistance and parasitic capacitance of the wiring GBL can be significantly reduced, so that power consumption and signal delays can be reduced.

Note that the wiring BL is provided in contact with a semiconductor layer of the transistor included in the memory cell 10. Alternatively, the wiring BL is provided in contact with a region functioning as a source or a drain in the semiconductor layer of the transistor included in the memory cell 10. Alternatively, the wiring BL is provided in contact with a conductor provided in contact with the region functioning as the source or the drain in the semiconductor layer of the transistor included in the memory cell 10. In other words, the wiring BL is a wiring for electrically connecting one of the source and the drain of the transistor included in the memory cell 10 in each layer of the memory array 20 to the functional circuit 51 in the perpendicular direction.

The memory array 20 can be provided over the driver circuit 21 to overlap therewith. When the driver circuit 21 and the memory array 20 are provided to overlap with each other, a signal transmission distance between the driver circuit 21 and the memory array 20 can be shortened. Accordingly, the resistance and parasitic capacitance between the driver circuit 21 and the memory array 20 are reduced, so that power consumption and signal delays can be reduced. In addition, the storage device 300 can be downsized.

The functional circuit 51 can be provided in any desired position, e.g., over a circuit that is formed using Si transistors, in a manner similar to that of the memory arrays 20[1] to 20[m] when the functional circuit 51 is formed with an OS transistor like the transistor included in the memory cell 10 of the DOSRAM, whereby integration can be easily performed. With the structure in which a signal is amplified by the functional circuit 51, a circuit in a subsequent stage, such as the sense amplifier 46, can be downsized, so that the storage device 300 can be downsized. The driver circuit 21 includes a PSW 22 (power switch), a PSW 23, and a peripheral circuit 31. The peripheral circuit 31 includes a peripheral circuit 41, a control circuit 32, and a voltage generation circuit 33.

In the storage device 300, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 32.

The control circuit 32 is a logic circuit having a function of controlling the entire operation of the storage device 300. For example, the control circuit performs a logical operation on the signal CE, the signal GW, and the signal BW to determine an operation mode (e.g., a writing operation or a reading operation) of the storage device 300. Alternatively, the control circuit 32 generates a control signal for the peripheral circuit 41 so that the operation mode is executed.

The voltage generation circuit 33 has a function of generating a negative voltage. The signal WAKE has a function of controlling the input of the signal CLK to the voltage generation circuit 33. For example, when an H-level signal is supplied as the signal WAKE, the signal CLK is input to the voltage generation circuit 33, and the voltage generation circuit 33 generates a negative voltage.

The peripheral circuit 41 is a circuit for writing and reading data to/from the memory cells 10. The peripheral circuit 41 is a circuit that outputs signals for controlling the functional circuits 51. The peripheral circuit 41 includes a row decoder 42, a column decoder 44, a row driver 43, a column driver 45, an input circuit 47 (Input Cir.), an output circuit 48 (Output Cir.), and the sense amplifier 46.

The row decoder 42 and the column decoder 44 have a function of decoding the signal ADDR. The row decoder 42 is a circuit for specifying a row to be accessed, and the column decoder 44 is a circuit for specifying a column to be accessed. The row driver 43 has a function of selecting the wiring WL specified by the row decoder 42. The column driver 45 has a function of writing data to the memory cells 10, a function of reading data from the memory cells 10, a function of retaining the read data, and the like.

The input circuit 47 has a function of retaining the signal WDA. Data retained by the input circuit 47 is output to the column driver 45. Data output from the input circuit 47 is data (Din) to be written to the memory cells 10. Data (Dout) read from the memory cells 10 by the column driver 45 is output to the output circuit 48. The output circuit 48 has a function of retaining Dout. In addition, the output circuit 48 has a function of outputting Dout to the outside of the storage device 300. Data output from the output circuit 48 is the signal RDA.

The PSW 22 has a function of controlling supply of VDD to the peripheral circuit 31. The PSW 23 has a function of controlling supply of VHM to the row driver 43. Here, in the storage device 300, a high power supply voltage is VDD and a low power supply voltage is GND (a ground potential). In addition, VHM is a high power supply voltage used to set a word line at a high level and is higher than VDD. The on/off state of the PSW 22 is controlled by the signal PON1, and the on/off state of the PSW 23 is controlled by the signal PON2. The number of power domains to which VDD is supplied is one in the peripheral circuit 31 in FIG. 20 but can be more than one. In that case, a power switch is provided for each power domain.

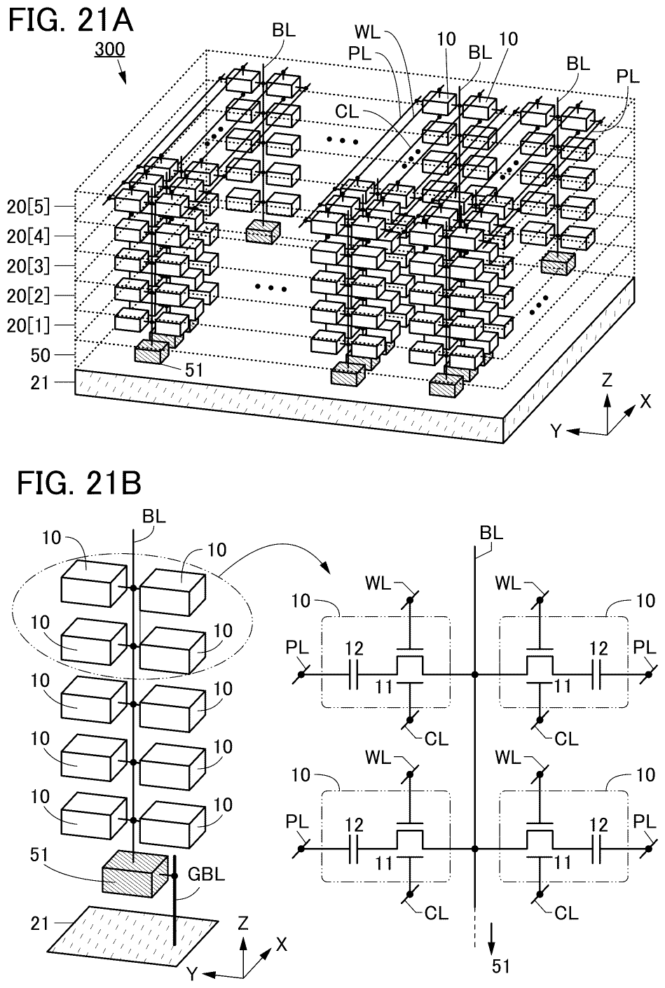

In the memory array 20 including the memory arrays 20[1] to 20[m] (m is an integer greater than or equal to 2) and the functional layer 50, a plurality of layers of the memory arrays 20 can be provided over the driver circuit 21 to overlap with the driver circuit 21. Stacking the plurality of layers of the memory arrays 20 can increase the memory density of the memory cells 10. FIG. 21A is a perspective view of the storage device 300 in which five layers of the memory arrays 20[1] to 20[5] (m=5) and the functional layer 50 are provided over the driver circuit 21 to overlap with the driver circuit 21.

In FIG. 21A, the memory array 20 provided in the first layer is denoted as the memory array 20[1], the memory array 20 provided in the second layer is denoted as the memory array 20[2], and the memory array 20 provided in the fifth layer is denoted as the memory array 20[5]. FIG. 21A also illustrates the wiring WL, the wiring PL, and the wiring CL provided to extend in the X direction and the wiring BL provided to extend in the Z direction (the direction perpendicular to the surface of the substrate provided with the driver circuit). For easy viewing of the drawing, some of the wirings WL and the wirings PL included in the memory arrays 20 are not illustrated.

FIG. 21B is a schematic view for describing a structure example of the functional circuit 51, which is connected to the wiring BL, and the memory cells 10 included in the memory arrays 20[1] to 20[5], which are connected to the wiring BL, illustrated in FIG. 21A. FIG. 21B illustrates the wiring GBL provided between the functional circuit 51 and the driver circuit 21. Note that a structure in which a plurality of memory cells (memory cells 10) are electrically connected to one of the wirings BL is also referred to as “memory string”. In the drawings, the wiring GBL in some cases is represented by a bold line for increasing visibility.

FIG. 21B illustrates an example of a circuit structure of the memory cell 10 connected to the wiring BL. The memory cell 10 includes a transistor 11 and a capacitive element 12. As for the transistor 11, the capacitive element 12, and the wirings (e.g., BL and WL), for example, the wiring BL[1] and the wiring WL[1] are referred to as the wiring BL and the wiring WL in some cases.

In the memory cell 10, one of a source and a drain of the transistor 11 is connected to the wiring BL. The other of the source and the drain of the transistor 11 is connected to one electrode of the capacitive element 12. The other electrode of the capacitive element 12 is connected to the wiring PL. A gate of the transistor 11 is connected to the wiring WL. A back gate of the transistor 11 is connected to the wiring CL.

The wiring PL is a wiring for supplying a constant potential for retaining the potential of the capacitive element 12. The wiring CL is a wiring for supplying a constant potential for controlling the threshold voltage of the transistor 11. The wiring PL and the wiring CL may have the same potential. In that case, the number of wirings connected to the memory cell 10 can be reduced by connecting the two wirings.

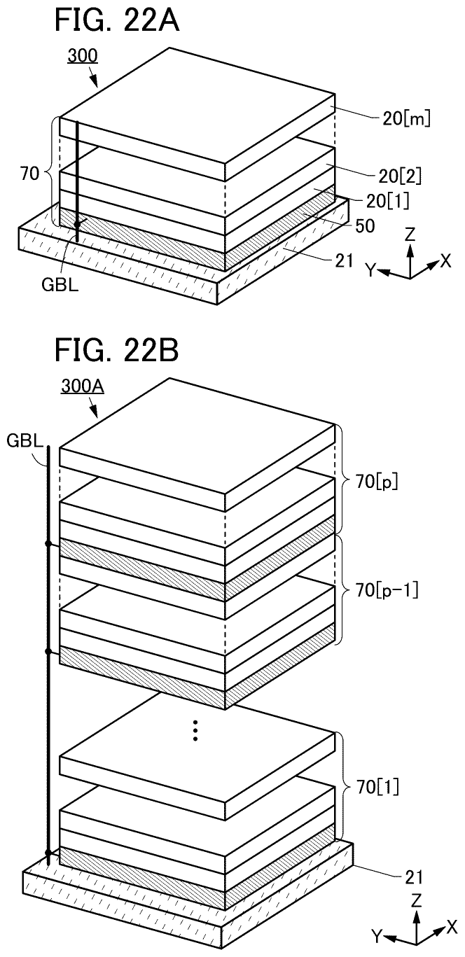

The wiring GBL illustrated in FIG. 21B is provided to electrically connect the driver circuit 21 and the functional layer 50. FIG. 22A is a schematic view of the storage device 300 in which the functional circuit 51 and the memory arrays 20[1] to 20[m] are regarded as a repeating unit 70. Note that although FIG. 22A illustrates one of the wirings GBL, the wiring GBL is provided as appropriate depending on the number of functional circuits 51 provided in the functional layer 50.

Note that the wiring GBL is provided in contact with a semiconductor layer of a transistor included in the functional circuit 51. Alternatively, the wiring GBL is provided in contact with a region functioning as a source or a drain in the semiconductor layer of the transistor included in the functional circuit 51. Alternatively, the wiring GBL is provided in contact with a conductor provided in contact with the region functioning as the source or the drain in the semiconductor layer of the transistor included in the functional circuit 51. In other words, the wiring GBL is a wiring for electrically connecting the driver circuit 21 and one of the source and the drain of the transistor included in the functional circuit 51 in the functional layer 50 in the perpendicular direction.

The repeating unit 70 including the functional circuit 51 and the memory arrays 20[1] to 20[m] may have a stacked-layer structure. A storage device 300A of one embodiment of the present invention can include repeating units 70[1] to 70[p] (p is an integer greater than or equal to 2) as illustrated in FIG. 22B. The wiring GBL is connected to the functional layers 50 included in the repeating units 70. The wiring GBL is provided as appropriate depending on the number of functional circuits 51.

In one embodiment of the present invention, OS transistors are provided in stacked layers and a wiring functioning as a bit line is provided in the direction perpendicular to the surface of the substrate provided with the driver circuit 21. Since the wiring provided to extend from the memory array 20 and function as a bit line is provided in the direction perpendicular to the surface of the substrate, the length of the wiring between the memory array 20 and the driver circuit 21 can be shortened. Thus, the parasitic capacitance of the bit line can be significantly reduced.

In one embodiment of the present invention, the functional layer 50 including the functional circuit 51 having functions of amplifying and outputting a data potential retained in the memory cell 10 is provided in a layer where the memory array 20 is provided. With this structure, a slight difference in the potential of the wiring BL functioning as a bit line can be amplified at the time of data reading to drive the sense amplifier 46 included in the driver circuit 21. A circuit such as a sense amplifier can be downsized, so that the storage device 300 can be downsized. Moreover, even when the capacitance of the capacitive elements 12 included in the memory cells 10 is reduced, operation is possible.

### [Structure Examples of Memory Array 20 and Functional Circuit 51]

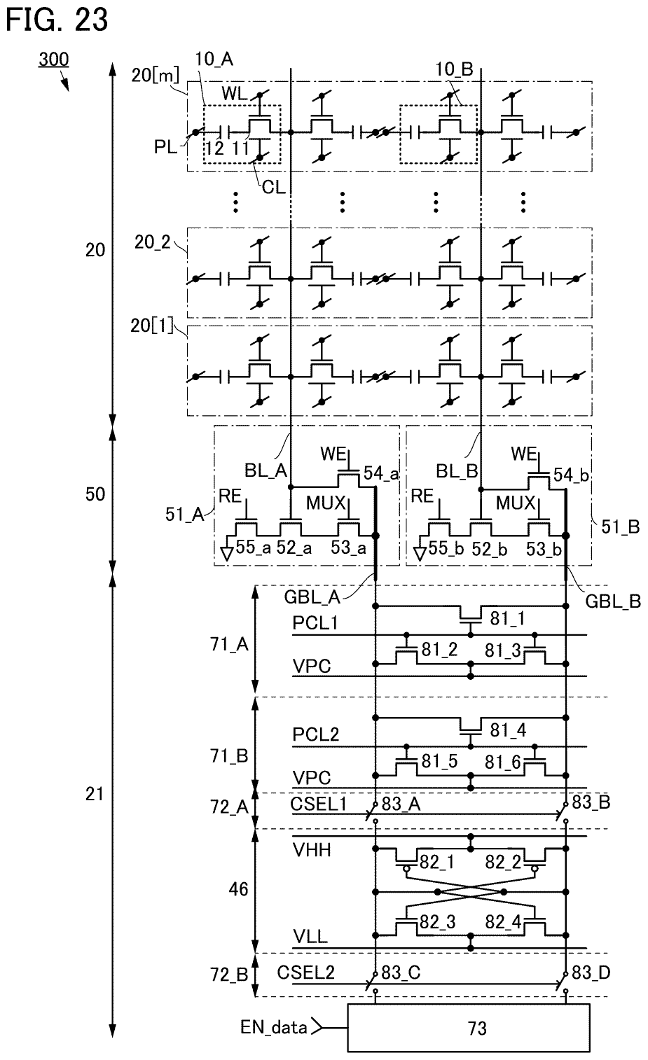

A structure example of the functional circuit 51 and structure examples of the memory array 20 and the sense amplifier 46 included in the driver circuit 21, which are described with reference to FIG. 20 to FIG. 22, are described with reference to FIG. 23. FIG. 23 illustrates the driver circuit 21 connected to the wirings GBL (GBL_A and GBL_B) connected to the functional circuits 51 (51_A and 51_B) connected to the memory cells 10 (10_A and 10_B) connected to different wirings BL (BL_A and BL_B). FIG. 23 also illustrates, as the driver circuit 21, a precharge circuit 71_A, a precharge circuit 71_B, a switch circuit 72_A, a switch circuit 72_B, and a write/read circuit 73 in addition to the sense amplifier 46.

As the functional circuits 51_A and 51_B, transistors 52_a, 52_b, 53_a, 53_b, 54_a, 54_b, 55_a, and 55_b are illustrated. The transistors 52_a, 52_b, 53_a, 53_b, 54_a, 54_b, 55_a, and 55_b illustrated in FIG. 23 are OS transistors like the transistor 11 included in the memory cell 10. The functional layer 50 including the functional circuits 51 can be provided in stacked layers like the memory arrays 20[1] to 20[m].

The wirings BL_A and BL_B are connected to gates of the transistors 52_a and 52_b. Ones of sources and drains of the transistors 53_a, 53_b, 54_a, and 54_b are connected to the wirings GBL_A and GBL_B. The wirings GBL_A and GBL_B are provided in the perpendicular direction like the wirings BL_A and BL_B and connected to the transistors included in the driver circuit 21. As illustrated in FIG. 23, control signals WE, RE, and MUX are supplied to gates of the transistors 53_a, 53_b, 54_a, 54_b, 55_a, and 55_b.

Transistors 81_1 to 81_6 and 82_1 to 82_4 included in the sense amplifier 46, the precharge circuit 71_A, and the precharge circuit 71_B illustrated in FIG. 23 are Si transistors. Switches 83_A to 83_D included in the switch circuit 72_A and the switch circuit 72_B can also be Si transistors. The one of the source and the drain of each of the transistors 53_a, 53_b, 54_a, and 54_b is connected to the transistor or switch included in the precharge circuit 71_A, the precharge circuit 71_B, the sense amplifier 46, or the switch circuit 72_A.

The precharge circuit 71_A includes the n-channel transistors 81_1 to 81_3. The precharge circuit 71_A is a circuit for precharging the wirings BL_A and BL_B with an intermediate potential VPC corresponding to a potential VDD/2 between VDD and VSS in accordance with a precharge signal supplied to a precharge line PCL1.

The precharge circuit 71_B includes the n-channel transistors 81_4 to 81_6. The precharge circuit 71_B is a circuit for precharging the wiring GBL_A and the wiring GBL_B with the intermediate potential VPC corresponding to the potential VDD/2 between VDD and VSS in accordance with a precharge signal supplied to a precharge line PCL2.

The sense amplifier 46 includes the p-channel transistors 82_1 and 82_2 and the n-channel transistors 82_3 and 82_4, which are connected to a wiring VHH or a wiring VLL. The wiring VHH or the wiring VLL is a wiring having a function of supplying VDD or VSS. The transistors 82_1 to 82_4 are transistors that form an inverter loop. The potentials of the wiring BL_A and the wiring BL_B precharged by selecting the memory cells 10_A and 10_B are changed, and the potentials of the wiring GBL_A and the wiring GBL_B are set to the high power supply potential VDD or the low power supply potential VSS in accordance with the changes. The potentials of the wiring GBL_A and the wiring GBL_B can be output to the outside through the switch 83_C, the switch 83_D, and the write/read circuit 73. The wiring BL_A and the wiring BL_B correspond to a bit line pair, and the wiring GBL_A and the wiring GBL_B correspond to a bit line pair. Data signal writing of the write/read circuit 73 is controlled in accordance with a signal EN_data.

The switch circuit 72_A is a circuit for controlling electrical continuity between the sense amplifier 46 and each of the wiring GBL_A and the wiring GBL_B. The on and off states of the switch circuit 72_A are switched under the control of a switch signal CSEL1. In the case where the switches 83_A and 83_B are n-channel transistors, the switches 83_A and 83_B are turned on and off when the switch signal CSEL1 is at a high level and a low level, respectively. The switch circuit 72_B is a circuit for controlling electrical continuity between the write/read circuit 73 and the bit line pair connected to the sense amplifier 46. The on and off states of the switch circuit 72_B are switched under the control of a switching signal CSEL2. The switches 83_C and 83_D are similar to the switches 83_A and 83_B.

As illustrated in FIG. 23, the storage device 300 can have a structure where the memory cell 10, the functional circuit 51, and the sense amplifier 46 are connected to each other through the wiring BL and the wiring GBL provided in the perpendicular direction which is the shortest distance. Even with addition of the functional layer 50 including transistors included in the functional circuit 51, the load of the wiring BL is reduced, whereby the writing time can be shortened and data reading can be facilitated.

As illustrated in FIG. 23, the transistors included in the functional circuits 51_A and 51_B are controlled in accordance with the control signals WE and RE and the control signal MUX. The transistors can output the potential of the wiring BL through the wiring GBL to the driver circuit 21 in accordance with the control signals and the selection signal. The functional circuits 51_A and 51_B can function as a sense amplifier formed with OS transistors. With this structure, a slight difference in the potential of the wiring BL can be amplified at the time of reading to drive the sense amplifier 46 formed using Si transistors.

### [Operation Example of Memory Cell 20, Functional Circuit 51, and Sense Amplifier 46]

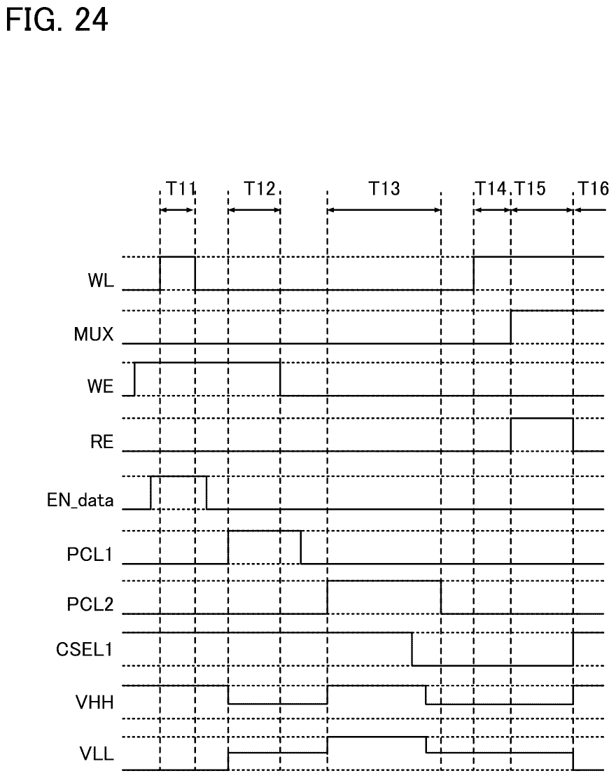

FIG. 24 is a timing chart for describing the operation of the circuit diagram in FIG. 23. In the timing chart in FIG. 24, a period T11 corresponds to a period for describing write operation, a period T12 corresponds to a period for describing precharge operation of the wiring BL, a period T13 corresponds to a period for describing precharge operation of the wiring GBL, a period T14 corresponds to a period for describing charge sharing operation, a period T15 corresponds to a period for describing standby operation for reading, and a period T16 corresponds to a period for describing read operation.

In the period T11, the potential of the wiring WL connected to the gate of the transistor 11 included in the memory cell 10 to which a data signal is desired to be written is set to a high level. At this time, the control signal WE and the signal EN_data are set to a high level, and the data signal is written to the memory cell through the wiring GBL and the wiring BL.

In the period T12, in order to precharge the wiring BL, the precharge line PCL1 is set to a high level in a state where the control signal WE is at a high level. The wiring BL is precharged with a precharge potential. In the period T12, the wiring VHH and the wiring VLL through which a power supply voltage is supplied to the sense amplifier 46 are both preferably set to VDD/2 in order to suppress power consumption due to a flow-through current.

In the period T13, in order to precharge the wiring GBL, the precharge line PCL2 is set to a high level. The wiring GBL is precharged with a precharge potential. In the period T13, the potentials of the wiring VHH and the wiring VLL are both set to VDD, so that the wiring GBL with a large load can be precharged in a short time.

In the period T14, in order to cause charge sharing for balancing charge retained in the memory cell 10 and charge with which the bit line BL is precharged, the potential of the wiring WL is set to a high level. In the period T14, the potentials of the wiring VHH and the wiring VLL through which a power supply voltage is supplied to the sense amplifier 46 are both preferably set to VDD/2 in order to suppress power consumption due to a flow-through current.

In the period T15, the control signal RE and the control signal MUX are set to a high level. A current flows through the transistor 52 in accordance with the potential of the wiring BL, and the potential of the wiring GBL varies in accordance with the current amount. The switch signal CSEL1 is set to a low level so that the variation in the potential of the wiring GBL is not affected by the sense amplifier 46. The wiring VHH or the wiring VLL is similar to that in the period T14.

In the period T16, the switch signal CSEL1 is set to a high level and the variation in the potential of the wiring GBL is amplified by the bit line pair connected to the sense amplifier 46; thus, the data signal written to the memory cell is read.

### [Arrangement Example of Memory Cell Array]

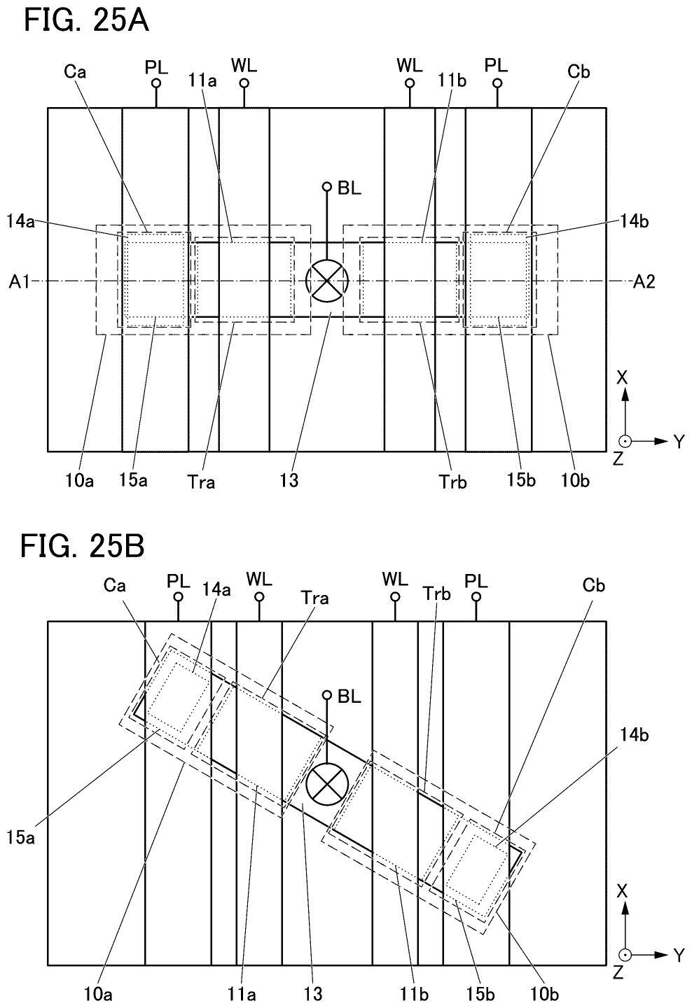

FIG. 25A is a layout diagram illustrating an arrangement example of the wirings and the semiconductor layers in the memory cells 10 described above. FIG. 25A illustrates the wiring WL and the wiring PL provided to extend in the X direction; a semiconductor layer 11a and a semiconductor layer 11b; a conductive layer 13; a conductive layer 14a and a conductive layer 14b; a conductive layer 15a and a conductive layer 15b; and the wiring BL provided to extend in the Z direction. FIG. 25A illustrates a state where each of the semiconductor layer 11a and the semiconductor layer 11b is provided to intersect with one of the wirings WL, each of the conductive layer 14a and the conductive layer 14b is provided to overlap with one of the wirings PL, and the semiconductor layer 11a and the semiconductor layer 11b are connected to one of the wirings BL through the conductive layer 13, whereby two of the memory cells 10 are arranged. Note that the semiconductor layer 11a is electrically connected to the conductive layer 14a through the conductive layer 15a. The semiconductor layer 11b is electrically connected to the conductive layer 14b through the conductive layer 15b.

For easy understanding of the invention, in some cases, the memory cell 10 including the semiconductor layer 11a is referred to as a memory cell 10a and the memory cell 10 including the semiconductor layer 11b is referred to as a memory cell 10b to distinguish the two memory cells 10 from each other.

In the memory cell 10a, the wiring WL and the conductive layer 13 are provided over the semiconductor layer 11a to overlap with the semiconductor layer 11a, and the wiring PL is provided over the conductive layer 14a, which is electrically connected to the semiconductor layer 11a, to overlap with the conductive layer 14a. The transistor Tra is provided in a region where the wiring WL and the semiconductor layer 11a overlap with each other. The capacitive element Ca is provided in a region where the wiring PL and the conductive layer 14a overlap with each other. The conductive layer 13 is a conductive layer for connecting the transistor Tra to the wiring BL. Similarly, in the memory cell 10b, the wiring WL and the conductive layer 13 are provided over the semiconductor layer 11b to overlap with the semiconductor layer 11b, and the wiring PL is provided over the conductive layer 14b, which is electrically connected to the semiconductor layer 11b, to overlap with the conductive layer 14b. The transistor Trb is provided in a region where the wiring WL and the semiconductor layer 11b overlap with each other. The capacitive element Cb is provided in a region where the wiring PL and the conductive layer 14b overlap with each other. The conductive layer 13 is a conductive layer for connecting the transistor Trb to the wiring BL.

Note that the transistor Tra, the transistor Trb, the capacitive element Ca, and the capacitive element Cb respectively correspond to the transistor 200a, the transistor 200b, the capacitive element 250a, and the capacitive element 250b described in Embodiment 1. The semiconductor layer 11a and the semiconductor layer 11b correspond to the oxide 230 described in Embodiment 1. The conductive layer 13 corresponds to the conductor 242a described in Embodiment 1. The conductive layer 15a and the conductive layer 15b correspond to the conductor 242b described in Embodiment 1. The conductive layer 14a and the conductive layer 14b correspond to the conductor 156 described in Embodiment 1. The wiring WL and the wiring PL respectively correspond to the conductor 260 and the conductor 160 described in Embodiment 1. Therefore, detailed description of the cross-sectional view of the memory cell 10 is similar to the description in Embodiment 1, and accordingly, the above description is to be referred to.

In the case where the memory arrays 20 with the memory cells 10 illustrated in FIG. 25A are stacked, it is preferable that the wiring PL in an upper layer and the wiring PL in a lower layer overlap with each other and the wiring WL in an upper layer and the wiring WL in a lower layer overlap with each other. That is, the layout diagrams of two layers of the memory arrays 20 that are provided to overlap with each other preferably overlap with each other. With this structure, the manufacturing process of the storage device can be simplified, and the productivity can be improved.

Although FIG. 25A illustrates a structure in which the semiconductor layer 11a, the semiconductor layer 11b, the conductive layer 13, the conductive layer 15a, and the conductive layer 15b extending in the Y direction are provided to intersect with the wiring WL and the wiring PL at right angles, one embodiment of the present invention is not limited thereto. For example, as illustrated in FIG. 25B, one end portion of the semiconductor layer 11a and one end portion of the semiconductor layer 11b that are provided to extend in the Y direction may be located to be inclined in the X direction, and the semiconductor layer 11a, the semiconductor layer 11b, the conductive layer 13, the conductive layer 15a, and the conductive layer 15b may be provided to intersect with the wiring WL and the wiring PL. With this structure, the memory density of the memory cells 10 can be further increased.

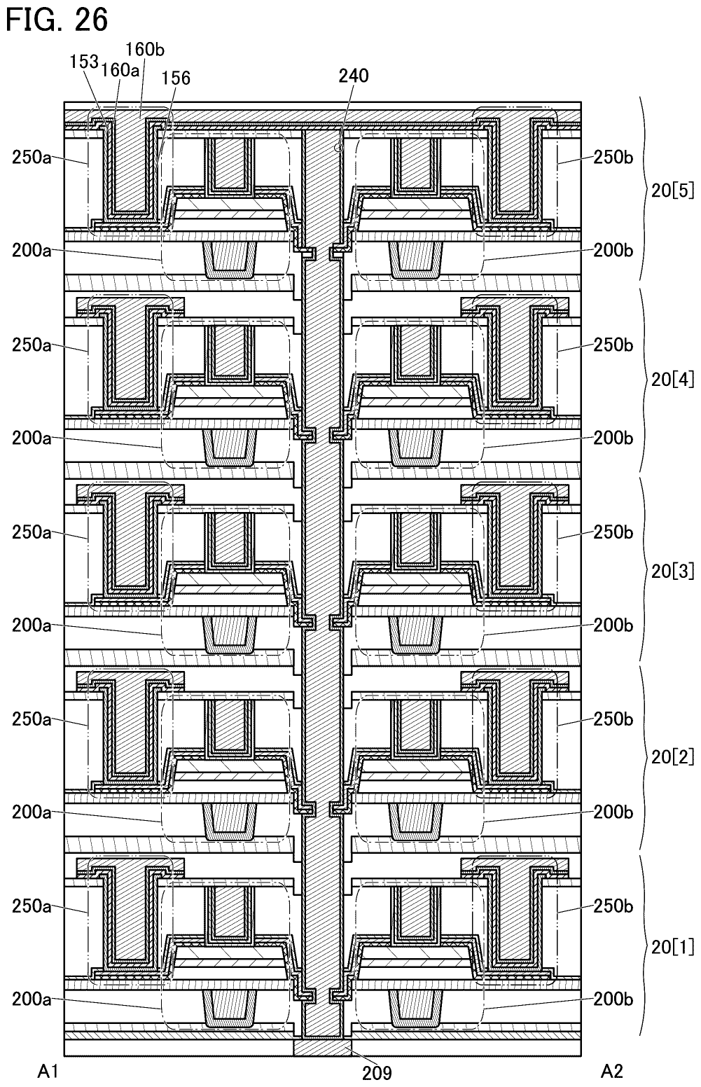

FIG. 26 is a cross-sectional view in which a cut plane including a portion along the dashed-dotted line A1-A2 in FIG. 25A is expanded to form the memory array 20[1] to the memory array 20[5], and the transistor 200 and the capacitive element 250 described in the above embodiment are provided in each memory cell array.

In FIG. 26, the combination of the transistor 200a and the capacitive element 250a corresponds to the memory cell 10a, and the combination of the transistor 200b and the capacitive element 250b corresponds to the memory cell 10b. The conductor 260 corresponds to the wiring WL, and the conductor 160 corresponds to the wiring PL. The oxide 230 corresponds to the semiconductor layer 11a and the semiconductor layer 11b.

As illustrated in FIG. 26, the conductor 160 of the capacitive element 250a in an upper layer is provided over the conductor 160 of the capacitive element 250a in a lower layer such that the conductors 160 overlap with each other, and the conductor 260 of the transistor 200a in an upper layer is provided over the conductor 260 of the transistor 200a in a lower layer such that the conductors 260 overlap with each other.

In the memory cell array 20[5], the insulator 153, the conductor 160a, and the conductor 160b are provided to be shared by the capacitive element 250a and the capacitive element 250b. The insulator 153, the conductor 160a, and the conductor 160b each include a region overlapping with the transistor 200a, the transistor 200b, the capacitive element 250a, and the capacitive element 250b, which are located therebelow.

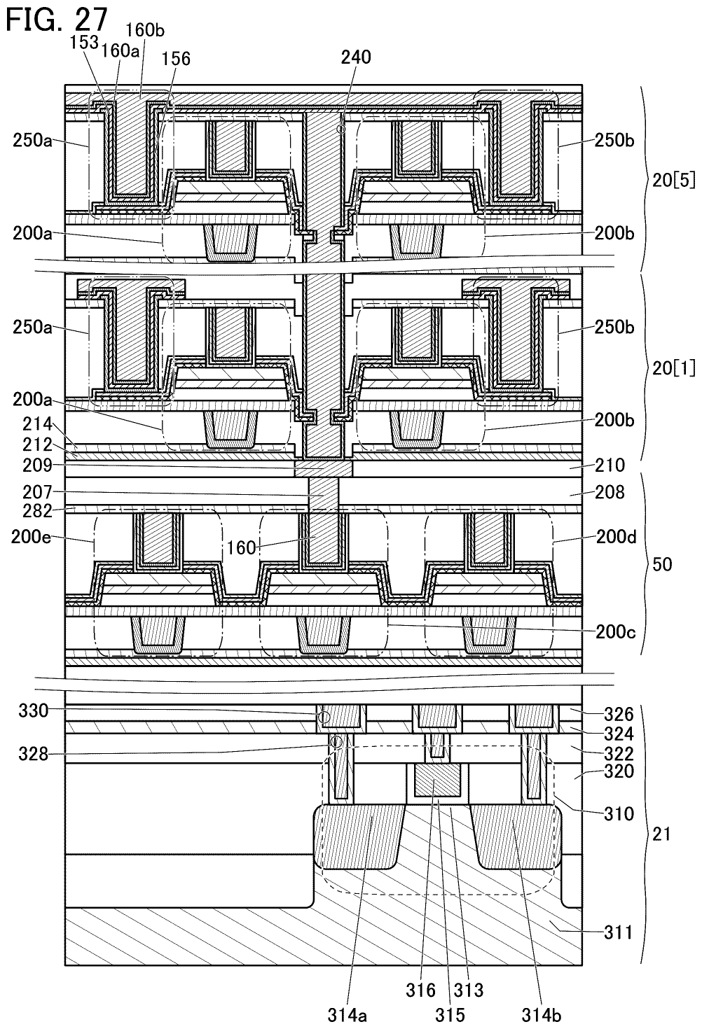

As illustrated in FIG. 27, a transistor 310 can be provided in the driver circuit 21 provided under the memory array 20[1].

The transistor 310 is provided on a substrate 311 and includes a conductor 316 functioning as a gate, an insulator 315 functioning as a gate insulator, a semiconductor region 313 formed of part of the substrate 311, and a low-resistance region 314a and a low-resistance region 314b functioning as a source region and a drain region. The transistor 310 may be a p-channel transistor or an n-channel transistor.

Here, in the transistor 310 illustrated in FIG. 27, the semiconductor region 313 (part of the substrate 311) where a channel is formed has a protruding shape. In addition, the conductor 316 is provided to cover a side surface and the top surface of the semiconductor region 313 with the insulator 315 therebetween. Note that a material adjusting the work function may be used for the conductor 316. Such a transistor 310 is also referred to as a FIN-type transistor because it utilizes a protruding portion of a semiconductor substrate. Note that an insulator functioning as a mask for forming the protruding portion may be included in contact with an upper portion of the protruding portion. Furthermore, although the case where the protruding portion is formed by processing part of the semiconductor substrate is described here, a semiconductor film having a protruding shape may be formed by processing an SOI substrate.

Wiring layers provided with an interlayer film, a wiring, a plug, and the like may be provided between the components. A plurality of wiring layers can be provided in accordance with design.

For example, an insulator 320, an insulator 322, an insulator 324, and an insulator 326 are sequentially stacked over the transistor 310 as interlayer films. A conductor 328, a conductor 330, and the like that are electrically connected to the capacitive element 250, the transistor 200, or the conductor 240 are embedded in the insulator 320, the insulator 322, the insulator 324, and the insulator 326. Note that the conductor 328 and the conductor 330 function as plugs or wirings.

As illustrated in FIG. 22A, FIG. 22B, and the like, the functional layer 50 is provided under a plurality of the memory arrays 20. In FIG. 27, the functional layer 50 is provided between the memory array 20[1] and the driver circuit 21.

FIG. 27 illustrates transistors 200c, 200d, and 200e included in the plurality of functional circuits 51 provided in the functional layer 50. Here, the transistors 200c, 200d, and 200e have a structure similar to that of the transistor 200 described in the above embodiment.

An insulator 208 is provided over the insulator 280 of the functional layer 50, and a conductor 207 is provided in an opening formed in the insulator 208. An insulator similar to the insulator 210 can be provided as the insulator 208, and a conductor similar to the conductor 209 can be provided as the conductor 207.

The bottom surface of the conductor 207 is provided in contact with the top surface of the conductor 160 of the transistor 200c. The top surface of the conductor 207 is provided in contact with the bottom surface of the conductor 209. With such a structure, the conductor 240 that corresponds to the wiring BL functioning as a bit line can be electrically connected to a gate of the transistor 200c corresponding to the transistor 52.

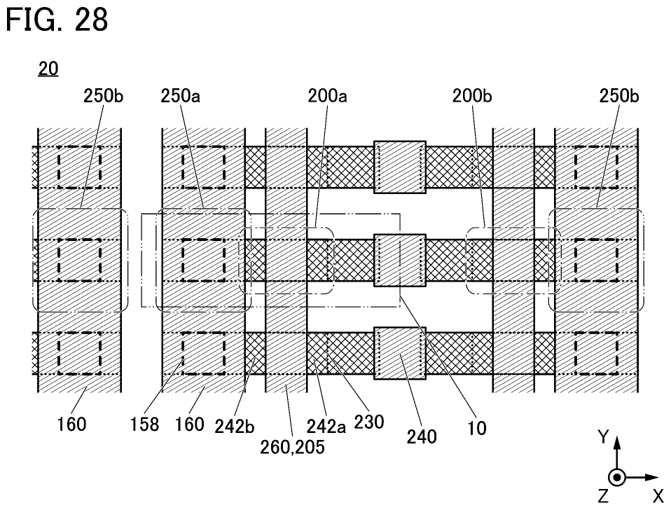

FIG. 28 illustrates an example of a layout in which the memory cells 10 are arranged in a matrix to form the memory array 20. The reference numerals in FIG. 28 correspond to the reference numerals shown in FIG. 7B and the like. In the case where the minimum feature size is 20 nm, the size of the memory cell 10 in FIG. 28 can be 45 nm×125 nm. Since the footprint of the memory cell 10 is 0.0054 μm², the density of the memory cells 10 in the storage device of this embodiment can be 185 cells/μm².

When a plurality of the memory cell arrays and the driver circuit are stacked as described above, the storage device can be highly integrated and have a high storage capacity.

This embodiment can be combined as appropriate with any of the other embodiments and the like described in this specification.

### Embodiment 4

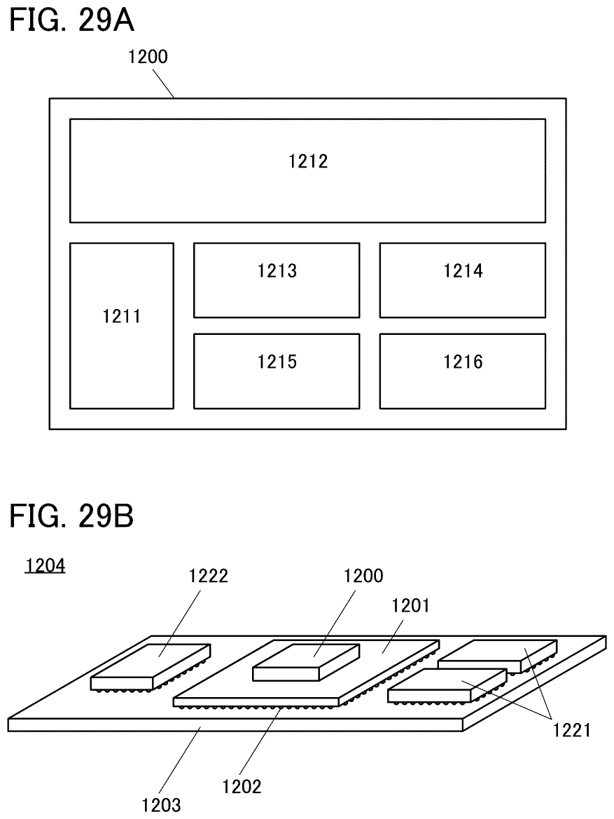

In this embodiment, an example of a chip 1200 on which the semiconductor device of the present invention is mounted is described with reference to FIG. 29A and FIG. 29B. A plurality of circuits (systems) are mounted on the chip 1200. A technique for integrating a plurality of circuits (systems) into one chip is referred to as system on chip (SoC) in some cases.

As illustrated in FIG. 29A, the chip 1200 includes a CPU 1211, a GPU 1212, one or more analog arithmetic units 1213, one or more memory controllers 1214, one or more interfaces 1215, one or more network circuits 1216, and the like.

A bump (not illustrated) is provided on the chip 1200, and as illustrated in FIG. 29B, the chip 1200 is connected to a first surface of a package substrate 1201. In addition, a plurality of bumps 1202 are provided on a rear side of the first surface of the package substrate 1201, and the package substrate 1201 is connected to a motherboard 1203.

Storage devices such as DRAMs 1221 and a flash memory 1222 may be provided over the motherboard 1203. For example, the DOSRAM described in the above embodiment can be used as the DRAM 1221. In that case, the DRAMs 1221 can have lower power consumption, higher speed, and higher capacity.

The CPU 1211 preferably includes a plurality of CPU cores. In addition, the GPU 1212 preferably includes a plurality of GPU cores. Furthermore, the CPU 1211 and the GPU 1212 may each include a memory for temporarily storing data. Alternatively, a common memory for the CPU 1211 and the GPU 1212 may be provided in the chip 1200. The DOSRAM described above can be used as the memory. Moreover, the GPU 1212 is suitable for parallel computation of a large number of pieces of data and thus can be used for image processing or product-sum operation. When an image processing circuit or a product-sum operation circuit including an oxide semiconductor of the present invention is provided in the GPU 1212, image processing and product-sum operation can be performed with low power consumption.

In addition, since the CPU 1211 and the GPU 1212 are provided on the same chip, a wiring between the CPU 1211 and the GPU 1212 can be shortened, and the data transfer from the CPU 1211 to the GPU 1212, the data transfer between memories included in the CPU 1211 and the GPU 1212, and the transfer of arithmetic operation results from the GPU 1212 to the CPU 1211 after the arithmetic operation in the GPU 1212 can be performed at high speed.

The analog arithmetic unit 1213 includes one or both of an A/D (analog/digital) converter circuit and a D/A (digital/analog) converter circuit. Furthermore, the product-sum operation circuit may be provided in the analog arithmetic unit 1213.

The memory controller 1214 includes a circuit functioning as a controller of the DRAM 1221 and a circuit functioning as an interface of the flash memory 1222.

The interface 1215 includes an interface circuit for an external connection device such as a display device, a speaker, a microphone, a camera, or a controller. Examples of the controller include a mouse, a keyboard, and a game controller. As such an interface, a USB (Universal Serial Bus), an HDMI (registered trademark) (High-Definition Multimedia Interface), or the like can be used.

The network circuit 1216 includes a network circuit such as a LAN (Local Area Network). The network circuit 1216 may further include a circuit for network security.

The circuits (systems) can be formed in the chip 1200 through the same manufacturing process. Therefore, even when the number of circuits needed for the chip 1200 increases, there is no need to increase the number of steps in the manufacturing process; thus, the chip 1200 can be manufactured at low cost.

The motherboard 1203 provided with the package substrate 1201 on which the chip 1200 including the GPU 1212 is mounted, the DRAMs 1221, and the flash memory 1222 can be referred to as a GPU module 1204.

The GPU module 1204 includes the chip 1200 using SoC technology, and thus can have a small size. In addition, the GPU module 1204 is excellent in image processing, and thus is suitably used in a portable electronic appliance such as a smartphone, a tablet terminal, a laptop PC, or a portable (mobile) game machine. Furthermore, the product-sum operation circuit using the GPU 1212 can perform a method such as a deep neural network (DNN), a convolutional neural network (CNN), a recurrent neural network (RNN), an autoencoder, a deep Boltzmann machine (DBM), or a deep belief network (DBN); hence, the chip 1200 can be used as an AI chip or the GPU module 1204 can be used as an AI system module.

At least part of the structure, method, and the like described in this embodiment can be implemented in an appropriate combination with any of those in the other embodiments, the other examples, and the like described in this specification.

### Embodiment 5

In this embodiment, examples of electronic components and electronic appliances in which the storage device or the like described in the above embodiment is incorporated are described. When the storage device described in the above embodiment is used for the following electronic components and electronic appliances, the electronic components and electronic appliances can have lower power consumption and higher speed.

### <Electronic Component>

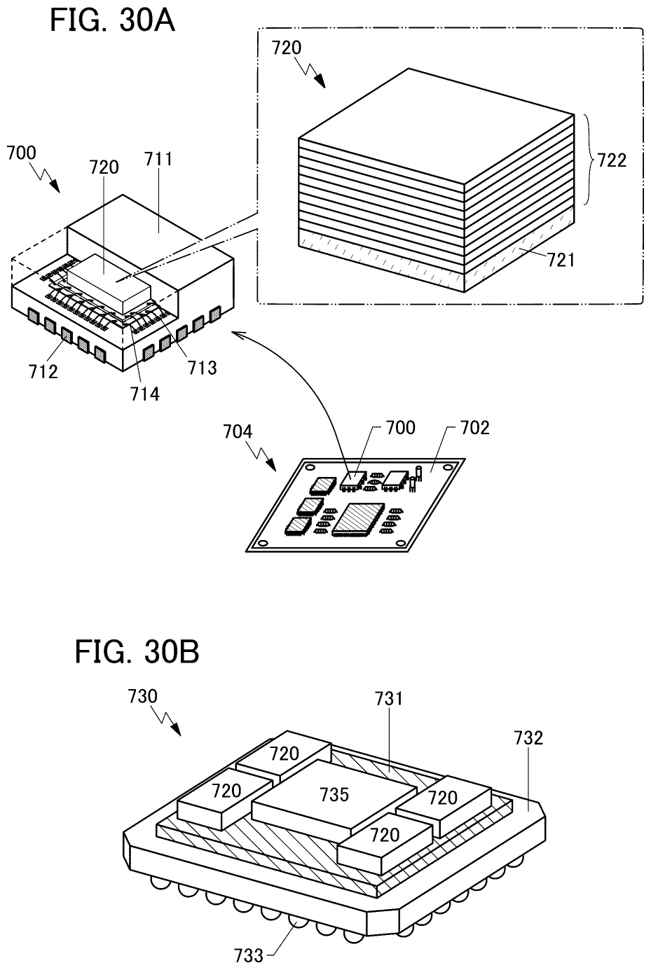

First, examples of an electronic component including a storage device 720 are described with reference to FIG. 30A and FIG. 30B.

FIG. 30A is a perspective view of an electronic component 700 and a substrate (mounting board 704) on which the electronic component 700 is mounted. The electronic component 700 illustrated in FIG. 30A includes the storage device 720 in a mold 711. FIG. 30A omits part of the electronic component to show the inside of the electronic component 700. The electronic component 700 includes a land 712 outside the mold 711. The land 712 is electrically connected to an electrode pad 713, and the electrode pad 713 is electrically connected to the storage device 720 via a wire 714. The electronic component 700 is mounted on a printed circuit board 702, for example. A plurality of such electronic components are combined and electrically connected to each other on the printed circuit board 702, which forms the mounting board 704.

The storage device 720 includes a driver circuit layer 721 and a storage circuit layer 722.

FIG. 30B is a perspective view of an electronic component 730. The electronic component 730 is an example of a SiP (System in package) or an MCM (Multi Chip Module). In the electronic component 730, an interposer 731 is provided over a package substrate 732 (printed circuit board), and a semiconductor device 735 and a plurality of the storage devices 720 are provided over the interposer 731.

The electronic component 730 using the storage device 720 as a high bandwidth memory (HBM) is illustrated as an example. An integrated circuit (a semiconductor device) such as a CPU, a GPU, or an FPGA can be used as the semiconductor device 735.

As the package substrate 732, a ceramic substrate, a plastic substrate, a glass epoxy substrate, or the like can be used. As the interposer 731, a silicon interposer, a resin interposer, or the like can be used.

The interposer 731 includes a plurality of wirings and has a function of electrically connecting a plurality of integrated circuits with different terminal pitches. The plurality of wirings have a single-layer structure or a layered structure. The interposer 731 has a function of electrically connecting an integrated circuit provided on the interposer 731 to an electrode provided on the package substrate 732. Accordingly, the interposer is sometimes referred to as a “redistribution substrate” or an “intermediate substrate”. A through electrode may be provided in the interposer 731 to be used for electrically connecting the integrated circuit and the package substrate 732. In the case of using a silicon interposer, a TSV (Through Silicon Via) can also be used as the through electrode.

A silicon interposer is preferably used as the interposer 731. The silicon interposer can be manufactured at lower cost than an integrated circuit because the silicon interposer does not need to be provided with an active element. Meanwhile, since wirings of the silicon interposer can be formed through a semiconductor process, the formation of minute wirings, which is difficult for a resin interposer, is easily achieved.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, or the like using a silicon interposer, a decrease in reliability due to a difference in expansion coefficient between an integrated circuit and the interposer is less likely to occur. Furthermore, a surface of a silicon interposer has high planarity, and a poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

A heat sink (radiator plate) may be provided to overlap with the electronic component 730. In the case of providing a heat sink, the heights of integrated circuits provided on the interposer 731 are preferably the same. In the electronic component 730 of this embodiment, the heights of the storage device 720 and the semiconductor device 735 are preferably the same, for example.

An electrode 733 may be provided on the bottom portion of the package substrate 732 to mount the electronic component 730 on another substrate. FIG. 30B illustrates an example where the electrode 733 is formed of a solder ball. Solder balls are provided in a matrix on the bottom portion of the package substrate 732, whereby BGA (Ball Grid Array) mounting can be achieved. Alternatively, the electrode 733 may be formed of a conductive pin. When conductive pins are provided in a matrix on the bottom portion of the package substrate 732, PGA (Pin Grid Array) mounting can be achieved.

The electronic component 730 can be mounted on another substrate by any of various mounting methods other than BGA and PGA. For example, a mounting method such as SPGA (Staggered Pin Grid Array), LGA (Land Grid Array), QFP (Quad Flat Package), QFJ (Quad Flat J-leaded package), or QFN (Quad Flat Non-leaded package) can be employed.

The structure, method, and the like described in this embodiment can be used in an appropriate combination with any of other structures, methods, and the like described in this embodiment or any of structures, methods, and the like described in the other embodiments.

### Embodiment 6

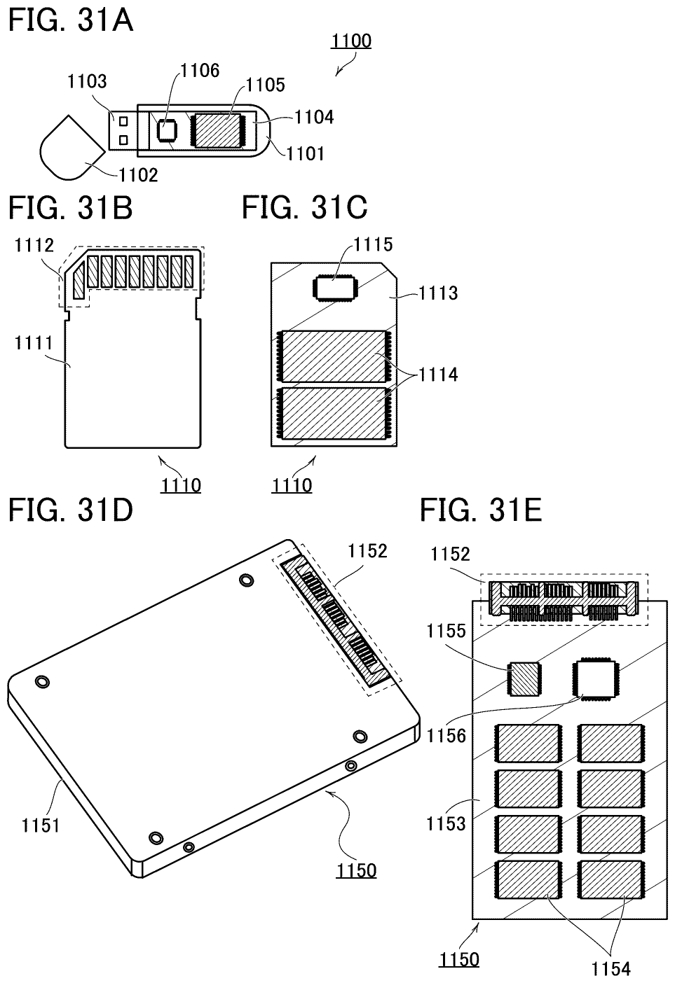

In this embodiment, application examples of the storage device using the storage device described in the above embodiment are described. The storage device described in the above embodiment can be applied to, for example, storage devices of a variety of electronic appliances (e.g., information terminals, computers, smartphones, e-book readers, digital cameras (including video cameras), video recording/reproducing devices, and navigation systems). When the storage device described in the above embodiment is used for the storage devices of the above electronic appliances, the electronic appliances can have lower power consumption and higher speed. Here, the computers refer not only to tablet computers, notebook computers, and desktop computers, but also to large computers such as server systems. Alternatively, the storage device described in the above embodiment is applied to a variety of removable storage devices such as memory cards (e.g., SD cards), USB memories, and SSDs (solid state drives). FIG. 31A to FIG. 31E schematically illustrate some structure examples of removable storage devices. The storage device described in the above embodiment is processed into a packaged memory chip and used in a variety of storage devices and removable memories, for example.

FIG. 31A is a schematic view of a USB memory. A USB memory 1100 includes a housing 1101, a cap 1102, a USB connector 1103, and a substrate 1104. The substrate 1104 is held in the housing 1101. The substrate 1104 is provided with a memory chip 1105 and a controller chip 1106, for example. The storage device described in the above embodiment can be incorporated in the memory chip 1105 or the like.

FIG. 31B is a schematic external view of an SD card, and FIG. 31C is a schematic view of the internal structure of the SD card. An SD card 1110 includes a housing 1111, a connector 1112, and a substrate 1113. The substrate 1113 is held in the housing 1111. The substrate 1113 is provided with a memory chip 1114 and a controller chip 1115, for example. When the memory chip 1114 is also provided on the back side of the substrate 1113, the capacity of the SD card 1110 can be increased. In addition, a wireless chip with a radio communication function may be provided on the substrate 1113. This enables data reading and writing of the memory chip 1114 by wireless communication between a host device and the SD card 1110. The storage device described in the above embodiment can be incorporated in the memory chip 1114 or the like.

FIG. 31D is a schematic external view of an SSD, and FIG. 31E is a schematic view of the internal structure of the SSD. An SSD 1150 includes a housing 1151, a connector 1152, and a substrate 1153. The substrate 1153 is held in the housing 1151. The substrate 1153 is provided with a memory chip 1154, a memory chip 1155, and a controller chip 1156, for example. The memory chip 1155 is a work memory of the controller chip 1156, and a DOSRAM chip can be used, for example. When the memory chip 1154 is also provided on the back side of the substrate 1153, the capacity of the SSD 1150 can be increased. The storage device described in the above embodiment can be incorporated in the memory chip 1154 or the like.

At least part of the structure, method, and the like described in this embodiment can be implemented in an appropriate combination with any of those in the other embodiments, the other examples, and the like described in this specification.

### Embodiment 7

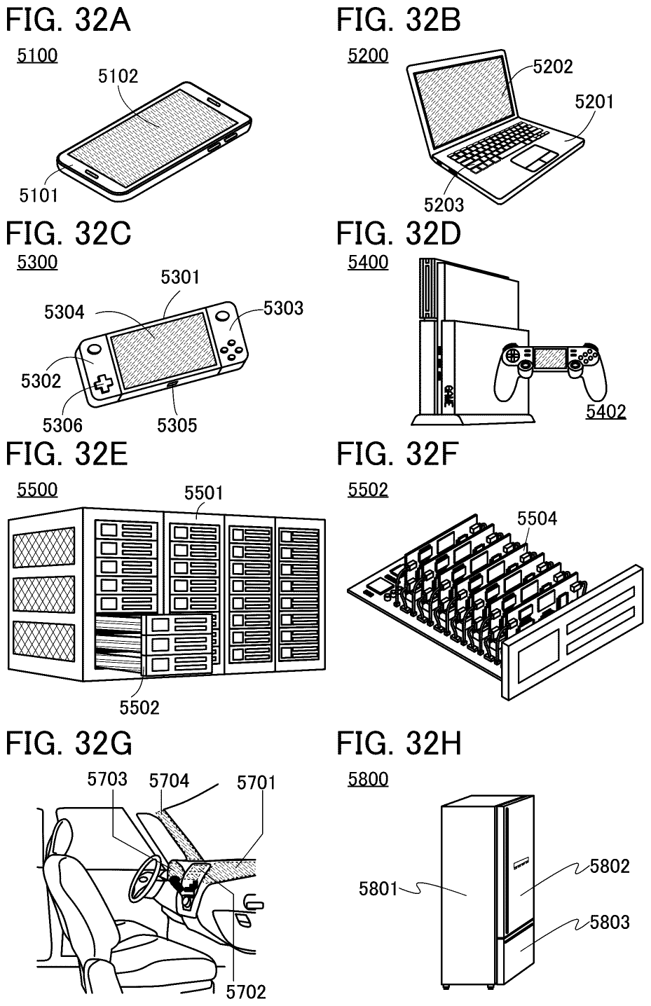

The storage device of one embodiment of the present invention can be used as a processor, e.g., a CPU or a GPU, or a chip. When such a processor, e.g., a CPU or a GPU, or such a chip is used for an electronic appliance, the electronic appliance can have lower power consumption and higher speed. FIG. 32A to FIG. 32H illustrate specific examples of the electronic appliance provided with the processor, e.g., the CPU or the GPU, or the chip that includes the storage device.

### <Electronic Appliance and System>

The GPU or the chip of one embodiment of the present invention can be mounted on a variety of electronic appliances. Examples of electronic appliances include a digital camera, a digital video camera, a digital photo frame, an e-book reader, a mobile phone, a portable game machine, a portable information terminal, and an audio reproducing device in addition to electronic appliances provided with a relatively large screen, such as a television device, a monitor for a desktop or notebook information terminal or the like, digital signage, and a large game machine like a pachinko machine. When the GPU or the chip of one embodiment of the present invention is provided in the electronic appliance, the electronic appliance can include artificial intelligence.

The electronic appliance of one embodiment of the present invention may include an antenna. When a signal is received by the antenna, the electronic appliance can display a video, data, or the like on a display portion. When the electronic appliance includes the antenna and a secondary battery, the antenna may be used for contactless power transmission.

The electronic appliance of one embodiment of the present invention may include a sensor (a sensor having a function of measuring force, displacement, position, speed, acceleration, angular velocity, rotational frequency, distance, light, liquid, magnetism, temperature, a chemical substance, sound, time, hardness, an electric field, current, voltage, power, radioactive rays, flow rate, humidity, a gradient, oscillation, odor, or infrared rays).

The electronic appliance of one embodiment of the present invention can have a variety of functions. For example, the electronic appliance can have a function of displaying a variety of data (a still image, a moving image, a text image, and the like) on the display portion, a touch panel function, a function of displaying a calendar, date, time, or the like, a function of executing a variety of software (programs), a wireless communication function, and a function of reading out a program or data stored in a recording medium. FIG. 32A to FIG. 32H illustrate examples of electronic appliances.

### [Information Terminal]

FIG. 32A illustrates a mobile phone (smartphone), which is a type of information terminal. An information terminal 5100 includes a housing 5101 and a display portion 5102. As input interfaces, a touch panel is provided in the display portion 5102 and a button is provided in the housing 5101.

When the chip of one embodiment of the present invention is applied to the information terminal 5100, the information terminal 5100 can execute an application utilizing artificial intelligence. Examples of the application utilizing artificial intelligence include an application for recognizing a conversation and displaying the contents of the conversation on the display portion 5102; an application for recognizing letters, figures, and the like input to the touch panel of the display portion 5102 by a user and displaying them on the display portion 5102; and an application for performing biometric authentication using fingerprints, voice prints, or the like.

FIG. 32B illustrates a notebook information terminal 5200. The notebook information terminal 5200 includes a main body 5201 of the information terminal, a display portion 5202, and a keyboard 5203.

Like the information terminal 5100 described above, when the chip of one embodiment of the present invention is applied to the notebook information terminal 5200, the notebook information terminal 5200 can execute an application utilizing artificial intelligence. Examples of the application utilizing artificial intelligence include design-support software, text correction software, and software for automatic menu generation. Furthermore, with the use of the notebook information terminal 5200, novel artificial intelligence can be developed.

Note that although FIG. 32A and FIG. 32B illustrate a smartphone and a notebook information terminal, respectively, as examples of the electronic appliance in the above description, an information terminal other than a smartphone and a notebook information terminal can be used. Examples of information terminals other than a smartphone and a notebook information terminal include a PDA (Personal Digital Assistant), a desktop information terminal, and a workstation.

### [Game Machine]

FIG. 32C illustrates a portable game machine 5300 as an example of a game machine. The portable game machine 5300 includes a housing 5301, a housing 5302, a housing 5303, a display portion 5304, a connection portion 5305, an operation key 5306, and the like. The housing 5302 and the housing 5303 can be detached from the housing 5301. When the connection portion 5305 provided in the housing 5301 is attached to another housing (not illustrated), an image to be output to the display portion 5304 can be output to another video device (not illustrated). In this case, the housing 5302 and the housing 5303 can each function as an operating unit. Thus, a plurality of players can play a game at the same time. The chip described in the above embodiment can be incorporated into the chip provided on a substrate in the housing 5301, the housing 5302, and the housing 5303.

FIG. 32D illustrates a stationary game machine 5400 as an example of a game machine. A controller 5402 is wired or connected wirelessly to the stationary game machine 5400.

Using the GPU or the chip of one embodiment of the present invention in a game machine such as the portable game machine 5300 and the stationary game machine 5400 achieves a low-power-consumption game machine. Moreover, heat generation from a circuit can be reduced owing to low power consumption; thus, the influence of heat generation on the circuit, a peripheral circuit, and a module can be reduced.

Furthermore, when the GPU or the chip of one embodiment of the present invention is applied to the portable game machine 5300, the portable game machine 5300 including artificial intelligence can be achieved.

In general, the progress of a game, the actions and words of game characters, and expressions of an event and the like occurring in the game are determined by the program in the game; however, the use of artificial intelligence in the portable game machine 5300 enables expressions not limited by the game program. For example, it becomes possible to change expressions such as questions posed by the player, the progress of the game, time, and actions and words of game characters.

In addition, when a game requiring a plurality of players is played on the portable game machine 5300, the artificial intelligence can create a virtual game player; thus, the game can be played alone with the game player created by the artificial intelligence as an opponent.

Although the portable game machine and the stationary game machine are illustrated as examples of game machines in FIG. 32C and FIG. 32D, the game machine using the GPU or the chip of one embodiment of the present invention is not limited thereto. Examples of the game machine to which the GPU or the chip of one embodiment of the present invention is applied include an arcade game machine installed in entertainment facilities (a game center, an amusement park, and the like), and a throwing machine for batting practice installed in sports facilities.

### [Large Computer]

The GPU or the chip of one embodiment of the present invention can be used in a large computer.

FIG. 32E is a diagram illustrating a supercomputer 5500 as an example of a large computer. FIG. 32F is a diagram illustrating a rack-mount computer 5502 included in the supercomputer 5500.

The supercomputer 5500 includes a rack 5501 and a plurality of rack-mount computers 5502. The plurality of computers 5502 are stored in the rack 5501. The computer 5502 includes a plurality of substrates 5504, on which the GPU or the chip described in the above embodiment can be mounted.

The supercomputer 5500 is a large computer mainly used for scientific computation. In scientific computation, an enormous amount of arithmetic operation needs to be processed at high speed; hence, power consumption is high and chips generate a large amount of heat. Using the GPU or the chip of one embodiment of the present invention in the supercomputer 5500 achieves a low-power-consumption supercomputer. Moreover, heat generation from a circuit can be reduced owing to low power consumption; thus, the influence of heat generation on the circuit, a peripheral circuit, and a module can be reduced.

Although a supercomputer is illustrated as an example of a large computer in FIG. 32E and FIG. 32F, a large computer using the GPU or the chip of one embodiment of the present invention is not limited thereto. Other examples of large computers in which the GPU or the chip of one embodiment of the present invention is usable include a computer that provides service (a server) and a large general-purpose computer (a mainframe).

### [Moving Vehicle]

The GPU or the chip of one embodiment of the present invention can be applied to an automobile, which is a moving vehicle, and the periphery of a driver's seat in the automobile.

FIG. 32G is a diagram illustrating an area around a windshield inside an automobile, which is an example of a moving vehicle. FIG. 32G illustrates a display panel 5701, a display panel 5702, and a display panel 5703 that are attached to a dashboard and a display panel 5704 that is attached to a pillar.

The display panel 5701 to the display panel 5703 can provide a variety of kinds of information by displaying a speedometer, a tachometer, mileage, a fuel gauge, a gear state, air-condition setting, and the like. In addition, the content, layout, or the like of the display on the display panels can be changed as appropriate to suit the user's preference, so that the design quality can be increased. The display panel 5701 to the display panel 5703 can also be used as lighting devices.

The display panel 5704 can compensate for view obstructed by the pillar (a blind spot) by showing an image taken by an image capturing device (not illustrated) provided for the automobile. That is, displaying an image taken by the image capturing device provided outside the automobile leads to compensation for the blind spot and an increase in safety. In addition, displaying an image to compensate for a portion that cannot be seen makes it possible for the driver to confirm the safety more naturally and comfortably. The display panel 5704 can also be used as a lighting device.

Since the GPU or the chip of one embodiment of the present invention can be applied to a component of artificial intelligence, the chip can be used for an automatic driving system of the automobile, for example. The chip can also be used for a system for navigation, risk prediction, or the like. A structure may be employed in which the display panel 5701 to the display panel 5704 display navigation information, risk prediction information, or the like.

Note that although an automobile is described above as an example of a moving vehicle, the moving vehicle is not limited to an automobile. Examples of the moving vehicle include a train, a monorail train, a ship, and a flying vehicle (a helicopter, an unmanned aircraft (a drone), an airplane, and a rocket), and these moving vehicles can each include a system utilizing artificial intelligence when the chip of one embodiment of the present invention is applied to each of these moving vehicles.

### [Household Appliance]

FIG. 32H illustrates an electric refrigerator-freezer 5800 as an example of a household appliance. The electric refrigerator-freezer 5800 includes a housing 5801, a refrigerator door 5802, a freezer door 5803, and the like.

When the chip of one embodiment of the present invention is applied to the electric refrigerator-freezer 5800, the electric refrigerator-freezer 5800 including artificial intelligence can be achieved. Utilizing the artificial intelligence enables the electric refrigerator-freezer 5800 to have a function of automatically making a menu based on foods stored in the electric refrigerator-freezer 5800, expiration dates of the foods, or the like, a function of automatically adjusting temperature to be appropriate for the foods stored in the electric refrigerator-freezer 5800, and the like.

Although the electric refrigerator-freezer is described as an example of a household appliance, examples of other household appliances include a vacuum cleaner, a microwave oven, an electric oven, a rice cooker, a water heater, an IH cooker, a water server, a heating-cooling combination appliance such as an air conditioner, a washing machine, a drying machine, and an audio visual appliance.

The electronic appliances, the functions of the electronic appliances, the application examples of artificial intelligence, their effects, and the like described in this embodiment can be combined as appropriate with the description of another electronic appliance.

At least part of the structure, method, and the like described in this embodiment can be implemented in an appropriate combination with any of those in the other embodiments, the other examples, and the like described in this specification.

### Embodiment 8

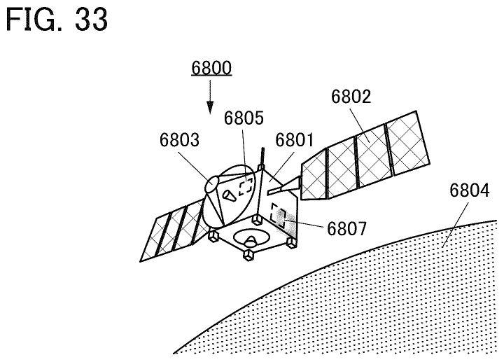

The semiconductor device of one embodiment of the present invention includes an OS transistor. A change in electrical characteristics of the OS transistor due to radiation irradiation is small. That is, the OS transistor is highly resistant to radiation, and thus can be suitably used even in an environment where radiation can enter. For example, OS transistors can be suitably used in outer space. In this embodiment, a specific example of using the semiconductor device of one embodiment of the present invention in a device for space will be described with reference to FIG. 33.

FIG. 33 illustrates an artificial satellite 6800 as an example of a device for space. The artificial satellite 6800 includes a body 6801, a solar panel 6802, an antenna 6803, a secondary battery 6805, and a control device 6807. In FIG. 33, a planet 6804 in outer space is illustrated as an example. Note that outer space refers to, for example, space at an altitude greater than or equal to 100 km, and outer space described in this specification may include thermosphere, mesosphere, and stratosphere.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beam, proton beam, heavy-ion beams, and meson beams.

When the solar panel 6802 is irradiated with sunlight, electric power required for operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a storage device, for example. Note that the semiconductor device that is one embodiment of the present invention and that includes an OS transistor is suitably used for the control device 6807. A change in electrical characteristics due to radiation irradiation is smaller in an OS transistor than in a Si transistor. That is, the OS transistor has high reliability and thus can be suitably used even in an environment where radiation can enter.

The artificial satellite 6800 can be configured to include a sensor. For example, when configured to include a visible light sensor, the artificial satellite 6800 can have a function of sensing sunlight reflected by a ground-based object. Alternatively, when configured to include a thermal infrared sensor, the artificial satellite 6800 can have a function of sensing thermal infrared rays emitted from the surface of the earth. Thus, the artificial satellite 6800 can have a function of an earth observing satellite, for example.

Although the artificial satellite is described as an example of a device for space in this embodiment, one embodiment of the present invention is not limited thereto. The semiconductor device of one embodiment of the present invention can be suitably used for a device for space such as a spacecraft, a space capsule, or a space probe, for example.

### REFERENCE NUMERALS

10: memory cell, 11a: semiconductor layer, 11b: semiconductor layer, 11: transistor, 12: capacitive element, 13: conductive layer, 14a: conductive layer, 14b: conductive layer, 15a: conductive layer, 15b: conductive layer, 20: memory array, 21: driver circuit, 22: PSW, 23: PSW, 31: peripheral circuit, 32: control circuit, 33: voltage generation circuit, 41: peripheral circuit, 42: row decoder, 43: row driver, 44: column decoder, 45: column driver, 46: sense amplifier, 47: input circuit, 48: output circuit, 50: functional layer, 51_A: functional circuit, 51_B: functional circuit, 51: functional circuit, 52_a: transistor, 52_b: transistor, 52: transistor, 53_a: transistor, 53_b: transistor, 54_a: transistor, 54_b: transistor, 55_a: transistor, 55_b: transistor, 70: repeating unit, 71_A: precharge circuit, 71_B: precharge circuit, 72_A: switch circuit, 72_B: switch circuit, 73: write/read circuit, 81_1: transistor, 81_3: transistor, 81_4: transistor, 81_6: transistor, 82_1: transistor, 82_2: transistor, 82_3: transistor, 82_4: transistor, 83_A: switch, 83_B: switch, 83_C: switch, 83_D: switch, 110: storage device, 111t: memory cell, 111: memory cell, 112: transistor, 113t: capacitor, 113: capacitor, 114: transistor, 115: transistor, 120: memory cell array, 121: electrode, 122t: electrode, 122: electrode, 123t: insulating layer, 123: insulating layer, 130: substrate, 131: semiconductor layer, 132: gate insulating layer, 133: gate electrode, 134a: electrode, 134b: electrode, 135: conductive layer, 136: conductive layer, 137: conductive layer, 138: wiring, 139: wiring, 153: insulator, 156: conductor, 158: opening, 160a: conductor, 160b: conductor, 160: conductor, 200a: transistor, 200b: transistor, 200c: transistor, 200d: transistor, 200e: transistor, 200: transistor, 205a: conductor, 205b: conductor, 205c: conductor, 205: conductor, 206a: opening, 206b: opening, 206c: opening, 206d: opening, 206e: opening, 206f: opening, 206: opening, 207: conductor, 208: insulator, 209: conductor, 210: insulator, 212: insulator, 214: insulator, 216: insulator, 221: insulator, 222: insulator, 224: insulator, 230a: oxide, 230b: oxide, 230ba: region, 230bb: region, 230bc: region, 230: oxide, 240a: conductor, 240b: conductor, 240: conductor, 242a: conductor, 242b: conductor, 242: conductor, 250a: capacitive element, 250b: capacitive element, 250: capacitive element, 253: insulator, 254: insulator, 258: opening, 260a: conductor, 260b: conductor, 260: conductor, 275: insulator, 280: insulator, 282: insulator, 283: insulator, 285: insulator, 300A: storage device, 300: storage device, 310: transistor, 311: substrate, 313: semiconductor region, 314a: low-resistance region, 314b: low-resistance region, 315: insulator, 316: conductor, 320: insulator, 322: insulator, 324: insulator, 326: insulator, 328: conductor, 330: conductor, 700: electronic component, 702: printed circuit board, 704: mounting board, 711: mold, 712: land, 713: electrode pad, 714: wire, 720: storage device, 721: driver circuit layer, 722: storage circuit layer, 730: electronic component, 731: interposer, 732: package substrate, 733: electrode, 735: semiconductor device, 1100: USB memory, 1101: housing, 1102: cap, 1103: USB connector, 1104: substrate, 1105: memory chip, 1106: controller chip, 1110: SD card, 1111: housing, 1112: connector, 1113: substrate, 1114: memory chip, 1115: controller chip, 1150: SSD, 1151: housing, 1152: connector, 1153: substrate, 1154: memory chip, 1155: memory chip, 1156: controller chip, 1200: chip, 1201: package substrate, 1202: bump, 1203: motherboard, 1204: GPU module, 1211: CPU, 1212: GPU, 1213: analog arithmetic unit, 1214: memory controller, 1215: interface, 1216: network circuit, 1221: DRAM, 1222: flash memory, 5100: information terminal, 5101: housing, 5102: display portion, 5200: notebook information terminal, 5201: main body, 5202: display portion, 5203: keyboard, 5300: portable game machine, 5301: housing, 5302: housing, 5303: housing, 5304: display portion, 5305: connection portion, 5306: operation key, 5400: stationary game machine, 5402: controller, 5500: supercomputer, 5501: rack, 5502: computer, 5504: substrate, 5701: display panel, 5702: display panel, 5703: display panel, 5704: display panel, 5800: electric refrigerator-freezer, 5801: housing, 5802: refrigerator door, 5803: freezer door, 6800: artificial satellite, 6801: body, 6802: solar panel, 6803: antenna, 6804: planet, 6805: secondary battery, 6807: control device

1. A storage device comprising:
a first transistor;
a second transistor;
a first capacitor; and
a second capacitor,
wherein the first capacitor comprises a first electrode and a second electrode,
wherein the second capacitor comprises the first electrode and a third electrode,
wherein one of a source and a drain of the first transistor is electrically connected to the second electrode,
wherein one of a source and a drain of the second transistor is electrically connected to the third electrode, and
wherein the first electrode comprises a portion overlapping with each of the second electrode, the third electrode, the first transistor, and the second transistor and is supplied with a fixed potential or a ground potential.

2. The storage device according to claim 1,
wherein the first electrode comprises a portion above the first transistor and a portion on a side of the first transistor.

3. The storage device according to claim 1, further comprising:
a connection electrode,
wherein the other of the source and the drain of the first transistor is electrically connected to the connection electrode, and
wherein the other of the source and the drain of the second transistor is electrically connected to the connection electrode.

4. The storage device according to claim 3,
wherein the other of the source and the drain of the first transistor comprises a first conductive layer,
wherein the other of the source and the drain of the second transistor comprises a second conductive layer, and
wherein the connection electrode comprises a portion in contact with a top surface of the first conductive layer, a portion in contact with a side surface of the first conductive layer, a portion in contact with a top surface of the second conductive layer, and a portion in contact with a side surface of the second conductive layer.

5. The storage device according to claim 3, further comprising:
a third transistor; and
a third capacitor,
wherein the third transistor and the third capacitor are located below the first transistor,
wherein the third capacitor comprises a fourth electrode and a fifth electrode,
wherein the fourth electrode is supplied with a ground potential or a fixed potential, and
wherein one of a source and a drain of the third transistor is electrically connected to the fifth electrode, and the other of the source and the drain of the third transistor is electrically connected to the connection electrode.

6. The storage device according to claim 5,
wherein the other of the source and the drain of the third transistor comprises a third conductive layer, and
wherein the connection electrode comprises a portion in contact with a top surface of the third conductive layer and a portion in contact with a side surface of the third conductive layer.

7. The storage device according to claim 5,
wherein the first electrode comprises a portion located on a side of the third transistor.

8. The storage device according to claim 7,
wherein the fourth electrode is electrically connected to the first electrode.

9. The storage device according to claim 5,
wherein the first transistor comprises a semiconductor layer and a gate electrode,
wherein the fourth electrode comprises a portion located below the first transistor, and
wherein the gate electrode comprises a portion overlapping with the fourth electrode with the semiconductor layer therebetween.

10. The storage device according to claim 1,
wherein each of the first electrode and the second electrode has a flat-plate shape.

11. The storage device according to claim 1,
wherein a top surface of the second electrode comprises a depressed portion, and
wherein the first electrode comprises a protruding portion engaging with the top surface of the second electrode.

12. The storage device according to claim 2, further comprising:
a connection electrode,
wherein the other of the source and the drain of the first transistor is electrically connected to the connection electrode, and
wherein the other of the source and the drain of the second transistor is electrically connected to the connection electrode.

13. The storage device according to claim 2,
wherein each of the first electrode and the second electrode has a flat-plate shape.

14. The storage device according to claim 2,
wherein a top surface of the second electrode comprises a depressed portion, and
wherein the first electrode comprises a protruding portion engaging with the top surface of the second electrode.
